(19) United States
(12) Patent Application Publication
(10) Pub. No.: US 2025/0113480 A1
(43) Pub. Date: Apr. 3, 2025

(54) METHOD FOR MANUFACTURING SEMICONDUCTOR DEVICE

(71) Applicant: Semiconductor Energy Laboratory Co., Ltd., Atsugi-shi (JP)

(72) Inventors: Toshihiko SAITO, Atsugi (JP); Yasuhiro JINBO, Isehara (JP); Shunpei YAMAZAKI, Setagaya (JP)

(21) Appl. No.: 18/893,067

(22) Filed: Sep. 23, 2024

(30) Foreign Application Priority Data
Sep. 28, 2023 (JP) 2023-167762

(51) Int. Cl. H10B 12/00

(52) U.S. Cl. CPC H10B 12/01

(57) ABSTRACT

A semiconductor device with a high operation speed is provided. The semiconductor device includes a second oxide semiconductor; a second conductor; a third conductor; a first insulator over the second oxide semiconductor, the second conductor, and the third conductor; a second insulator and a fourth conductor in a first opening portion of the first insulator; and a third insulator and a fifth conductor in a second opening portion of the first insulator. The second oxide semiconductor is formed by removing a region covering the top surface of a columnar insulator from a first oxide semiconductor formed to cover the columnar insulator. The second conductor and the third conductor are formed by sequentially forming a first conductor and a first insulator over the second oxide semiconductor and removing a region overlapping with the second opening portion of the first insulator from the first conductor to expose the second oxide semiconductor. The first opening portion of the first insulator includes a region overlapping with the third conductor and the second oxide semiconductor.

### BACKGROUND OF THE INVENTION

### 1. Field of the Invention

One embodiment of the present invention relates to a semiconductor device, a memory device, and an electronic device each including an oxide semiconductor layer. Another embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

### 2. Description of the Related Art

In recent years, semiconductor devices have been developed to be used mainly for an LSI, a CPU, a memory, and the like. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

An object of one embodiment of the present invention is to provide a semiconductor device with a high operation speed. Another object of one embodiment of the present invention is to provide a semiconductor device that can be miniaturized or highly integrated. Another object of one embodiment of the present invention is to provide a semiconductor device with favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Another object of one embodiment of the present invention is to provide a memory device that can be miniaturized or highly integrated. Another object of one embodiment of the present invention is to provide a memory device with a large memory capacity. Another object of one embodiment of the present invention is to provide a memory device with a high operation speed. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a method for manufacturing a semiconductor device, including the steps of: forming a second insulator having a columnar shape over a first insulator; forming a first oxide semiconductor to cover a top surface of the first insulator, a side surface of the second insulator, and a top surface of the second insulator; forming a second oxide semiconductor by removing a region of the first oxide semiconductor covering the top surface of the second insulator and a region of the first oxide semiconductor covering the top surface of the first insulator by anisotropic etching; removing the second insulator; forming a first conductor to cover the second oxide semiconductor and the first insulator; forming a third insulator over the first conductor; forming a first opening portion in the third insulator to reach the first conductor; exposing the second oxide semiconductor and forming a second conductor and a third conductor by forming a second opening portion in the third insulator to reach the first conductor and removing a region of the first conductor overlapping with the second opening portion; forming a fourth insulator to cover the second oxide semiconductor, the second conductor, the third conductor, and the third insulator; forming a fourth conductor over the fourth insulator; forming a fifth conductor in the first opening portion and a sixth conductor in the second opening portion by partly removing the fourth conductor; and forming a fifth insulator in the first opening portion and a sixth insulator in the second opening portion by partly removing the fourth insulator. The third conductor is formed to overlap with the first opening portion.

In the above embodiment, the first opening portion is preferably formed to overlap with the second oxide semiconductor.

In the above embodiment, the first opening portion and the second opening portion preferably do not overlap with each other.

In the above embodiment, it is preferable that the fifth conductor and the sixth conductor be formed by a first treatment for removing a region of the fourth conductor covering a top surface of the third insulator, the fifth insulator and the sixth insulator be formed by a second treatment for removing a region of the fourth insulator covering the top surface of the third insulator, and the first treatment and the second treatment each be a planarization treatment.

In the above embodiment, the planarization treatment is preferably performed by a chemical mechanical polishing method.

Another embodiment of the present invention is a method for manufacturing a semiconductor device, including the steps of: forming a second insulator having a columnar shape over a first insulator; forming a first oxide semiconductor to cover a top surface of the first insulator, a side surface of the second insulator, and a top surface of the second insulator; forming a second oxide semiconductor by removing a region of the first oxide semiconductor covering the top surface of the second insulator and a region of the first oxide semiconductor covering the top surface of the first insulator by anisotropic etching; removing the second insulator; forming a first conductor and a second conductor over the first conductor as a stacked-layer structure to cover the second oxide semiconductor and the first insulator; forming a third insulator over the second conductor; forming a first opening portion and a second opening portion in the third insulator to each reach the second conductor and include a region overlapping with the second oxide semiconductor; forming a third conductor and a fourth conductor by removing a region of the second conductor overlapping with the first opening portion and a region of the second conductor overlapping with the second opening portion; forming a first mask over the third insulator and the first conductor; exposing the second oxide semiconductor and forming a fifth conductor to overlap with the third conductor and a sixth conductor to overlap with the fourth conductor by partly removing a region of the first conductor overlapping with the second opening portion using the first mask; forming a fourth insulator to cover the second oxide semiconductor, the fifth conductor, the sixth conductor, and the third insulator; forming a seventh conductor over the fourth insulator; forming an eighth conductor in the first opening portion and a ninth conductor in the second opening portion by partly removing the seventh conductor; and forming a fifth insulator in the first opening portion and a sixth insulator in the second opening portion by partly removing the fourth insulator. The fifth conductor is formed to overlap with the first opening portion.

In the above embodiment, the first opening portion is preferably formed to overlap with the second oxide semiconductor.

In the above embodiment, it is preferable that the first conductor contain tantalum nitride and the second conductor contain tungsten.

In the above embodiment, the first conductor is preferably formed by a sputtering method.

In the above embodiment, each of the fifth conductor and the sixth conductor preferably includes a region having an end portion protruding into the second opening portion.

In the above embodiment, it is preferable that the end portion of the fifth conductor protruding into the second opening portion extend inward from an end portion of the third conductor and the end portion of the sixth conductor protruding into the second opening portion extend inward from an end portion of the fourth conductor.

In the above embodiment, it is preferable that the first oxide semiconductor be formed by forming a first semiconductor layer, forming a second semiconductor layer over the first semiconductor layer, and forming a third semiconductor layer over the second semiconductor layer, the first semiconductor layer and the third semiconductor layer be formed by an ALD method using a precursor containing indium and an oxidizer, and the second semiconductor layer be formed by a sputtering method using a sputtering target containing zinc.

One embodiment of the present invention can provide a semiconductor device with a high operation speed. Another embodiment of the present invention can provide a semiconductor device that can be miniaturized or highly integrated. Another embodiment of the present invention can provide a semiconductor device with favorable electrical characteristics. Another embodiment of the present invention can provide a semiconductor device with a small variation in electrical characteristics of transistors. Another embodiment of the present invention can provide a highly reliable semiconductor device. Another embodiment of the present invention can provide a semiconductor device with a high on-state current. Another embodiment of the present invention can provide a semiconductor device with low power consumption. Another embodiment of the present invention can provide a novel semiconductor device. Another embodiment of the present invention can provide a method for manufacturing a semiconductor device with high productivity. Another embodiment of the present invention can provide a method for manufacturing a novel semiconductor device.

Another embodiment of the present invention can provide a memory device that can be miniaturized or highly integrated. Another embodiment of the present invention can provide a memory device with a large memory capacity. Another embodiment of the present invention can provide a memory device with a high operation speed. Another embodiment of the present invention can provide a memory device with low power consumption. Another embodiment of the present invention can provide a novel memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIGS. 1B to 1D are cross-sectional views illustrating the example of the semiconductor device.

FIGS. 2A and 2B are cross-sectional views illustrating the example of the semiconductor device.

FIGS. 3A and 3B are cross-sectional views illustrating examples of semiconductor devices.

FIGS. 4A and 4B are cross-sectional views illustrating examples of parts of semiconductor devices.

FIGS. 5A and 5B are plan views illustrating examples of parts of semiconductor devices.

FIG. 6A is a plan view illustrating an example of a semiconductor device. FIGS. 6B to 6D are cross-sectional views illustrating the example of the semiconductor device.

FIG. 7 is a cross-sectional view illustrating the example of the semiconductor device.

FIG. 8A is a plan view illustrating an example of a semiconductor device. FIGS. 8B to 8D are cross-sectional views illustrating the example of the semiconductor device.

FIG. 9A is a plan view illustrating an example of a semiconductor device. FIGS. 9B to 9D are cross-sectional views illustrating the example of the semiconductor device.

FIGS. 10A and 10B are cross-sectional views illustrating examples of semiconductor devices.

FIG. 11A is a plan view illustrating an example of a semiconductor device. FIGS. 1lB to 11D are cross-sectional views illustrating the example of the semiconductor device.

FIGS. 12A to 12D are cross-sectional views illustrating an example of a method for manufacturing an oxide semiconductor.

FIGS. 13A to 13D are cross-sectional views illustrating examples of oxide semiconductors.

FIG. 14A is a plan view illustrating an example of a semiconductor device. FIGS. 14B to 14D are cross-sectional views illustrating the example of the semiconductor device.

FIGS. 15A to 15D are cross-sectional views illustrating examples of semiconductor devices.

FIG. 16A is a plan view illustrating an example of a semiconductor device. FIGS. 16B to 16D are cross-sectional views illustrating the example of the semiconductor device.

FIGS. 17A and 17B are cross-sectional views illustrating the example of the semiconductor device.

FIG. 18A is a plan view illustrating an example of a semiconductor device. FIGS. 18B to 18D are cross-sectional views illustrating the example of the semiconductor device.

FIGS. 19A and 19B are cross-sectional views illustrating the example of the semiconductor device.

FIGS. 20A and 20B are perspective views illustrating an example of a semiconductor device.

FIGS. 21A and 21B are perspective views illustrating an example of a semiconductor device.

FIGS. 22A to 22E are cross-sectional views illustrating examples of semiconductor devices.

FIGS. 23A to 23C are plan views illustrating examples of semiconductor devices.

FIGS. 24A to 24C are cross-sectional views illustrating an example of a semiconductor device.

FIG. 25 is a cross-sectional view illustrating an example of a semiconductor device.

FIG. 26 is a cross-sectional view illustrating an example of a semiconductor device.

FIG. 27A is a plan view illustrating an example of a method for manufacturing a semiconductor device. FIGS. 27B to 27D are cross-sectional views illustrating the example of the method for manufacturing a semiconductor device.

FIG. 28A is a plan view illustrating the example of the method for manufacturing a semiconductor device. FIGS. 28B to 28D are cross-sectional views illustrating the example of the method for manufacturing a semiconductor device.

FIG. 29A is a plan view illustrating the example of the method for manufacturing a semiconductor device. FIGS. 29B to 29D are cross-sectional views illustrating the example of the method for manufacturing a semiconductor device.

FIG. 30A is a plan view illustrating an example of a method for manufacturing a semiconductor device. FIGS. 30B to 30D are cross-sectional views illustrating the example of the method for manufacturing a semiconductor device.

FIG. 31A is a plan view illustrating the example of the method for manufacturing a semiconductor device. FIGS. 31B to 31D are cross-sectional views illustrating the example of the method for manufacturing a semiconductor device.

FIG. 32A is a plan view illustrating the example of the method for manufacturing a semiconductor device. FIGS. 32B to 32D are cross-sectional views illustrating the example of the method for manufacturing a semiconductor device.

FIG. 33A is a plan view illustrating the example of the method for manufacturing a semiconductor device. FIGS. 33B to 33D are cross-sectional views illustrating the example of the method for manufacturing a semiconductor device.

FIG. 34A is a plan view illustrating the example of the method for manufacturing a semiconductor device. FIGS. 34B to 34D are cross-sectional views illustrating the example of the method for manufacturing a semiconductor device.

FIG. 35A is a plan view illustrating the example of the method for manufacturing a semiconductor device. FIGS. 35B to 35D are cross-sectional views illustrating the example of the method for manufacturing a semiconductor device.

FIG. 36A is a plan view illustrating the example of the method for manufacturing a semiconductor device. FIGS. 36B to 36D are cross-sectional views illustrating the example of the method for manufacturing a semiconductor device.

FIG. 37A is a plan view illustrating the example of the method for manufacturing a semiconductor device. FIGS. 37B to 37D are cross-sectional views illustrating the example of the method for manufacturing a semiconductor device.

FIG. 38A is a plan view illustrating the example of the method for manufacturing a semiconductor device. FIGS. 38B to 38D are cross-sectional views illustrating the example of the method for manufacturing a semiconductor device.

FIG. 39A is a plan view illustrating the example of the method for manufacturing a semiconductor device. FIGS. 39B to 39D are cross-sectional views illustrating the example of the method for manufacturing a semiconductor device.

FIG. 40A is a plan view illustrating an example of a method for manufacturing a semiconductor device. FIGS. 40B to 40D are cross-sectional views illustrating the example of the method for manufacturing a semiconductor device.

FIG. 41A is a plan view illustrating the example of the method for manufacturing a semiconductor device. FIGS. 41B to 41D are cross-sectional views illustrating the example of the method for manufacturing a semiconductor device.

FIG. 42A is a plan view illustrating the example of the method for manufacturing a semiconductor device. FIGS. 42B to 42D are cross-sectional views illustrating the example of the method for manufacturing a semiconductor device.

FIG. 43A is a plan view illustrating the example of the method for manufacturing a semiconductor device. FIGS. 43B to 43D are cross-sectional views illustrating the example of the method for manufacturing a semiconductor device.

FIGS. 44A to 44D are cross-sectional views illustrating the example of the method for manufacturing a semiconductor device.

FIGS. 45A and 45B are cross-sectional views illustrating examples of methods for manufacturing a semiconductor device.

FIGS. 46A and 46B are cross-sectional views illustrating an example of a method for manufacturing a semiconductor device.

FIG. 47 is a block diagram illustrating a structure example of a semiconductor device.

FIGS. 48A to 48H each illustrate a circuit structure example of a memory cell.

FIGS. 49A and 49B are perspective views illustrating structure examples of semiconductor devices.

FIGS. 50A and 50B are schematic diagrams and a circuit diagram illustrating an example of a semiconductor device.

FIGS. 51A and 51B are schematic diagrams illustrating examples of semiconductor devices.

FIG. 52 is a circuit diagram illustrating an example of a semiconductor device.

FIG. 53 is a cross-sectional view illustrating an example of a semiconductor device.

FIGS. 54A and 54B are a top view and a cross-sectional view illustrating an example of a semiconductor device.

FIG. 55 is a block diagram illustrating a CPU.

FIG. 56 is a block diagram illustrating a CPU.

FIGS. 57A and 57B are perspective views of a semiconductor device.

FIGS. 58A and 58B are perspective views of semiconductor devices.

FIGS. 59A and 59B each illustrate the hierarchy of memory devices in a semiconductor device.

FIGS. 60A and 60B illustrate examples of electronic devices, and FIGS. 60C to 60E illustrate an example of a large computer.

FIG. 61 illustrates an example of a device for space.

FIG. 62 illustrates an example of a storage system that can be used in a data center.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Especially in a plan view (also referred to as a “top view”), a perspective view, or the like, some components might not be illustrated for easy understanding of the invention. In addition, some hidden lines might not be shown.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 950 is also included. In addition, the term “substantially perpendicular” indicates that the angle formed between two straight lines is greater than or equal to 70° and less than or equal to 110°.

The term “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

The term “opening” includes a groove and a slit, for example. A region where an opening is formed is referred to as an opening portion in some cases.

In the drawings used in embodiments, a sidewall of an insulator in an opening portion is illustrated as being perpendicular or substantially perpendicular to a substrate surface or a formation surface, but the sidewall may have a tapered shape.

In this specification and the like, the tapered shape refers to a shape such that at least part of a side surface of a component is inclined with respect to a substrate surface or a formation surface. For example, the tapered shape preferably includes a region where the angle between the inclined side surface and the substrate surface or the formation surface (the angle is hereinafter referred to as a taper angle in some cases) is less than 90°. Note that the side surface of the component and the substrate surface are not necessarily completely flat, and may have a substantially planar shape with a small curvature or slight unevenness.

Note that in this specification and the like, the expression “level or substantially level” indicates components having the same or substantially the same level from a reference surface (e.g., a flat surface such as a substrate surface) in a cross-sectional view. For example, in a manufacturing process of a memory device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level or substantially level” in this specification and the like. For example, the expression “level or substantially level with” also includes the case where two layers (here, a first layer and a second layer) have different levels with respect to a reference surface and the difference in the top-surface level between the first and second layers is less than or equal to 20 nm.

In this specification and the like, the expression “a side end portion is aligned or substantially aligned with another side end portion” means that at least outlines of stacked layers partly overlap with each other in a plan view. For example, the case of patterning or partly patterning an upper layer and a lower layer with the use of the same mask pattern is included. The expression “a side end portion is aligned or substantially aligned with another side end portion” also includes the case where the outlines do not exactly overlap with each other; for instance, the outline of the upper layer may be positioned inward or outward from the outline of the lower layer.

### Embodiment 1

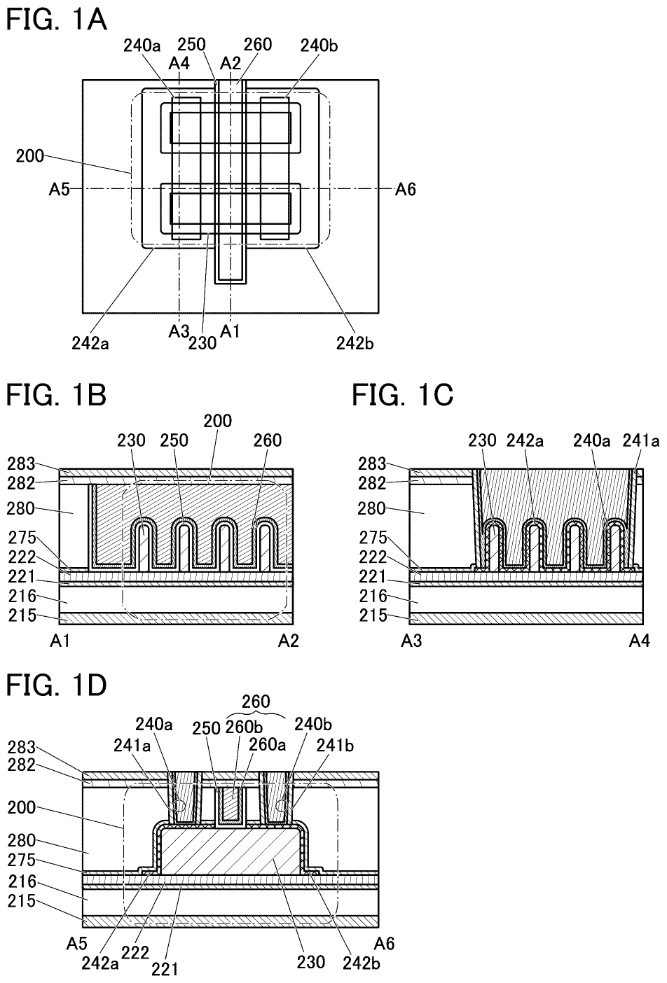

In this embodiment, a semiconductor device including an oxide semiconductor layer and a method for manufacturing the semiconductor device will be described with reference to FIGS. 1A to 46B.

### Structure Example 1 of Semiconductor Device

Structure examples of a semiconductor device will be described with reference to FIGS. 1A to 11D. FIGS. 1A to 1D are a plan view and cross-sectional views of a semiconductor device including a transistor 200 over a substrate (not illustrated).

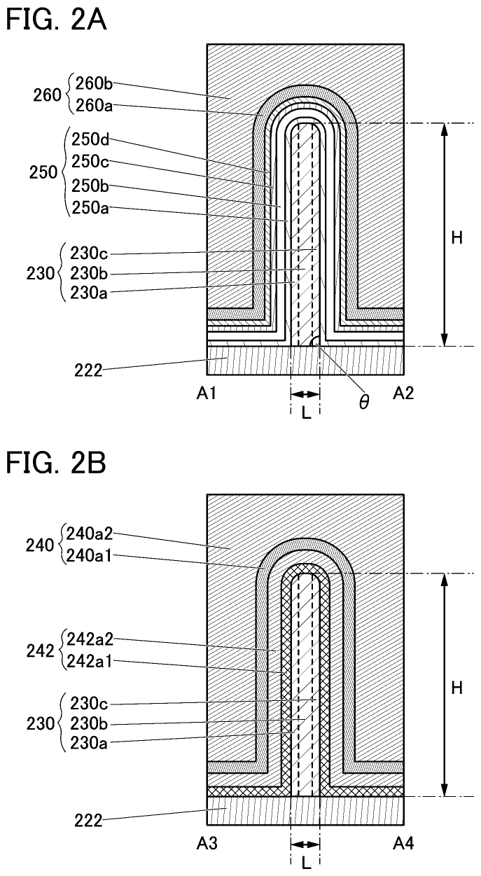

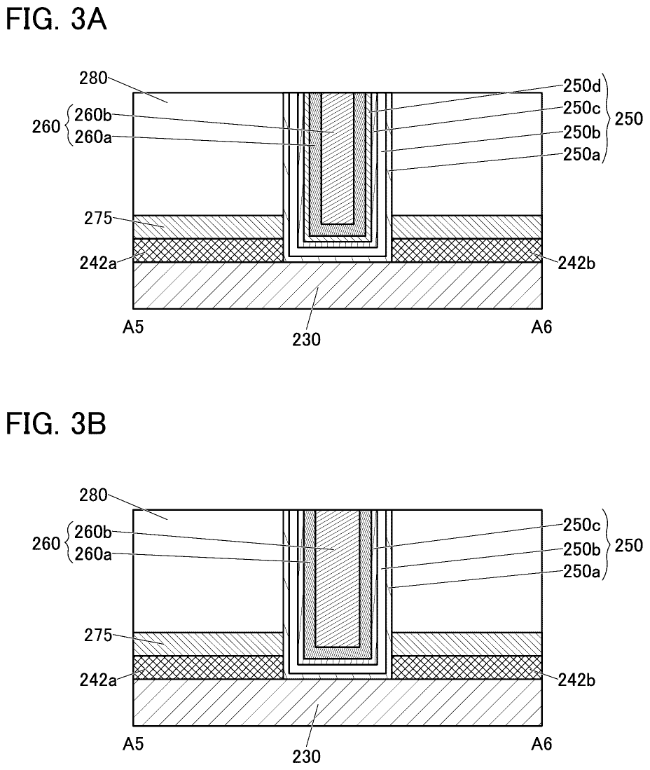

FIG. 1A is the plan view of the semiconductor device. FIGS. 1B to 1D are the cross-sectional views of the semiconductor device. FIG. 1B is a cross-section view taken along the dashed-dotted line A1-A2 in FIG. 1A, which corresponds to a cross-sectional view of the transistor 200 in the channel width direction. FIG. 1C is a cross-sectional view taken along the dashed-dotted line A3-A4 in FIG. 1A, which corresponds to a cross-sectional view of the transistor 200 in the channel width direction. FIG. 1D is a cross-sectional view taken along the dashed-dotted line A5-A6 in FIG. 1A, which corresponds to a cross-sectional view of the transistor 200 in the channel length direction. The dashed-dotted line A5-A6 is orthogonal to the dashed-dotted line A1-A2 and the dashed-dotted line A3-A4, and the dashed-dotted line A1-A2 is parallel to the dashed-dotted line A3-A4. For simplification of the drawing, some components are not illustrated and other components are illustrated in a see-through manner in the plan view of FIG. 1A. FIG. 3A is an enlarged view of a conductor 260 and its vicinity in FIG. 1D. FIG. 2A is an enlarged view of an oxide semiconductor 230 and its vicinity in FIG. 1B. FIG. 2B is an enlarged view of the oxide semiconductor 230 and its vicinity in FIG. 1C.

FIG. 2A illustrates an example in which the oxide semiconductor 230 includes an oxide semiconductor 230a, an oxide semiconductor 230b, and an oxide semiconductor 230c. The details of the oxide semiconductor 230a, the oxide semiconductor 230b, and the oxide semiconductor 230c will be described later. FIG. 2A illustrates an example in which an insulator 250 includes an insulator 250a, an insulator 250b, an insulator 250c, and an insulator 250d.

FIG. 2B illustrates an example in which the oxide semiconductor 230 includes the oxide semiconductor 230a, the oxide semiconductor 230b, and the oxide semiconductor 230c. FIG. 2B also illustrates an example in which a conductor 240a includes a conductor 240a1 and a conductor 240a2. The conductor 260, the conductor 240a, a conductor 240b, a conductor 242a, a conductor 242b, and the like each preferably have a stacked-layer structure. The details of the stacked-layer structures of the conductors will be described later.

FIG. 3A also illustrates an example in which the insulator 250 includes the insulator 250a, the insulator 250b, the insulator 250c, and the insulator 250d. The details of the insulator 250a, the insulator 250b, the insulator 250c, and the insulator 250d will be described later.

The semiconductor device of this embodiment includes an insulator 216 over the substrate (not illustrated), an insulator 221 over the insulator 216, an insulator 222 over the insulator 221, the oxide semiconductor 230 over the insulator 222, the conductor 242a and the conductor 242b over the oxide semiconductor 230 and the insulator 222, the insulator 250 over the oxide semiconductor 230, and the conductor 260 (a conductor 260a and a conductor 260b) over the insulator 250. Hereinafter, the conductor 242a and the conductor 242b are sometimes collectively referred to as a conductor 242.

An insulator 275 is provided over the conductor 242, and an insulator 280 is provided over the insulator 275. The insulator 250 and the conductor 260 are provided in an opening formed in the insulator 280 and the insulator 275. The opening reaches the oxide semiconductor 230, and the insulator 250 is in contact with the oxide semiconductor 230 in the opening. An insulator 282 is provided over the insulator 280 and the conductor 260. An insulator 283 is provided over the insulator 282. An insulator 215 is provided under the insulator 216.

An insulator 241a is provided in contact with an inner wall of an opening in the insulator 280 and the like, and the conductor 240a is provided in contact with the side surface of the insulator 241a. The bottom surface of the conductor 240a is in contact with the top surface of the conductor 242a. An insulator 241b is provided in contact with an inner wall of an opening in the insulator 280 and the like, and the conductor 240b is provided in contact with the side surface of the insulator 241b. The bottom surface of the conductor 240b is in contact with the top surface of the conductor 242b. Hereinafter, the conductor 240a and the conductor 240b are sometimes collectively referred to as a conductor 240. In addition, the insulator 241a and the insulator 241b are sometimes collectively referred to as an insulator 241.

The oxide semiconductor 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200.

The conductor 242a includes a region functioning as one of a source electrode and a drain electrode of the transistor 200. The conductor 240a functions as a plug connected to the conductor 242a. The conductor 242b includes a region functioning as the other of the source electrode and the drain electrode of the transistor 200. The conductor 240b functions as a plug connected to the conductor 242b.

The oxide semiconductor 230 is formed on the top surface of the insulator 222. As illustrated in FIGS. 2A and 2B, the oxide semiconductor 230 has a shape with a high aspect ratio in a cross-sectional view in the channel width direction. Thus, the oxide semiconductor 230 can be regarded as having a fin shape.

Note that the aspect ratio of the oxide semiconductor 230 in a cross-sectional view in the channel width direction refers to the ratio of a length H (also referred to as a height H) of the oxide semiconductor 230 in a direction perpendicular to the formation surface of the oxide semiconductor 230 (e.g., the insulator 222) to a length L (also referred to as a width L) of the oxide semiconductor 230 in the A1-A2 direction. The aspect ratio of the oxide semiconductor 230 is preferably as high as possible unless the oxide semiconductor 230 collapses in the manufacturing process of the transistor 200. The height H of the oxide semiconductor 230 is greater than at least the width L of the oxide semiconductor 230. The height H of the oxide semiconductor 230 is greater than 1 time and less than or equal to 400 times, preferably greater than or equal to 2 times and less than or equal to 100 times, further preferably greater than or equal to 5 times and less than or equal to 40 times, still further preferably greater than or equal to 10 times and less than or equal to 20 times the width L of the oxide semiconductor 230. For example, the height H may be greater than or equal to 2 times and less than or equal to 10 times the width L. The width L is, for example, greater than or equal to 5 nm and less than or equal to 100 nm, preferably greater than or equal to 5 nm and less than or equal to 50 nm, further preferably greater than or equal to 10 nm and less than or equal to 30 nm. The height H is, for example, greater than or equal to 50 nm and less than or equal to 2000 nm, preferably greater than or equal to 100 nm and less than or equal to 1000 nm. As another example, the height H may be greater than or equal to 50 nm and less than or equal to 100 nm.

As illustrated in FIG. 2A, it is preferable that the side surface of the oxide semiconductor 230 be perpendicular or substantially perpendicular to the top surface of the insulator 222 in a cross-sectional view in the channel width direction. The angle formed by the side surface of the oxide semiconductor 230 and the top surface of the insulator 222 is referred to as an angle θ. For example, the angle θ is preferably greater than or equal to 80° and less than or equal to 100°, further preferably greater than or equal to 85° and less than or equal to 95°.

The insulator 250, the conductor 260, and the conductor 242 are provided to cover the oxide semiconductor 230 having such a high aspect ratio. The insulator 250 and the conductor 260 are provided in the transistor 200 such that part of each of the insulator 250 and the conductor 260 is folded in half to sandwich the oxide semiconductor 230, as illustrated in FIGS. 1B and 2A. Thus, in a cross-sectional view in the channel width direction, the oxide semiconductor 230 and the conductor 260 face each other with the insulator 250 therebetween in the upper portion, the side surface on the A1 side, and the side surface on the A2 side of the oxide semiconductor 230. That is, the upper portion, the side surface on the A1 side, and the side surface on the A2 side of the oxide semiconductor 230 function as a channel formation region. Accordingly, the channel width of the transistor 200 is greater than that in the case where the oxide semiconductor 230 has a planar shape by the side surface on the A1 side and the side surface on the A2 side of the oxide semiconductor 230.

The transistor 200 having such a large channel width can have a high on-state current, high mutual conductance, excellent frequency characteristics, and the like. Thus, a semiconductor device with a high operation speed can be provided. In addition, the operation speed of a memory device including the semiconductor device can be increased. In the above structure, providing the oxide semiconductor 230 enables the channel width to be increased without an increase in the area occupied by the transistor 200. Accordingly, miniaturization or high integration of the semiconductor device can be achieved. Moreover, the memory capacity of the memory device including the semiconductor device can be increased. With the above structure, the area where the conductor 260 and the side surface of the oxide semiconductor 230 face each other is increased, so that the transistor 200 can be normally off by control of the threshold voltage.

As illustrated in FIG. 2A and the like, the upper portion of the oxide semiconductor 230 may have a curved shape. Such a curved shape can prevent formation of a defect such as a void in the insulator 250 and the conductor 242 in the vicinity of the upper portion of the oxide semiconductor 230. Although the upper portion of the oxide semiconductor 230 has a symmetrical structure in which both the A1 side (A3 side) and the A2 side (A4 side) of the upper portion of the oxide semiconductor 230 have a curved shape in FIGS. 2A and 2B and the like, the present invention is not limited thereto. For example, the upper portion of the oxide semiconductor 230 sometimes has an asymmetrical structure in which one of the A1 side (A3 side) and the A2 side (A4 side) of the upper portion of the oxide semiconductor 230 has a curved shape.

The oxide semiconductor 230 has a shape with a high aspect ratio and is thus preferably formed to have a sidewall shape on the side surface of a pillar (an insulator 223 described later). Accordingly, the oxide semiconductor 230 is preferably formed by an ALD method, which offers excellent coverage. In the case where the oxide semiconductor 230 has a stacked-layer structure, at least one layer, preferably a layer in contact with the pillar, is preferably formed by an ALD method.

When the oxide semiconductor 230 is formed in contact with the side surfaces of a plurality of pillars to have a sidewall shape, a plurality of fin-shaped regions can be formed concurrently in the oxide semiconductor 230 as illustrated in FIG. 1A. When the plurality of fin-shaped regions are formed in this manner, the distances between the fin-shaped regions can be independently set in accordance with the sizes and shapes of the pillars. This can reduce the distances between the fin-shaped regions, leading to a reduction in the area occupied by the transistor 200 and high integration of the semiconductor device.

Since the oxide semiconductor 230 is formed in contact with the pillar to have a sidewall shape, the top surface shape of the oxide semiconductor 230 is an enclosing shape with no endpoints (which can also be referred to as a frame shape, a ring shape, a doughnut shape, or a closed-curve shape) as illustrated in FIG. 1A. The oxide semiconductor 230 can also be regarded as having an opening in the center portion. Although the top surface shape of the oxide semiconductor 230 is a line-symmetrical shape with respect to the line A1-A2 in FIG. 1A, the present invention is not limited thereto. For example, the top surface shape of the oxide semiconductor 230 may be an asymmetrical shape.

In the structure illustrated in FIG. 1A, two pillars are arranged in the A1-A2 direction and the enclosing-shaped oxide semiconductor 230 is formed in contact with the side surface of each of the pillars. As illustrated in FIG. 1A, the oxide semiconductor 230 preferably overlaps with the conductor 260 at two or more points in a top view. That is, there are two or more regions where the oxide semiconductor 230 and the conductor 260 overlap with each other. With such a structure, the plurality of fin-shaped regions are formed in the oxide semiconductor 230 in a cross-sectional view in the channel width direction as illustrated in FIG. 1B. The plurality of fin-shaped regions each function as a channel formation region. That is, the transistor 200 functions as a multi-channel transistor. Thus, the transistor 200 can have a larger channel width.

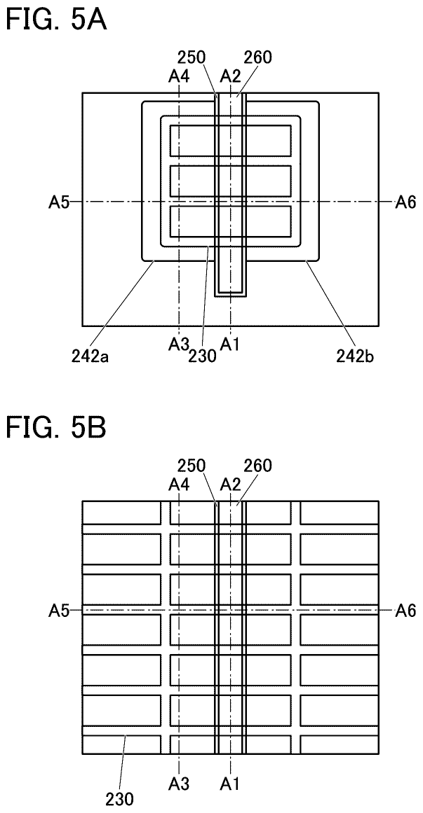

Although the structure in which the two enclosing-shaped oxide semiconductors 230 are provided is described above, the present invention is not limited thereto. For example, one or three or more enclosing-shaped oxide semiconductors 230 may be provided. Alternatively, the enclosing-shaped oxide semiconductors 230 may be bonded to each other to form the oxide semiconductor 230 having a plurality of openings. For example, as illustrated in FIG. 5A, the oxide semiconductor 230 can have a shape in which three openings are arranged in the A1-A2 direction in a top view. In that case, three pillars are formed to be adjacent to each other at a short distance, and the oxide semiconductor 230 is formed between the pillars. As another example, as illustrated in FIG. 5B, the oxide semiconductor 230 can have a lattice shape in a top view. In that case, a lattice-shaped trench is formed in the pillar, and the oxide semiconductor 230 is formed to fill the trench. Note that the number of oxide semiconductors 230 is not limited to two and can be one or three or more. As described above, the oxide semiconductor 230 preferably has a plurality of portions extending in the channel width direction (A1-A2 direction) and a plurality of portions extending in the channel length direction (A5-A6 direction). This can inhibit the oxide semiconductor 230 from collapsing during the manufacturing process of the transistor even when the oxide semiconductor 230 has a high aspect ratio.

In the oxide semiconductor 230, a channel formation region and source and drain regions of the transistor 200 are formed. The channel formation region is sandwiched between the source and drain regions. At least a part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower concentration of impurities than the source and drain regions, and thus is a high-resistance region with a low carrier concentration. Thus, the channel formation region can be regarded as an i-type (intrinsic) or substantially i-type region.

The source and drain regions have a large amount of oxygen vacancies or a high concentration of impurities such as hydrogen, nitrogen, or a metal element, and thus are low-resistance regions with a high carrier concentration. In other words, the source and drain regions are n-type regions (low-resistance regions) having a higher carrier concentration than the channel formation region.

Note that the carrier concentration in the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration of the oxide semiconductor 230, the concentration of impurities in the oxide semiconductor 230 is reduced so that the density of defect states is reduced. In this specification and the like, a state with a low concentration of impurities and a low density of defect states is referred to as a highly purified intrinsic or substantially highly purified intrinsic state. Note that an oxide semiconductor (or metal oxide) having a low carrier concentration may be referred to as a highly purified intrinsic or substantially highly purified intrinsic oxide semiconductor (or metal oxide).

In order to obtain stable electrical characteristics of the transistor 200, reducing the concentration of impurities in the channel formation region of the oxide semiconductor 230 is effective. In order to reduce the concentration of impurities in the oxide semiconductor 230, the concentration of impurities in a film adjacent to the oxide semiconductor 230 is preferably reduced. Examples of the impurities include hydrogen, nitrogen, an alkali metal, an alkaline earth metal, iron, nickel, and silicon. Note that impurities in the oxide semiconductor 230 refer to, for example, elements other than the main components of the oxide semiconductor 230. For example, an element with a concentration lower than 0.1 atomic % is regarded as an impurity.

In the oxide semiconductor 230, it is sometimes difficult to clearly observe the boundaries between the regions. The concentrations of a metal element and an impurity element such as hydrogen or nitrogen, which are detected in each region, may be not only gradually changed between the regions but also continuously changed in each region. That is, the region closer to the channel formation region may have lower concentrations of a metal element and an impurity element such as hydrogen or nitrogen.

If impurities and oxygen vacancies are present in a channel formation region in an oxide semiconductor, a transistor including the oxide semiconductor may have variable electrical characteristics and poor reliability. In some cases, hydrogen in the vicinity of an oxygen vacancy forms a defect that is an oxygen vacancy into which hydrogen has entered (hereinafter sometimes referred to as VoH), which generates an electron serving as a carrier. Therefore, when the channel formation region in the oxide semiconductor includes oxygen vacancies, the transistor tends to have normally-on characteristics (with which the channel is generated even when no voltage is applied to the gate electrode, and current flows through the transistor). Therefore, the impurities, oxygen vacancies, and VoH are preferably reduced as much as possible in the channel formation region in the oxide semiconductor. In other words, the channel formation region in the oxide semiconductor is preferably an i-type (intrinsic) or substantially i-type region with a reduced carrier concentration.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that the electrical characteristics and reliability of the transistor might be adversely affected.

Therefore, the oxide semiconductor preferably includes an i-type or substantially i-type channel formation region with a low carrier concentration and n-type source and drain regions with a high carrier concentration. That is, the amounts of oxygen vacancies and VoH in the channel formation region of the oxide semiconductor are preferably reduced. Excessive supply of oxygen to the source and drain regions and excessive reduction in the amount of VoH in the source and drain regions are preferably inhibited. Furthermore, a reduction in the conductivity of the conductors 260, 242a, and 242b and the like is preferably inhibited. For example, oxidation of the conductors 260, 242a, and 242b and the like is preferably inhibited. Note that hydrogen in an oxide semiconductor can form VoH; thus, the hydrogen concentration needs to be reduced in order to reduce the amount of VoH.

The semiconductor device of this embodiment thus has a structure in which the hydrogen concentration in the channel formation region is reduced, oxidation of the conductors 242a, 242b, and 260 is inhibited, and the hydrogen concentration in the source and drain regions is inhibited from being reduced.

A conductive material that is less likely to be oxidized or a conductive material having a function of inhibiting diffusion of oxygen is preferably used for the conductors 242a, 242b, and 260. Examples of the conductive material include a conductive material containing nitrogen and a conductive material containing oxygen. This can inhibit a reduction in the conductivity of the conductors 242a, 242b, and 260. In the case where a conductive material containing a metal and nitrogen is used for each of the conductors 242a, 242b, and 260, the conductors 242a, 242b, and 260 contain at least a metal and nitrogen.

The conductor 242a and the conductor 242b are provided apart from each other and in contact with the oxide semiconductor 230. As illustrated in FIG. 2B and the like, the conductor 242 is provided to cover the oxide semiconductor 230 having a high aspect ratio. As illustrated in FIG. 1C, the conductor 242a (the conductor 242b) is preferably in contact with two or more fin-shaped regions of the oxide semiconductor 230 in a cross-sectional view.

The conductor 242a is provided such that the conductor 242a is folded in half to sandwich the oxide semiconductor 230 in the vicinity of the source or the drain of the transistor 200 as illustrated in FIG. 2B. Thus, the conductor 242a is in contact with the oxide semiconductor 230 in the upper portion, the side surface on the A3 side, and the side surface on the A4 side of the oxide semiconductor 230 in a cross-sectional view in the channel width direction. Accordingly, the contact area between the conductor 242a and the oxide semiconductor 230 is larger than that in the case where the oxide semiconductor 230 has a planar shape by the side surface on the A3 side and the side surface on the A4 side of the oxide semiconductor 230. The structure illustrated in FIG. 1C in which the conductor 242a is in contact with the plurality of fin-shaped regions of the oxide semiconductor 230 can further increase the contact area. Although FIGS. 2B and 1C illustrate the conductor 242a and its vicinity, the same applies to the conductor 242b. That is, the contact area between the conductor 242b and the oxide semiconductor 230 increases like that between the conductor 242a and the oxide semiconductor 230.

The increase in the contact area between the conductor 242 and the oxide semiconductor 230 enables the transistor 200 to have a high on-state current, excellent frequency characteristics, and the like without an increase in the area occupied by the transistor 200. Thus, a semiconductor device with a high operation speed can be provided. In addition, the operation speed of a memory device including the semiconductor device can be increased. Accordingly, miniaturization or high integration of the semiconductor device can be achieved. Moreover, the memory capacity of the memory device including the semiconductor device can be increased.

Since the conductors 242a and 242b are in contact with the oxide semiconductor 230, a conductive material that is less likely to be oxidized or a conductive material having a function of inhibiting diffusion of oxygen is preferably used for the conductors 242a and 242b. This can inhibit a reduction in the conductivity of the conductors 242a and 242b. This can also inhibit oxygen extraction from the oxide semiconductor 230 and formation of an excessive amount of oxygen vacancies. For the conductors 242a and 242b, a material that is likely to absorb (extract) hydrogen is preferably used, in which case the hydrogen concentration in the oxide semiconductor 230 can be reduced.

For the conductor 242, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

Note that hydrogen contained in the oxide semiconductor 230 or the like diffuses into the conductor 242a or 242b in some cases. In particular, when a nitride containing tantalum is used for the conductors 242a and 242b, hydrogen contained in the oxide semiconductor 230 or the like is likely to diffuse into the conductor 242a or 242b, and the diffused hydrogen is bonded to nitrogen contained in the conductor 242a or 242b in some cases. That is, hydrogen contained in the oxide semiconductor 230 or the like is sometimes absorbed by the conductor 242a or 242b.

In order to inhibit a reduction in the conductivity of the conductors 242a and 242b, an oxide having crystallinity, such as a CAAC-OS, is preferably used as the oxide semiconductor 230. In particular, a metal oxide containing indium, zinc, and one or more selected from gallium, aluminum, and tin is preferably used. The use of the CAAC-OS can inhibit the conductor 242a or 242b from extracting oxygen from the oxide semiconductor 230. In addition, a reduction in the conductivity of the conductors 242a and 242b can be inhibited.

The conductors 242a and 242b each preferably have a two-layer structure. The conductor 242a can be a stacked-layer film of a conductor 242al and a conductor 242a2 over the conductor 242al, and the conductor 242b can be a stacked-layer film of a conductor 242b1 and a conductor 242b2 over the conductor 242b1. At this time, the conductive material that is less likely to be oxidized or the conductive material having a function of inhibiting diffusion of oxygen described above is preferably used for layers (the conductors 242a1 and 242b1) in contact with the oxide semiconductor 230. This can inhibit a reduction in the conductivity of the conductors 242a and 242b. This can also inhibit oxygen extraction from the oxide semiconductor 230 and formation of an excessive amount of oxygen vacancies. For layers (the conductors 242al and 242b1) in contact with the oxide semiconductor 230, a material that is likely to absorb (extract) hydrogen is preferably used, in which case the hydrogen concentration in the oxide semiconductor 230 can be reduced.

The conductors 242a2 and 242b2 preferably have higher conductivity than the conductors 242al and 242b1. For example, the thicknesses of the conductors 242a2 and 242b2 are preferably larger than those of the conductors 242al and 242b1. For the conductors 242a2 and 242b2, a conductor that can be used as the conductor 260b described later may be used. The above structure can reduce the resistances of the conductors 242a2 and 242b2. This can increase the on-state current of the transistor 200 and improve the operation speed of the semiconductor device of this embodiment.

For example, tantalum nitride or titanium nitride can be used for the conductors 242al and 242b1, and tungsten can be used for the conductors 242a2 and 242b2.

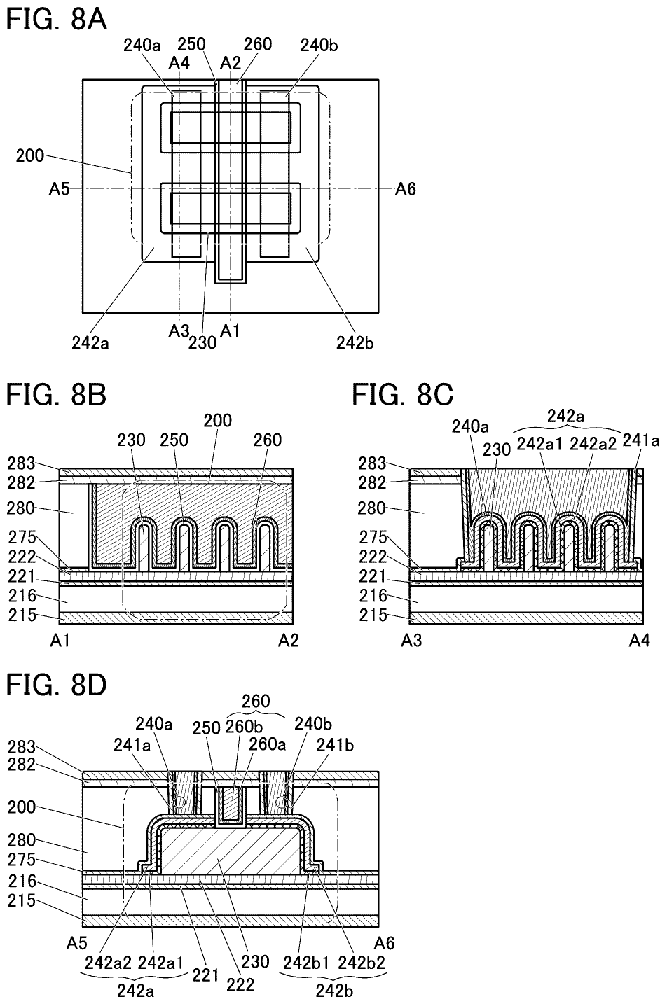

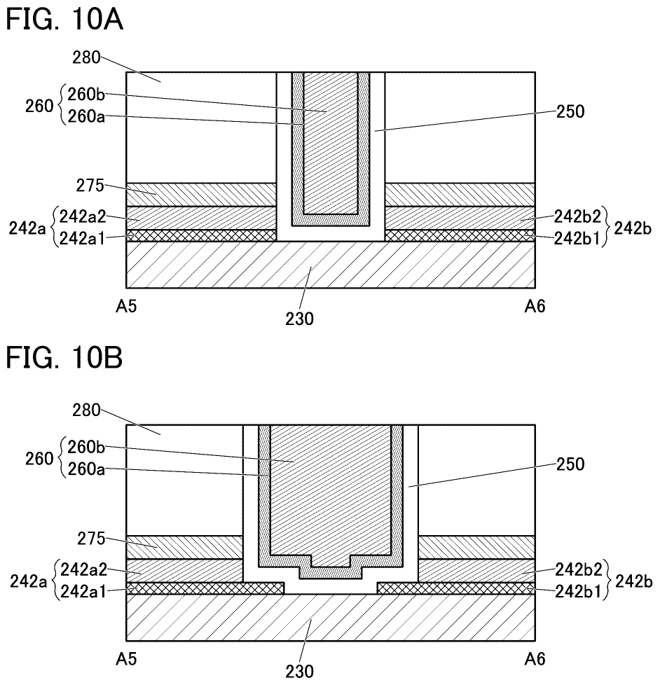

FIGS. 8A to 8D illustrate an example of a semiconductor device in which the conductors 242a and 242b in the structure illustrated in FIGS. 1A to 1D each have a stacked-layer structure of two layers. FIG. 10A is an enlarged view of the conductor 260 and its vicinity in FIG. 8D.

As illustrated in FIGS. 1B and 1D, the conductor 260 is provided in the opening formed in the insulators 280 and 275. The conductor 260 is formed in the opening to cover the top surface of the insulator 222 and the top and side surfaces of the oxide semiconductor 230 with the insulator 250 therebetween. The top surface of the conductor 260 is positioned to be level or substantially level with the uppermost portion of the insulator 250 and the top surface of the insulator 280.

Note that the sidewall of the opening in which the conductor 260 and the insulator 250 are provided may be perpendicular or substantially perpendicular to the top surface of the insulator 222 or may have a tapered shape. The sidewall with a tapered shape can improve the coverage with the insulator 250 and the like formed in the opening in the insulator 280, so that the number of defects such as voids can be reduced.

The conductor 260 functions as the first gate electrode of the transistor 200. Here, the conductor 260 is preferably provided to extend in the channel width direction as illustrated in FIGS. 1A and 1B. With such a structure, the conductor 260 functions as a wiring when a plurality of transistors are provided.

The conductor 260 is provided such that part of the conductor 260 is folded in half to sandwich the fin-shaped oxide semiconductor 230. Thus, as illustrated in FIG. 2A, the oxide semiconductor 230 and the conductor 260 face each other with the insulator 250 therebetween in the upper portion, the side surface on the A1 side, and the side surface on the A2 side of the oxide semiconductor 230 in a cross-sectional view in the channel width direction. That is, the upper portion, the side surface on the A1 side, and the side surface on the A2 side of the oxide semiconductor 230 function as a channel formation region. Accordingly, the channel width of the transistor 200 is greater than that in the case where the oxide semiconductor 230 has a planar shape by the side surface on the A1 side and the side surface on the A2 side of the oxide semiconductor 230.

FIG. 1D and the like illustrate the conductor 260 having a two-layer structure. Here, the conductor 260 preferably includes the conductor 260a and the conductor 260b over the conductor 260a. For example, the conductor 260a is preferably placed to cover the bottom and side surfaces of the conductor 260b. In that case, a conductive material that is less likely to be oxidized or a conductive material having a function of inhibiting diffusion of oxygen is preferably used for the conductor 260a.

The conductor 260a is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 260a is preferably formed using a conductive material having a function of inhibiting diffusion of oxygen (e.g., at least one of oxygen atoms and oxygen molecules).

When the conductor 260a has a function of inhibiting diffusion of oxygen, the conductivity of the conductor 260b can be inhibited from being lowered because of oxidization of the conductor 260b due to oxygen in the insulator 280 and the like. As the conductive material having a function of inhibiting diffusion of oxygen, for example, titanium, titanium nitride, tantalum, tantalum nitride, or ruthenium is preferably used. Ruthenium has conductivity even when oxidized and thus can be inhibited from having a reduced conductivity even when oxygen is taken into ruthenium. Accordingly, ruthenium and ruthenium oxide can maintain low conductivity even when provided in contact with an insulator from which oxygen is released, for example.

The conductor 260b is preferably formed using a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner to fill the opening formed in the insulator 280 and the like. Here, the side surface of the insulator 280 in the above opening is aligned or substantially aligned with the side surface of the conductor 242a and the side surface of the conductor 242b. Accordingly, the conductor 260 can be provided to overlap with a region between the conductor 242a and the conductor 242b without alignment.

The insulators 216 and 280 preferably have a lower dielectric constant than the insulator 222. In the case where a material with a low dielectric constant is used for an interlayer film, parasitic capacitance between wirings can be reduced.

For example, each of the insulators 216 and 280 preferably contains one or more of silicon oxide, silicon oxynitride, silicon oxide to which fluorine is added, silicon oxide to which carbon is added, silicon oxide to which carbon and nitrogen are added, and porous silicon oxide.

Silicon oxide and silicon oxynitride are particularly preferable because of their thermal stability. In particular, materials such as silicon oxide, silicon oxynitride, and porous silicon oxide are preferably used, in which case a region containing oxygen released by heating can be easily formed.

Each of the top surfaces of the insulators 216 and 280 may be planarized.

The concentration of an impurity such as water or hydrogen in the insulator 280 is preferably reduced. For example, the insulator 280 preferably contains an oxide containing silicon such as silicon oxide or silicon oxynitride.

Each of the conductors 240a and 240b is formed in an opening in the insulator 275, the insulator 280, the insulator 282, and the insulator 283. The bottom surface of the conductor 240a is in contact with the top surface of the conductor 242a, and the bottom surface of the conductor 240b is in contact with the top surface of the conductor 242b. The top surface of the conductor 240 is substantially level with the top surface of the insulator 283.

The conductor 240 is preferably formed using a conductive material containing tungsten, copper, or aluminum as its main component. The conductor 240 may have a stacked-layer structure in which a first conductor is provided in contact with the side surface of the insulator 241 and a second conductor is provided inward from the first conductor. In that case, the second conductor can be formed using the above conductive material. The first conductor corresponds to the conductor 240al and the conductor 240b1 illustrated in FIG. 2B. The second conductor corresponds to the conductor 240a2 and the conductor 240b2 illustrated in FIG. 2B.

In the case where the conductor 240 has a stacked-layer structure, a conductive material having a function of inhibiting passage of impurities such as water and hydrogen is preferably used as the first conductor located in the vicinity of the insulators 283, 282, 280, and 275. For example, tantalum, tantalum nitride, titanium, titanium nitride, ruthenium, or ruthenium oxide is preferably used. The conductive material having a function of inhibiting passage of impurities such as water and hydrogen can be used as a single layer or stacked layers. With such a structure, impurities such as water and hydrogen contained in the components above the insulator 283 can be inhibited from entering the oxide semiconductor 230 through the conductors 240a and 240b.

Each of the insulators 241a and 241b is formed in contact with the inner wall of the opening in the insulators 275, 280, 282, and 283. The inner side surface of the insulator 241a is in contact with the conductor 240a, and the inner side surface of the insulator 241b is in contact with the conductor 240b.

For the insulator 241, a barrier insulating film that can be used for the insulator 275 or the like is used. For the insulator 241, for example, an insulator such as silicon nitride, aluminum oxide, or silicon nitride oxide can be used. With the insulator 241, impurities such as water and hydrogen contained in the insulator 280 or the like can be inhibited from entering the oxide semiconductor 230 through the conductors 240a and 240b. Silicon nitride is particularly preferable because of its high blocking property against hydrogen. Furthermore, oxygen contained in the insulator 280 can be prevented from being absorbed by the conductors 240a and 240b.

In the case where the insulator 241 has a stacked-layer structure as illustrated in FIG. 1D, a combination of a barrier insulating film against oxygen and a barrier insulating film against hydrogen is preferably used for a first insulator that is in contact with an inner wall of the opening provided in the insulator 280 and the like and a second insulator located inward from the first insulator.

For example, an aluminum oxide film formed by a thermal ALD method can be used as the first insulator, and a silicon nitride film formed by a PEALD method can be used as the second insulator. With this structure, oxidation of the conductor 240 can be inhibited, and hydrogen can be inhibited from entering the conductor 240.

Although the insulator 241 has a two-layer structure in the above example, the present invention is not limited thereto. For example, the insulator 241 may have a single-layer structure or a stacked-layer structure of three or more layers. Although the conductor 240 has a two-layer structure in the above example, the present invention is not limited thereto. For example, the conductor 240 may have a single-layer structure or a stacked-layer structure of three or more layers.

As illustrated in FIG. 2B, for example, the conductor 240a may cover the oxide semiconductor 230 and the conductor 242a that is folded in half to sandwich the oxide semiconductor 230. Thus, the conductor 240a is in contact with the conductor 242a in the upper portion, the side surface on the A3 side, and the side surface on the A4 side of the oxide semiconductor 230 in a cross-sectional view in the channel width direction. Accordingly, the contact area between the conductor 240a and the conductor 242a is larger than that in the case where the oxide semiconductor 230 has a planar shape by the side surface on the A3 side and the side surface on the A4 side of the oxide semiconductor 230. The structure illustrated in FIG. 1C in which the plurality of fin-shaped regions of the oxide semiconductor 230 are covered with the conductor 240a can further increase the contact area between the conductor 240a and the conductor 242a. Although FIGS. 2B and 1C illustrate the conductor 240a, the conductor 242a, and their vicinities, the same applies to the conductor 240b and the conductor 242b. That is, the contact area between the conductor 240b and the conductor 242b increases like that between the conductor 240a and the conductor 242a.

The increase in the contact area between the conductor 240 and the conductor 242 can reduce the contact resistance between the conductor 240 and the conductor 242. This enables the transistor 200 to have a high on-state current, excellent frequency characteristics, and the like without an increase in the area occupied by the transistor 200. Thus, a semiconductor device with a high operation speed can be provided. In addition, the operation speed of a memory device including the semiconductor device can be increased. Accordingly, miniaturization or high integration of the semiconductor device can be achieved. Moreover, the memory capacity of the memory device including the semiconductor device can be increased.

Although the opening in which the conductor 240 and the insulator 241 are provided has a quadrangular shape in a top view as illustrated in FIG. 1A, the shape of the opening is not limited thereto. For example, the opening in a top view may have a circular shape, an almost circular shape such as an elliptical shape, a polygonal shape such as a quadrangular shape, or a polygonal shape such as a quadrangular shape with rounded corners.

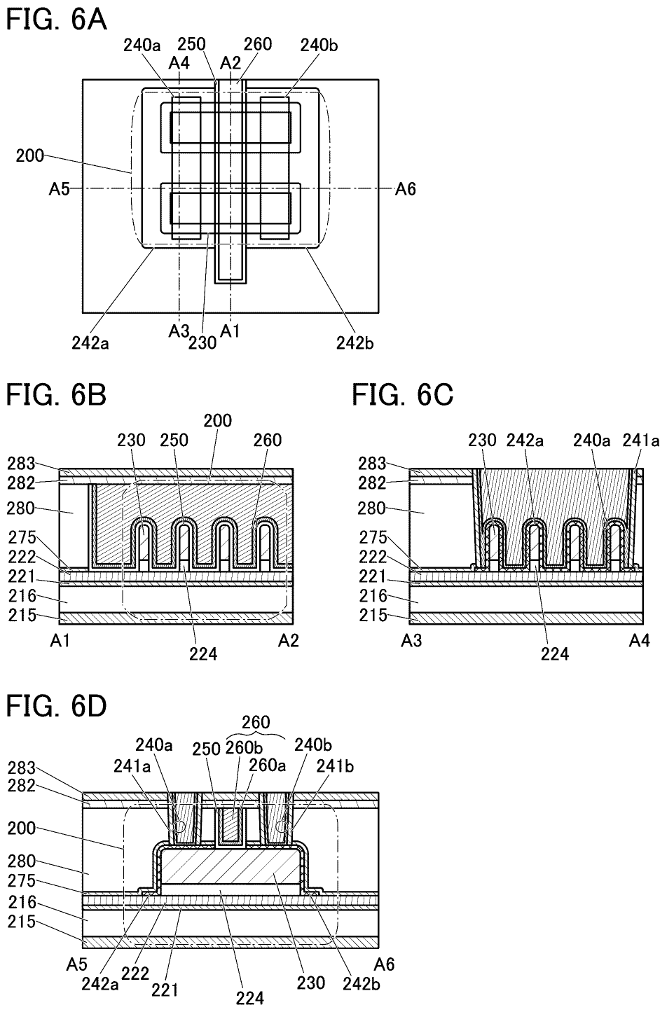

The semiconductor device of this embodiment may have a structure in which an insulator 224 is provided under the oxide semiconductor 230 as illustrated in FIGS. 6A to 6D. The top surface shape of the insulator 224 is similar to that of the oxide semiconductor 230, and the insulator 224 overlaps with the oxide semiconductor 230 in a top view. The bottom surface of the insulator 224 is in contact with the insulator 222, the side surface of the insulator 224 is in contact with the insulator 250 and the conductor 242a, and the top surface of the insulator 224 is in contact with the bottom surface of the oxide semiconductor 230. The insulator 224 is formed using an insulating material that can be used for the insulator 250b. For example, silicon oxide can be used for the insulator 224. FIGS. 6A to 6D correspond to FIGS. 1A to 1D; thus, refer to the above description for the detailed structure.

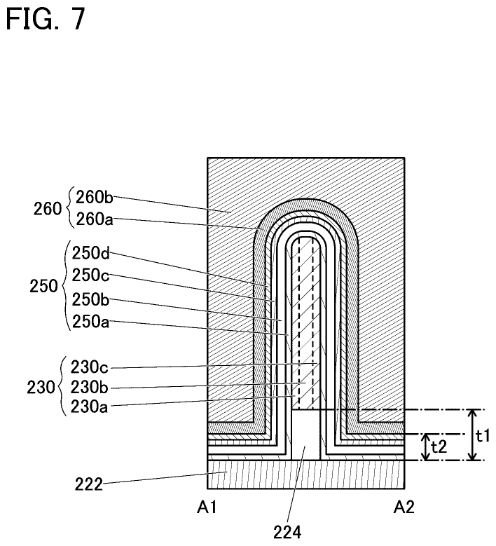

As illustrated in FIG. 7, a thickness t2 of the insulator 250 in the opening in the insulator 280 and the insulator 275 is preferably smaller than a thickness t1 of the insulator 224. With such a structure, the level of the bottom surface of the conductor 260 (the conductor 260a) positioned in the opening can be lower than the level of the bottom surface of the oxide semiconductor 230 by a difference between the thickness t1 and the thickness t2 (t1-t2).

When the level of the bottom surface of the conductor 260 is lower than the level of the bottom surface of the oxide semiconductor 230, a gate electric field can be adequately applied to the oxide semiconductor 230 from its upper end portion to its lower end portion. In other words, in the opening in the insulator 280 and the like, the entire oxide semiconductor 230 can be electrically surrounded by the electric field of the conductor 260 to function as a channel formation region. Such a structure can prevent the lower end portion of the oxide semiconductor 230 from functioning as a parasitic channel, thereby reducing leakage current between the source electrode and the drain electrode. In addition, poor characteristics of the transistor due to the parasitic channel, such as normally-on characteristics, can be inhibited. That is, the transistor 200 can have excellent electrical characteristics.

When a region from the upper end portion to the lower end portion of the oxide semiconductor 230 functions as a channel formation region as described above, the channel width can be increased. Thus, the transistor 200 can have a high on-state current, high mutual conductance, excellent frequency characteristics, and the like.

In this specification and the like, a transistor structure in which a channel formation region is electrically surrounded by the electric field of a gate electrode as described above is referred to as a surrounded channel (S-channel) structure. In the S-channel structure, at least two surfaces (specifically, two surfaces, three surfaces, four surfaces, or the like) of a channel are covered with the gate electrode. With the S-channel structure, resistance to a short-channel effect can be enhanced; that is, a transistor in which a short-channel effect is less likely to occur can be provided.

Since the S-channel structure is a structure with the electrically surrounded channel formation region, the S-channel structure is, in a sense, equivalent to a gate-all-around (GAA) structure or a lateral gate-all-around (LGAA) structure. When the transistor 200 has any of the S-channel structure, the GAA structure, and the LGAA structure, the channel formation region formed at the interface between the oxide semiconductor 230 and the gate insulator or in the vicinity thereof can correspond to the whole bulk of the oxide semiconductor 230. Consequently, the density of current flowing through the transistor can be improved, so that the on-state current or field-effect mobility of the transistor can be increased. In one embodiment of the present invention, the oxide semiconductor 230 has a CAAC structure and a fin shape. With this structure, a path of current flowing between the source and the drain of the transistor can be parallel to the a-b axis plane of a crystal. In other words, the oxide semiconductor having the CAAC structure and the fin shape has a conduction path equivalent to that of a two-dimensional semiconductor material. With the use of such an oxide semiconductor, a device having two-dimensional conduction can be manufactured.

### Modification Example 1-1 of Semiconductor Device

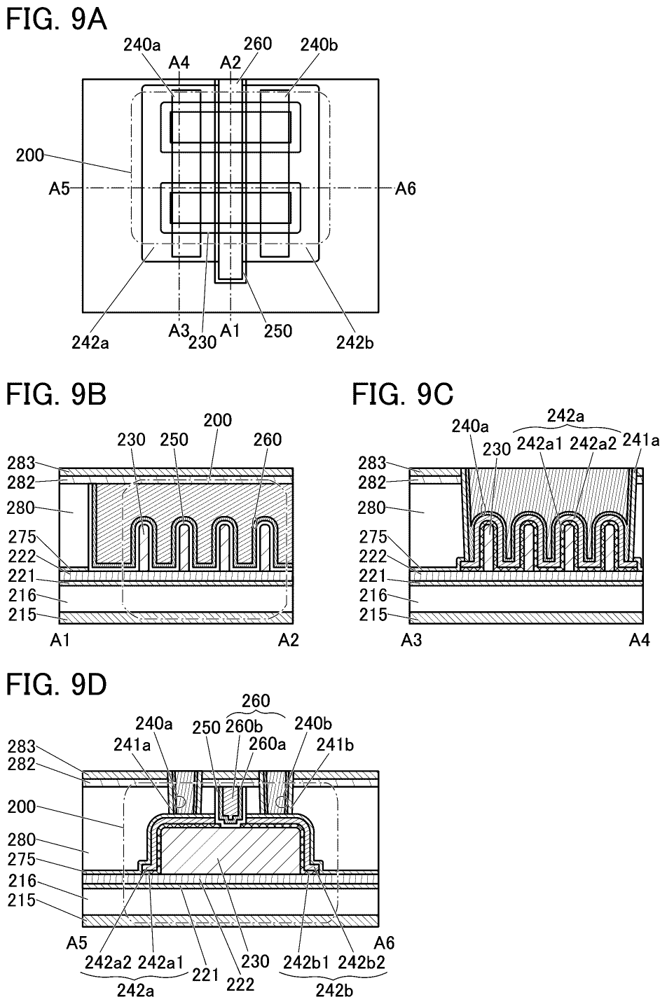

A semiconductor device illustrated in FIGS. 9A to 9D is different from that in FIGS. 8A to 8D mainly in that the conductors 242a1 and 242b1 extend beyond the conductors 242a2 and 242b2, respectively, in a cross-sectional view of the transistor 200 in the channel length direction. FIG. 10B is an enlarged view of the conductor 260 and its vicinity in FIG. 9D.

The extending portions of the conductor 242al and the conductor 242b1 are covered with the insulator 250. The distance between the conductor 242a1 and the conductor 242b1 is shorter than the distance between the conductor 242a2 and the conductor 242b2. With such a structure, the distance between the source and the drain can be shortened, and the channel length can be accordingly shortened. This can improve the frequency characteristics of the transistor 200. In this manner, miniaturization of the semiconductor device enables the semiconductor device to have a higher operation speed.

### Modification Example 1-2 of Semiconductor Device

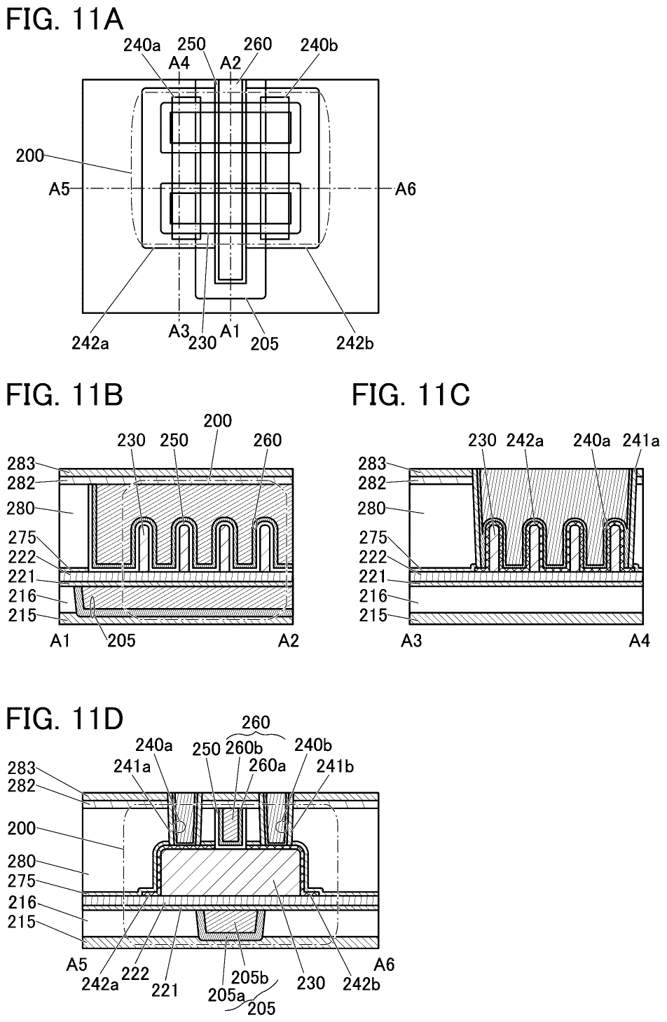

The semiconductor device of this embodiment may have a structure in which a conductor 205 is provided under the insulator 221 as illustrated in FIGS. 11A to 11D. The conductor 205 includes a region functioning as a second gate electrode (a lower gate electrode) of the transistor 200. Each of the insulators 222 and 221 includes a region functioning as a second gate insulator of the transistor 200. FIGS. 11A to 11D correspond to FIGS. 1A to 1D; thus, refer to the above description for the detailed structure.

In the transistor 200, the conductor 205 is provided to overlap with the oxide semiconductor 230 and the conductor 260. Here, the conductor 205 is preferably provided to fill an opening formed in the insulator 216. The conductor 205 is preferably provided to extend in the channel width direction as illustrated in FIGS. 11A and 11B. With such a structure, the conductor 205 functions as a wiring when a plurality of transistors are provided.

As illustrated in FIGS. 11B and 11D, the conductor 205 preferably includes a conductor 205a and a conductor 205b. The conductor 205a is provided in contact with the bottom surface and the sidewall of the opening. The conductor 205b is provided to fill a depressed portion formed by the conductor 205a along the opening. Here, the top surface of the conductor 205 is level or substantially level with the top surface of the insulator 216.

Here, the conductor 205a preferably contains a conductive material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms. Alternatively, the conductor 205a preferably contains a conductive material having a function of inhibiting diffusion of oxygen (e.g., at least one of oxygen atoms and oxygen molecules).

When a conductive material having a function of inhibiting diffusion of hydrogen is used for the conductor 205a, impurities such as hydrogen contained in the conductor 205b can be prevented from diffusing into the oxide semiconductor 230 through the insulator 216 and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, and ruthenium. Ruthenium has conductivity even when oxidized and thus can be inhibited from having a reduced conductivity even when oxygen is taken into ruthenium. Ruthenium and ruthenium oxide can maintain low conductivity even when provided in contact with an insulator from which oxygen is released, for example. The conductor 205a can have a single-layer structure or a stacked-layer structure of the above conductive material. For example, the conductor 205a preferably contains titanium nitride.

The conductor 205b is preferably formed using a conductive material containing tungsten, copper, or aluminum as its main component. For example, the conductor 205b preferably contains tungsten.

The conductor 205 can function as the second gate electrode. In that case, by changing a potential applied to the conductor 205 not in conjunction with but independently of a potential applied to the conductor 260, the threshold voltage (Vₜₕ) of the transistor 200 can be controlled. In particular, by applying a negative potential to the conductor 205, Vₜₕ of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is determined in accordance with the electrical resistivity. The thickness of the insulator 216 is substantially equal to that of the conductor 205. The conductor 205 and the insulator 216 are preferably as thin as possible in the allowable range of the design of the conductor 205. The insulator 216 with a reduced thickness contains a smaller absolute amount of impurities such as hydrogen, inhibiting the diffusion of the impurities into the oxide semiconductor 230.

Although the stacked-layer structure of the conductor 205a and the conductor 205b is described above, the present invention is not limited to this structure. The conductor 205 may have a single-layer structure or a stacked-layer structure of three or more layers. For example, in the case where the conductor 205 has a three-layer structure, a conductor that contains the same material as the conductor 205a can be further provided over the conductor 205b of the above-described stacked-layer structure of the conductors 205a and 205b. In that case, the level of the top surface of the conductor 205b may be lower than the level of the uppermost portion of the conductor 205a, and the aforementioned conductor may be formed to fill the depressed portion formed by the conductors 205a and 205b.

### Structure Example 2 of Semiconductor Device

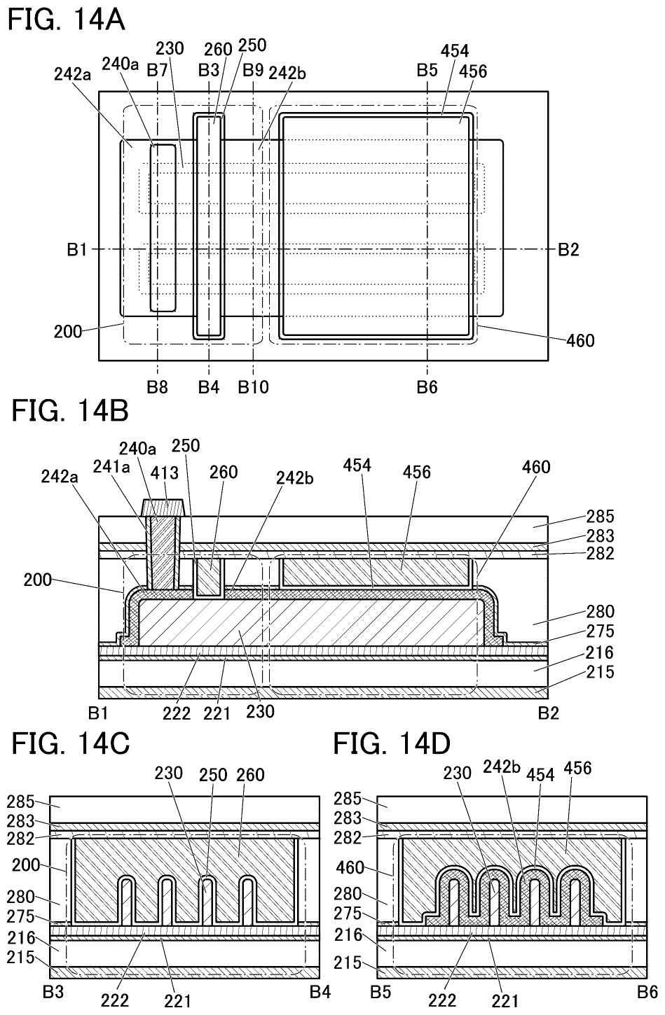

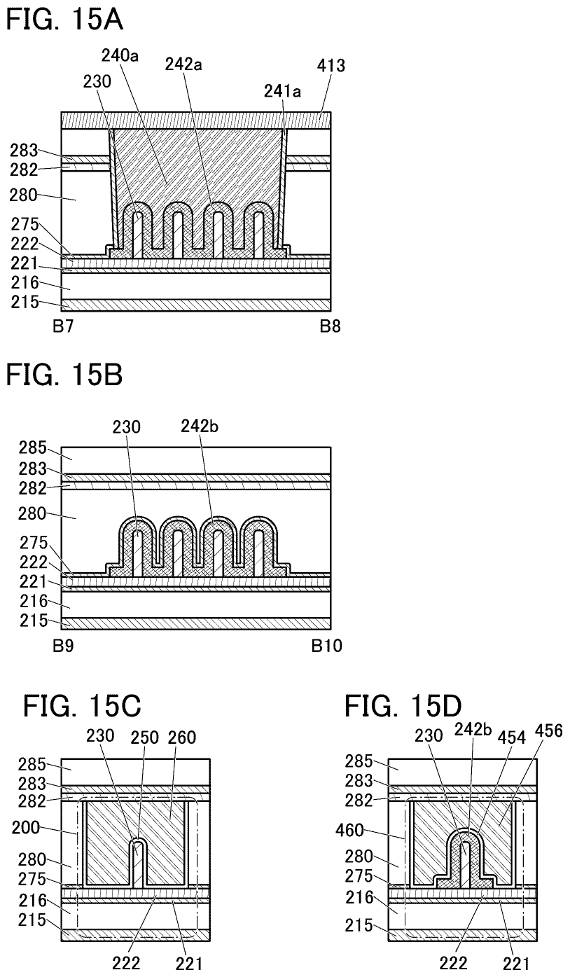

Structure examples of a semiconductor device will be described with reference to FIGS. 14A to 15D.

The structure illustrated in FIGS. 14A to 15B is a one-transistor and one-capacitor (1T1C) memory cell including the transistor 200 described above and a capacitor 460. A semiconductor device including a memory cell can function as a memory device. A plurality of memory cells can be arranged in a matrix to form a memory array (also referred to as a memory cell array). The memory device includes, for example, a memory array and a driver circuit for driving the memory array.

FIG. 14A is a plan view of the memory cell. FIG. 14B is a cross-sectional view taken along the dashed-dotted line B1-B2 in FIG. 14A, which includes a cross-sectional view of the transistor 200 in the channel length direction. FIG. 14C is a cross-section view taken along the dashed-dotted line B3-B4 in FIG. 14A, which includes a cross-sectional view of the transistor 200 in the channel width direction. FIG. 14D is a cross-sectional view taken along the dashed-dotted line B5-B6 in FIG. 14A, which includes a cross-sectional view of the capacitor 460. FIG. 15A is a cross-sectional view taken along the dashed-dotted line B7-B8 in FIG. 14A, which includes a cross-sectional view of the transistor 200 in the channel width direction. FIG. 15B is a cross-sectional view taken along the dashed-dotted line B9-B10 in FIG. 14A, which includes a cross-sectional view of the transistor 200 in the channel width direction. For simplification of the drawing, some components are not illustrated in the plan view of FIG. 14A.

The transistor 200 can be the transistor 200 illustrated in FIGS. 1A to 1D or FIGS. 8A to 8D or the like. The structure of the transistor 200 illustrated in FIG. 14A and the like is similar to the structure illustrated in FIGS. 1A to 1D or FIGS. 8A to 8D and can be denoted by similar hatching patterns and reference numerals. The above description can be referred to for the detailed structure. Note that the stacked-layer structure of the conductor 260 (the conductor 260a and the conductor 260b), the stacked-layer structures of the conductor 242a and the conductor 242b (the conductor 242al, the conductor 242a2, the conductor 242b1, and the conductor 242b2), and the like are not illustrated in FIGS. 14A and 14B in some cases. An insulator 285 is formed over the insulator 283, and a conductor 413 connected to the conductor 240a is formed over the insulator 285. The insulator 285 can be formed using an insulating material that can be used for the insulator 216. The conductor 413 can be formed using a conductive material that can be used for the conductor 242.

The capacitor 460 includes the oxide semiconductor 230, the conductor 242b over the oxide semiconductor 230, an insulator 454 over the conductor 242b, and a conductor 456 over the insulator 454. The oxide semiconductor 230 and the conductor 242b are shared with the transistor 200. The insulator 454 has the same structure as the insulator 250 and can be formed in the same step as the insulator 250. The conductor 456 has the same structure as the conductor 260 and can be formed in the same step as the conductor 260. Since the transistor 200 and the capacitor 460 share the oxide semiconductor 230, the oxide semiconductor 230 does not need to be divided into separate patterns for the transistor 200 and the capacitor. Thus, the area occupied by the transistor 200 and the capacitor 460 can be reduced. In addition, the cost required for the manufacturing process can be reduced.

The capacitor 460 and the transistor 200 can be formed in the same layer. As illustrated in FIG. 14B, the capacitor 460 and the transistor 200 can be formed in a region between the insulator 215 and the insulator 282. The insulator 454 of the capacitor 460 and the insulator 250 of the transistor 200 can be formed using the same insulating film, and the conductor 456 and the conductor 260 can be formed using the same conductive film. Thus, no additional steps of forming an insulating film, a conductive film, a semiconductor film, and the like are needed for the formation of the capacitor 460. In the case where the insulator 454 and the insulator 250 are processed in the same step, no additional processing step is needed. Similarly, in the case where the conductor 456 and the conductor 260 are processed in the same step, no additional processing step is needed. In addition, even in the case where both the transistor 200 and the capacitor 460 are provided in the same layer, the thickness of the layer does not need to be changed from that in the case where only the transistor 200 is provided.

In the semiconductor device of one embodiment of the present invention, when a plurality of layers each provided with the transistor 200 and the capacitor 460 are stacked, a plurality of memory cells can be three-dimensionally arranged and the memory capacity per unit area can be increased. In the semiconductor device illustrated in FIGS. 14A to 14D and the like, the capacitor can be manufactured without a significant change from the manufacturing process of the transistor, and the thickness of the layer where the memory cell is provided is not significantly changed; thus, the semiconductor device is suitable for memory cells included in a three-dimensional structure.

Here, the capacitor 460 includes the conductor 242b functioning as a first electrode, the conductor 456 functioning as a second electrode, and the insulator 454 functioning as a dielectric. That is, the capacitor 460 is a metal-insulator-metal (MIM) capacitor.

The capacitor 460 shares the oxide semiconductor 230 with the transistor 200. The insulator 454 and the conductor 456 are provided in an opening formed in the insulators 280 and 275. The insulator 454 can be formed using the same insulator as the insulator 250, and the conductor 456 can be formed using the same conductor as the conductor 260. The conductor 242b in the transistor 200 has an opening portion, and the conductor 242b in the capacitor 460 overlaps with the conductor 456 and the insulator 454. The opening provided in the insulators 275 and 280 in a region where the capacitor 460 is provided reaches the conductor 242b, and the insulator 454 is in contact with the top surface of the conductor 242b in the opening.

As illustrated in FIG. 14D and the like, in the capacitor 460, the height of the oxide semiconductor 230 is larger than the width of the oxide semiconductor 230 in a cross-sectional view in the channel width direction as in the transistor 200. In the top view, the oxide semiconductor 230 and the conductor 456 overlap with each other in two or more regions. This can increase the area where the conductor 242b, the insulator 454, and the conductor 456, which are provided along the top and side surfaces of the oxide semiconductor 230, face each other. Accordingly, the capacitance can be increased without a significant increase in the area occupied by the capacitor 460.

Although FIGS. 14A to 15B illustrate an example where the oxide semiconductor 230 and the conductor 260 (the oxide semiconductor 230 and the conductor 456) overlap with each other in two or more regions, the oxide semiconductor 230 and the conductor 260 (the oxide semiconductor 230 and the conductor 456) may overlap with each other in only one region. FIG. 15C is a modification example of FIG. 14C and is different from FIG. 14C mainly in that the oxide semiconductor 230 and the conductor 260 overlap with each other in one region. FIG. 15D is a modification example of FIG. 14D and is different from FIG. 14D mainly in that the oxide semiconductor 230 and the conductor 456 overlap with each other in one region.

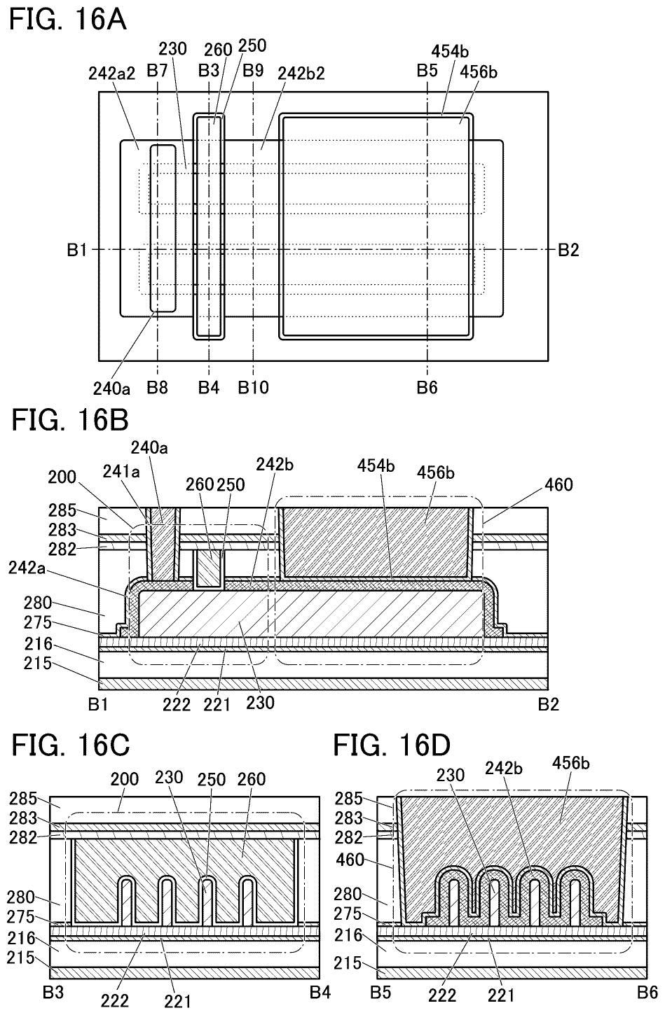

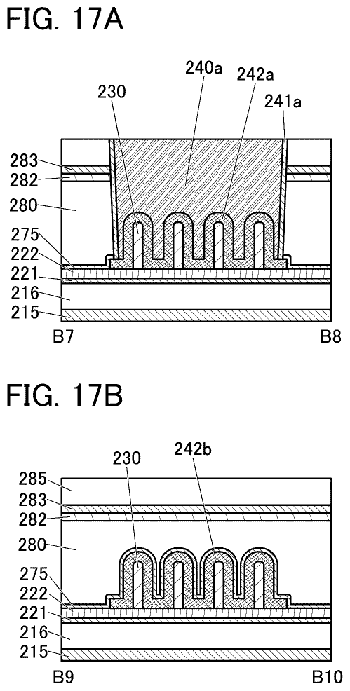

A semiconductor device illustrated in FIGS. 16A to 17B is different from the semiconductor device illustrated in FIGS. 14A to 15B in that the capacitor 460 includes an insulator 454b instead of the insulator 454 and a conductor 456b instead of the conductor 456.

In FIGS. 16A to 17B, an opening portion reaching the conductor 242b is provided in the insulators 275, 280, 282, 283, and 285. The insulator 454b is provided to cover the sidewall of the opening portion and the top surface of the conductor 242b. The insulator 454b is preferably provided in contact with the top surface of the conductor 242b. The conductor 456b is provided to fill the opening portion. A region of the insulator 454b between the conductor 242b and the conductor 456b functions as the dielectric of the capacitor 460.

The insulator 454b and the conductor 456b can be formed after the insulator 250 and the conductor 260 of the transistor 200 are formed and then the insulator 282 and the insulator 283 are formed. In the manufacturing process of the insulator 454b and the conductor 456b, the surface of the oxide semiconductor 230 of the transistor 200 is not exposed, so that damage by etching or the like at the time of forming the capacitor is less likely to occur, for example.

The insulator 454b may be formed using a material different from that of the insulator 250. For example, the insulator 454b may be formed using a material having a high dielectric constant. Alternatively, the insulator 454b may be formed using a material that can show ferroelectricity.

The conductor 456b may be formed using a material different from that of the conductor 260. For example, the conductor 456b can be formed using a material having a lower resistance than the conductor 260.

Insulators included in the semiconductor device of one embodiment of the present invention can be formed using a material that can show ferroelectricity. In particular, the insulator 454b is preferably formed using a material that can show ferroelectricity. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a κ-alumina-type structure.

Although metal oxides and metal nitrides are described above as examples, one embodiment of the present invention is not limited thereto. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulator of one embodiment of the present invention can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can show ferroelectricity in this specification and the like.

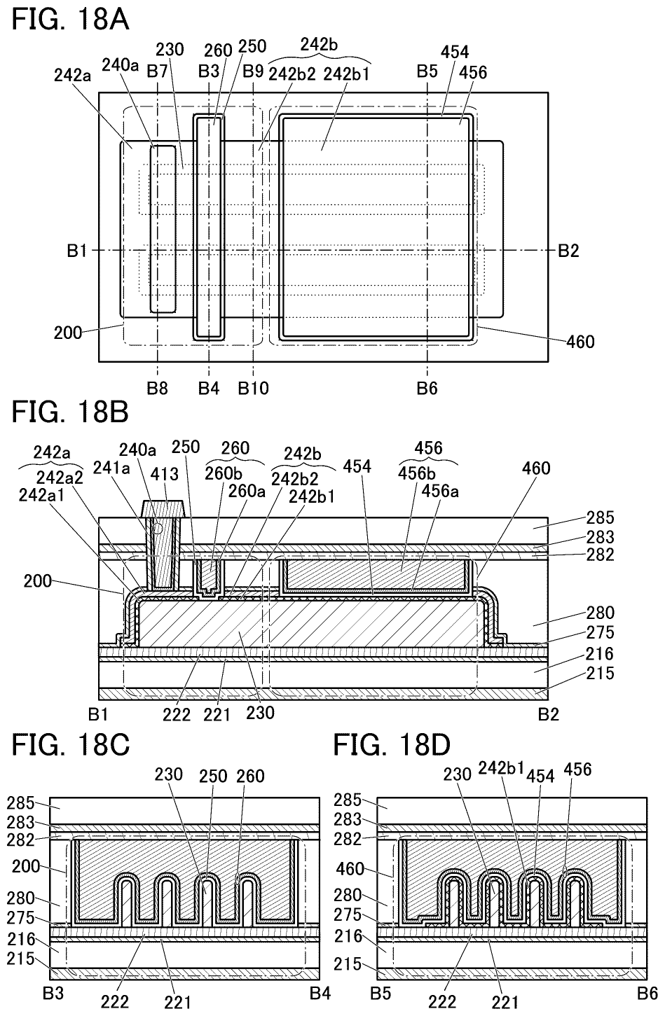

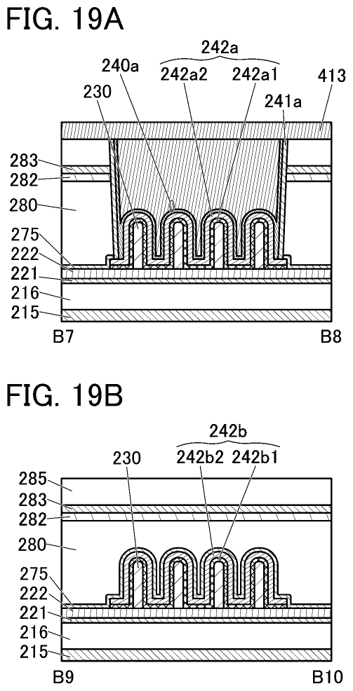

A semiconductor device illustrated in FIGS. 18A to 19B is different from the semiconductor device illustrated in FIGS. 14A to 15B mainly in that the transistor 200 has the structure illustrated in FIGS. 9A to 9D and 10B and the capacitor 460 includes the lower layer of the conductor 242b (the conductor 242b1) as one electrode.

In FIGS. 18A to 19B, the conductor 242b1 in the transistor 200 has an opening portion, and the conductor 242b1 in the capacitor 460 overlaps with the conductor 456 and the insulator 454. The opening provided in the insulators 275 and 280 in a region where the capacitor 460 is provided reaches the conductor 242b1, and the insulator 454 is in contact with the top surface of the conductor 242b1 in the opening. The conductor 242b2 is removed in a region overlapping with the conductor 456 of the capacitor 460. Thus, the conductor 242b1 in the transistor 200 includes a region overlapping with the conductor 242b2 and a region extending beyond the end portion of the conductor 242b2, and the conductor 242b1 in the capacitor 460 does not overlap with the conductor 242b2.

Note that as illustrated in FIG. 18B and the like, the conductor 456 can have a stacked-layer structure of a conductor 456a and a conductor 456b over the conductor 456a. Here, the conductor 456a and the conductor 260a can be formed by processing the same conductive film, and the conductor 456b and the conductor 260b can be formed by processing the same conductive film.

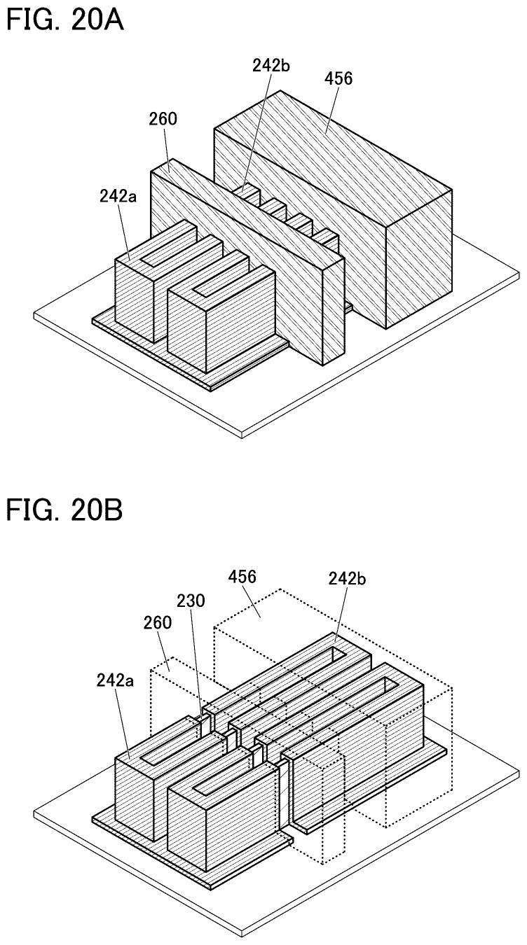

FIGS. 20A and 20B are perspective views illustrating the structure of the semiconductor device illustrated in FIGS. 14A to 15B. Note that insulators are omitted in FIG. 20A. Furthermore, some conductors such as the conductor 240a are omitted. FIG. 20B is a diagram in which the conductor 260 and the conductor 456 in FIG. 20A are illustrated in a see-through manner.

In each of FIGS. 20A and 20B, the oxide semiconductor 230 and the conductor 260 overlap with each other in four regions, and the oxide semiconductor 230 and the conductor 456 overlap with each other in four regions.

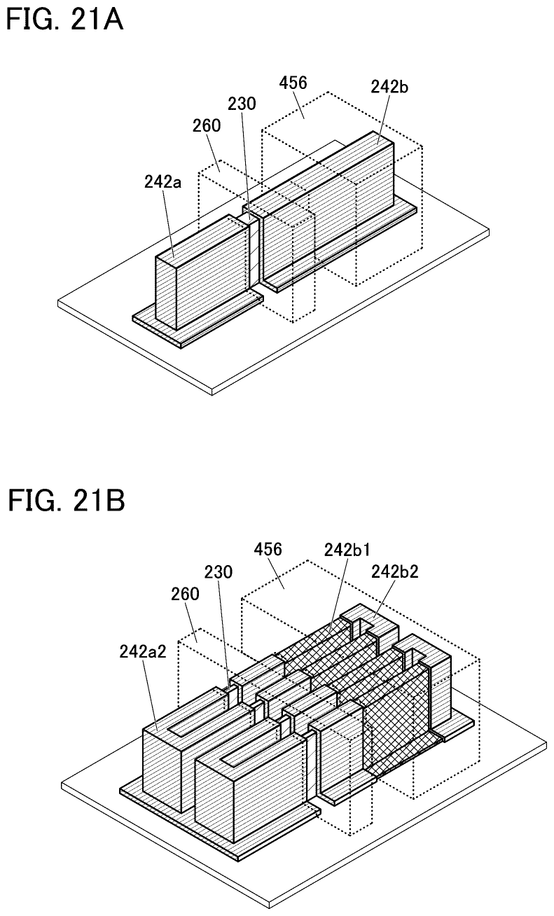

FIG. 21A illustrates a modification example of FIG. 20B, in which the oxide semiconductor 230 and the conductor 260 overlap with each other in one region and the oxide semiconductor 230 and the conductor 456 overlap with each other in one region.

FIG. 21B is a perspective view illustrating the structure of the semiconductor device illustrated in FIGS. 18A to 19B. Note that insulators are omitted in FIG. 21B. In addition, some conductors such as the conductor 240a are omitted. Furthermore, the conductor 260 and the conductor 456 are made transparent.

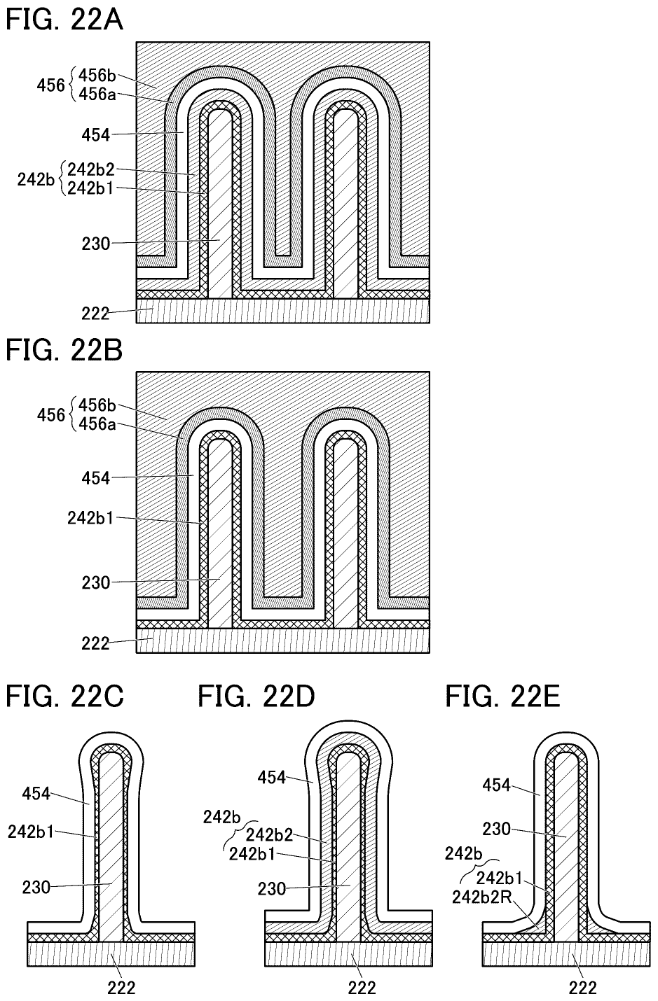

FIG. 22A is an enlarged view of part of the structure of the capacitor 460 illustrated in FIG. 14D. Note that in FIG. 22A, the conductor 242b has the stacked-layer structure of the conductor 242b1 and the conductor 242b2, and the conductor 456 has the stacked-layer structure of the conductor 456a and the conductor 456b.

FIG. 22B is an enlarged view of part of the structure of the capacitor 460 illustrated in FIG. 18D.

In the structure illustrated in FIG. 22B, the lower electrode of the capacitor 460 is formed of a single layer of the conductor 242b1; thus, even when the distance between the adjacent fin-shaped regions of the oxide semiconductors 230 is narrowed in the cross-sectional view of FIG. 22B, even the lower part of the oxide semiconductor 230 can be favorably covered with the lower electrode and the insulator 454 formed over the lower electrode. Thus, the surface area of the lower electrode of the capacitor 460 can be increased, so that the capacitance of the capacitor 460 can be increased.

FIGS. 22C to 22E illustrate states where the conductor 242b1, the conductor 242b2, and the insulator 454 cover the oxide semiconductor 230.

FIG. 22C illustrates a state where the conductor 242b1 is thinner at the side surface of the oxide semiconductor 230 than at the top surfaces of the insulator 222 and the oxide semiconductor 230. The thinner portion of the conductor 242b1 might have a higher resistance. Even in such a case, when the oxide semiconductor 230 is made to have a low resistance so as to function as an electrode, a circuit including the capacitor 460 can be favorably operated. The resistance of the oxide semiconductor 230 can be reduced by making the oxide semiconductor 230 include an appropriate amount of VoH. Note that the oxide semiconductor 230 is sometimes expressed as functioning as an auxiliary electrode of the conductor 242b1.

FIG. 22D illustrates an example in which the conductor 242b2 is stacked over the conductor 242b1 illustrated in FIG. 22C. When the lower electrode of the capacitor 460 has the stacked-layer structure of the conductor 242b1 and the conductor 242b2, in-plane variation in the resistance of the lower electrode can be reduced.

In the case where a conductive film to be the conductor 242b2 is formed in the region where the transistor 200 is provided and the region where the capacitor 460 is provided and then the conductive film is removed in the region where the capacitor 460 is provided, part of the conductive film remains in some cases. FIG. 22E illustrates a remaining part of the conductive film as a conductor 242b2R. The remaining conductor 242b2R improves the coverage with the insulator 454 in some cases.

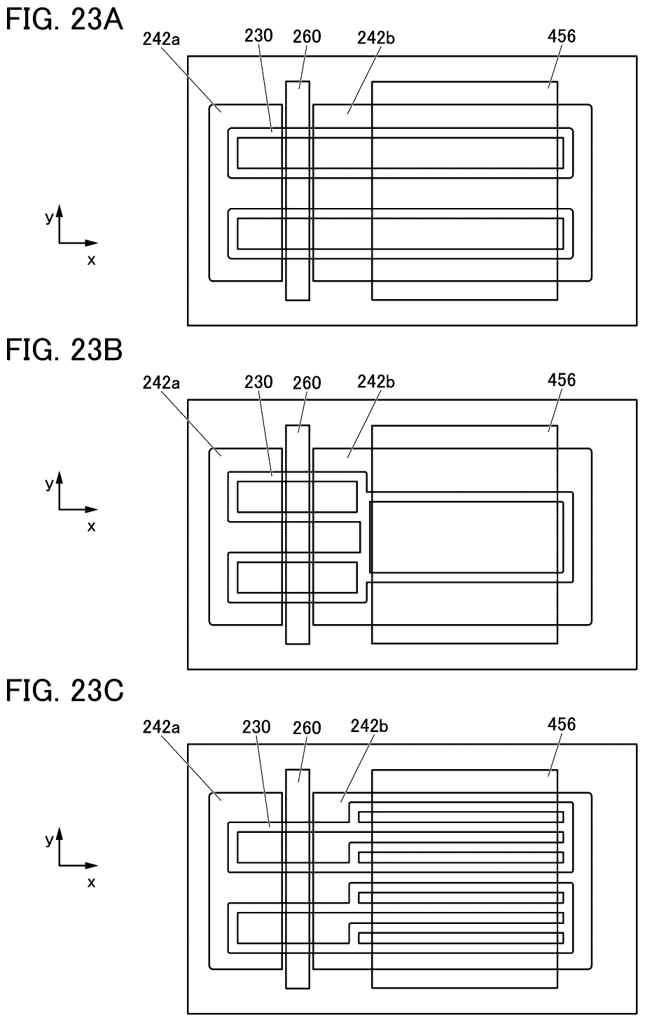

In FIG. 23A, some components in the top view in FIG. 14A are not illustrated and the oxide semiconductor 230 is indicated by solid lines in a see-through manner. FIGS. 23B and 23C illustrate modification examples of FIG. 23A.

In the top view in FIG. 23B, the distance between the fins of the oxide semiconductor 230 that are adjacent in the y-direction is widened in a region overlapping with the conductor 456, i.e., a region where the capacitor 460 is formed. Thus, even when the distance between the fins is narrowed in the region where the transistor 200 is provided, the conductor 456 can favorably cover the entire sidewall, including the lower part, of the oxide semiconductor 230.

In contrast, in the top view in FIG. 23C, the distance between the fins of the oxide semiconductor 230 that are adjacent in the y-direction is narrowed, so that the number of regions where the oxide semiconductor 230 and the conductor 456 overlap with each other can be increased. This can be rephrased as “the number of fins of the oxide semiconductor 230 that are covered with the conductor 456 is increased”. In the example illustrated in FIG. 23A, the region where the transistor 200 is provided includes two regions where the conductor 260 and the oxide semiconductor 230 overlap with each other, and the region where the capacitor 460 is provided also includes two regions where the conductor 456 and the oxide semiconductor 230 overlap with each other. In the example illustrated in FIG. 23C, the region where the transistor 200 is provided includes four regions where the conductor 260 and the oxide semiconductor 230 overlap with each other, while the region where the capacitor 460 is provided includes eight regions where the conductor 456 and the oxide semiconductor 230 overlap with each other, whereby the capacitance of the capacitor 460 can be increased.

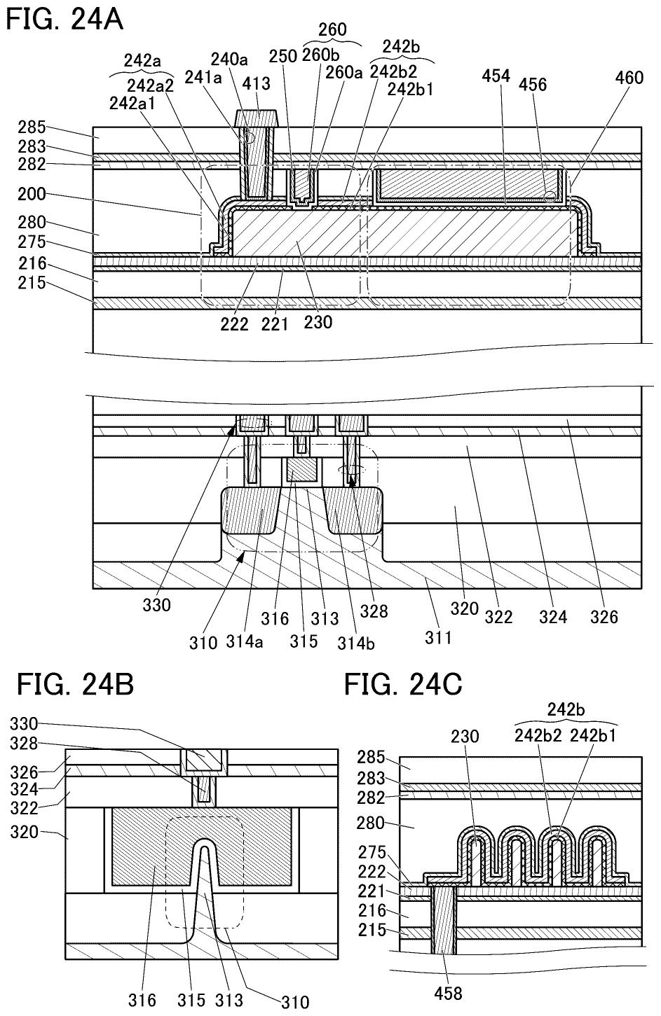

The semiconductor device may have a structure in which the memory cell described above is provided over a layer including a transistor formed on a silicon substrate. As one example, FIG. 24A illustrates a structure in which the memory cell illustrated in FIGS. 18A to 19B is provided over a layer including a transistor 310 formed on a silicon substrate. FIG. 24B is a cross-sectional view of the transistor 310 in the channel width direction. The layer including the transistor 310 formed on a silicon substrate can be provided with a transistor of a driver circuit included in a memory device. In the case where the memory cell further includes a transistor in addition to the transistor 200, the transistor of the memory cell can be provided in the layer including the transistor 310.

The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 may be a p-channel transistor or an n-channel transistor. As the substrate 311, a single crystal silicon substrate can be used, for example.

In the transistor 310, the semiconductor region 313 (part of the substrate 311) in which a channel is formed has a projecting shape as illustrated in FIG. 24B. The conductor 316 is provided to cover the side and top surfaces of the semiconductor region 313 with the insulator 315 therebetween. Note that the conductor 316 may be formed using a material for adjusting the work function. The transistor 310 is also referred to as a fin-type transistor because it utilizes a projecting portion of the semiconductor substrate. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing a silicon-on-insulator (SOI) substrate.

Note that the transistor 310 illustrated in FIGS. 24A and 24B is an example and the structure is not limited thereto; an appropriate transistor can be used in accordance with a circuit structure or a driving method.

A wiring layer including an interlayer film, a wiring, a plug, and the like may be provided between components. A plurality of wiring layers can be provided in accordance with the design. In this specification and the like, a wiring and a plug connected to the wiring may be a single component. That is, part of a conductor functions as a wiring in some cases and part of a conductor functions as a plug in other cases.

For example, an insulator 320, an insulator 322, an insulator 324, and an insulator 326 are sequentially stacked over the transistor 310 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as an interlayer film may function as a planarization film that covers a roughness thereunder. For example, the top surface of the insulator 322 may be planarized by planarization treatment using a chemical mechanical polishing (CMP) method or the like to improve planarity.

The transistor 200 and the capacitor 460 are provided over the insulator 326.

### Structure Example 3 of Semiconductor Device

The memory cell can further include a transistor in addition to the transistor 200 and the capacitor 460. In the structure illustrated in FIGS. 24A and 24B, the transistor 310 can be connected to the transistor 200 or the capacitor 460 to form a two-transistor and one-capacitor (2T1C) memory cell including the transistor 200, the transistor 310, and the capacitor 460.

As illustrated in FIG. 24C, the conductor 242b of the transistor 200 is connected to the conductor 330 provided in a lower layer through a conductor 458. As illustrated in FIG. 24C, the conductor 242b functioning as one of the source and the drain of the transistor 200 is connected to the conductor 316 functioning as the gate electrode of the transistor 310 through the conductor 458, the conductor 330, and the conductor 328. Note that FIG. 24C is a diagram including a cross section of the transistor 200 in the channel width direction.

### Structure Example 4 of Semiconductor Device

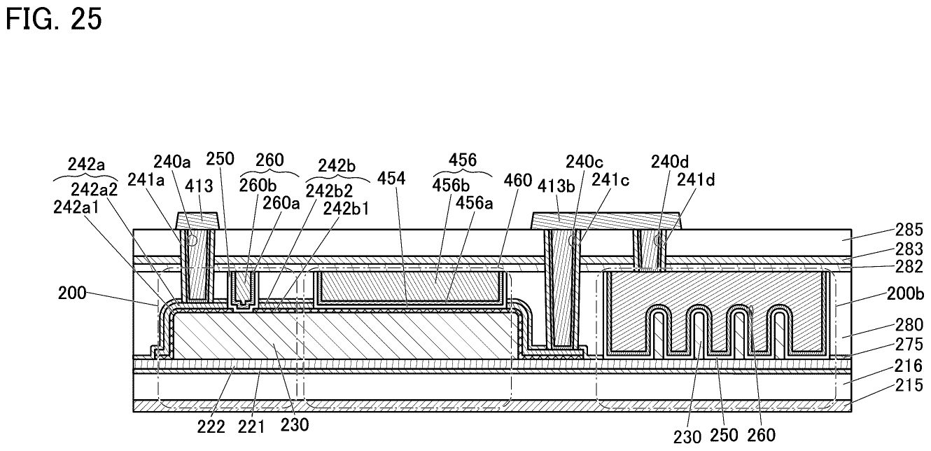

A structure illustrated in FIG. 25 is an example of a 2T1C memory cell including the transistor 200, the capacitor 460, and a transistor 200b. The transistor 200b has a structure similar to that of the transistor 200. The transistor 200 and the transistor 200b are formed in the same layer and provided such that their channel length directions intersect with each other. Since the transistor 200b has the structure similar to that of the transistor 200, its components are denoted by similar hatching patterns and reference numerals. The above description can be referred to for the detailed structure.

In FIG. 25, the conductor 242b included in the transistor 200 is connected to the conductor 260 included in the transistor 200b through a conductor 240c, a conductor 413b, and a conductor 240d.

Here, the conductors 240c and 240d are formed to fill openings in the insulators 282, 283, and 285 and have a structure similar to that of the conductor 240a. An insulator 241c and an insulator 241d are also formed to fill the openings in the insulators 282, 283, and 285 and have a structure similar to that of the insulator 241a. The conductor 413b is preferably provided in contact with the top surface of the conductor 240c and the top surface of the conductor 240d. The bottom surface of the conductor 240c is preferably provided in contact with the conductor 242b. The bottom surface of the conductor 240d is preferably provided in contact with the top surface of the conductor 260 of the transistor 200b. With such a structure, one of the source and the drain of the transistor 200, one electrode of the capacitor 460, and the gate of the transistor 200b are connected to each other.

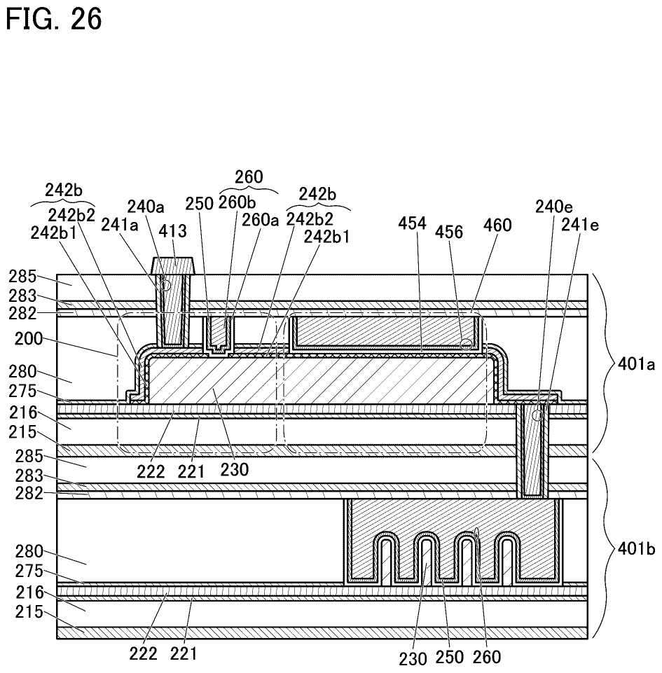

Although the transistor 200 and the transistor 200b are provided in the same layer in FIG. 25, the present invention is not limited thereto. For example, as illustrated in FIG. 26, a layer 401a including the transistor 200 and the capacitor 460 may be stacked over a layer 401b including the transistor 200b. Note that the layer 401a and the layer 401b have structures similar to that of the layer including the components from the insulator 215 up to the insulator 285 illustrated in FIG. 18B and the like.

As illustrated in FIG. 26, a conductor 240e and an insulator 241e are formed in an opening provided in the insulators 282, 283, and 285 in the layer 401b and the insulators 215, 216, 221, and 222 in the layer 401a. With such a structure, the conductor 242b of the transistor 200 and the conductor 260 of the transistor 200b can be electrically connected to each other.

Here, the oxide semiconductor 230 included in the transistor 200b preferably overlaps with the oxide semiconductor 230 included in the transistor 200 and the capacitor 460. Such a structure can reduce the area occupied by the memory cell.

### <Oxide Semiconductor Layer>

Here, an oxide semiconductor layer which can be used for the oxide semiconductor 230 will be described. The oxide semiconductor layer contains a metal oxide.

When a metal oxide is used for a semiconductor layer of a transistor, a lattice defect in the metal oxide may cause generation, capture, or the like of a carrier. Thus, when a metal oxide with a large number of lattice defects is used for a semiconductor layer of a transistor, the electrical characteristics of the transistor may be unstable. Thus, a metal oxide used for a semiconductor layer of a transistor preferably has a small number of lattice defects. Examples of the lattice defects include point defects such as an atomic vacancy and an exotic atom, linear defects such as transition, plane defects such as a crystal grain boundary, and volume defects such as a cavity.

By using a metal oxide having crystallinity for the oxide semiconductor layer, the density of defect states in the oxide semiconductor layer can be reduced. Examples of the structure of a metal oxide having crystallinity include a c-axis aligned crystalline (CAAC) structure, a polycrystalline structure, and a nanocrystalline (nc) structure.

The metal oxide included in the oxide semiconductor layer of one embodiment of the present invention includes a plurality of microcrystals. A clear crystal grain boundary (grain boundary) is not observed between the plurality of microcrystals. It is preferable that the metal oxide included in the oxide semiconductor layer of one embodiment of the present invention include a plurality of microcrystals aligned with each other and have a crystal structure in which the plurality of microcrystals are connected without a clear crystal grain boundary when observed from the alignment direction.

The oxide semiconductor layer of one embodiment of the present invention includes a metal oxide having a crystal structure different from a single crystal structure and a polycrystalline structure. It is particularly preferable that the oxide semiconductor layer of one embodiment of the present invention include a metal oxide having a CAAC structure.

The CAAC structure is a crystal structure in which a plurality of microcrystals (typically, a plurality of microcrystals each having a hexagonal crystal structure) have c-axis alignment and are connected on the a-b plane without any clear crystal grain boundary. In cross-sectional observation of an oxide semiconductor layer having a CAAC structure with use of a high-resolution transmission electron microscope (TEM) image, metal atoms are observed to be arranged in a layered manner in a crystal part. Thus, the oxide semiconductor layer having a CAAC structure can also be referred to as a structure including the layered crystal parts. The metal atoms arranged in a layered manner can be observed as arranged bright spots in the cross-sectional TEM image of the oxide semiconductor layer. The bright spots are arranged in a direction parallel to the formation surface of the oxide semiconductor layer, for example.

The CAAC structure sometimes refers to a structure in which metal atoms are arranged in a layered manner in a direction parallel or substantially parallel to a formation surface and the layers in which the metal atoms are arranged are stacked in a direction perpendicular or substantially perpendicular to the formation surface in each of a plurality of microcrystals. The crystal structure of the microcrystals is not limited to a hexagonal crystal structure as long as the microcrystals have such a structure. For example, some of the plurality of microcrystals may have a crystal structure other than a hexagonal crystal structure (e.g., a cubic crystal structure).

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 90°±20° (greater than or equal to 70° and less than or equal to 110°), further preferably within 90°±15° (greater than or equal to 75° and less than or equal to 105°), still further preferably within 90°±10° (greater than or equal to 80° and less than or equal to 100°), yet further preferably within 90°±5° (greater than or equal to 85° and less than or equal to 95°).

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electrical resistance of the oxide semiconductor layer is increased. This is because the electrical resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. In contrast, in the CAAC structure, crystal grain boundaries in the a-b plane are not observed clearly; thus, a highly reliable semiconductor device can be achieved. Furthermore, because the CAAC structure has a small number of crystal grain boundaries, an energy barrier for carrier conduction in a channel of a transistor is low, and an on-state current is expected to be increased. An increase in the electrical resistance of the semiconductor layer of a transistor including the oxide semiconductor layer can be inhibited or the initial characteristics (in particular, the on-state current) of the transistor can be improved; thus, a transistor suitable for high-speed operation can be expected.

For the channel formation region of a transistor, a metal oxide that can increase the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

The crystallinity of the oxide semiconductor layer can be analyzed by X-ray diffraction (XRD), TEM, or electron diffraction (ED), for example. Alternatively, these methods may be combined as appropriate for analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form the FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 70° and less than or equal to 1100 (within 90°±20°), further preferably greater than or equal to 75° and less than or equal to 1050 (within 90°±15°), still further preferably greater than or equal to 80° and less than or equal to 1000 (within 90°±10°), and yet further preferably greater than or equal to 85° and less than or equal to 950 (within 90°±5°) can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse fast Fourier transform is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by line segments connecting the Voronoi points is referred to as a Voronoi region. In the above manner, a Voronoi diagram can be formed.

Note that as the TEM observation range for forming a Voronoi diagram, a rectangular region that is 50 nm wide and 50 nm long is observed, for example. Note that the observation range is not limited to this.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material included in the oxide semiconductor layer. The oxide semiconductor layer sometimes includes at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or a metalloid element that has a high bonding energy with oxygen, such as a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from gallium, tin, yttrium, and aluminum, still further preferably one or more selected from gallium and tin. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

A main component in a metal oxide refers to, for example, a metal element having a proportion of 0.1 atomic % or higher or 1 atomic % or higher with respect to all metal elements contained in the metal oxide.

In the cross section of the oxide semiconductor layer observed using the TEM image, metal atoms arranged in a layered manner in a direction parallel or substantially parallel to the formation surface are observed. In a TEM image, a metal atom is observed as a bright spot. For example, in a metal oxide containing indium, indium atoms arranged in a layered manner are observed. As another example, in a metal oxide containing indium and zinc, indium atoms and zinc atoms arranged in a layered manner are observed.

Examples of the metal oxide of one embodiment of the present invention include indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO or IAGZO). Alternatively, indium tin oxide containing silicon (also referred to as ITSO), gallium tin oxide (Ga—Sn oxide), aluminum tin oxide (Al—Sn oxide), or the like can be given. As the metal oxide of one embodiment of the present invention, indium oxide can be used. Alternatively, as the metal oxide of one embodiment of the present invention, gallium oxide, zinc oxide, or the like can be used.

By increasing the proportion of the number of indium atoms in the total number of atoms of all the metal elements included in the metal oxide, a high on-state current and high frequency characteristics of the transistor can be achieved.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

Instead of indium, the metal oxide may contain one or more kinds of metal elements whose period number in the periodic table is large. Alternatively, in addition to indium, the metal oxide may contain one or more kinds of metal elements whose period number is large. The larger the overlap between orbits of metal elements is, the more likely it is that the metal oxide will have high carrier conductivity. Thus, when a metal element with a large period number is contained in the metal oxide, the field-effect mobility of the transistor can be increased in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, fluorine, chlorine, bromine, and hydrogen.

### [Formation Method of Oxide Semiconductor Layer]

The oxide semiconductor layer of one embodiment of the present invention can be formed by forming metal oxides using two kinds of film formation methods.

In the formation of the oxide semiconductor layer of one embodiment of the present invention, a metal oxide film having the CAAC structure is formed. Here, the use of a sputtering method as a film formation method enables a metal oxide film with high crystallinity to be formed. Alternatively, a film formation method such as a pulsed laser deposition (PLD) method may be used.

In the case where a metal oxide film is formed by the above-described film formation method (hereinafter, a first film formation method), a mixed layer is sometimes formed at the interface between the metal oxide film and a formation surface over which the metal oxide is formed. There is a concern that the mixed layer may hinder crystallization of the metal oxide film. A metal oxide film is formed in advance as a first layer over the formation surface by a film formation method (hereinafter, a second film formation method) that causes less damage than a sputtering method, a PLD method, or the like described as the first film formation method, and then a metal oxide film is formed as a second layer by the first film formation method, whereby the formation of a mixed layer at the interface between the oxide semiconductor layer and the formation surface can be inhibited. Moreover, entry of impurities contained in the formation surface into the second layer can be inhibited. Accordingly, the crystallinity of the second layer can be further increased.

An atomic layer deposition (ALD) method and a chemical vapor deposition (CVD) method are suitable as the second film formation method because they can reduce damage to a formation surface as compared with a sputtering method. Examples of the second film formation method include a molecular beam epitaxy (MBE) method and a wet method. Examples of the CVD method include a plasma enhanced CVD (PECVD) method, a thermal CVD method, a photo CVD method, and a metal organic CVD (MOCVD) method. The MBE method is a film formation method in which a thin film having a crystal structure reflecting a crystal system of a substrate is grown, and is one of film formation methods that cause less damage to a formation surface. The wet method is one of film formation methods that cause less damage to a formation surface. An example of the wet method is a spray coating method.

Furthermore, a third layer can be formed over the second layer. The third layer can be formed by the second film formation method, for example.

After the oxide semiconductor layer is formed, heat treatment is preferably performed.

In the method for forming the oxide semiconductor layer of one embodiment of the present invention, the crystallinity of the oxide semiconductor layers (the first and third layers) above and below the second layer can be increased by using the second layer having high crystallinity (i.e., CAAC) as a nucleus or a seed. This can increase the crystallinity of the whole oxide semiconductor layer. In other words, the second layer serves as a nucleus or a seed to cause solid-phase growths of the metal oxides in the oxide semiconductor layers above and below the second layer, so that the oxide semiconductor layer with high crystallinity can be formed. An oxide semiconductor layer formed by such a film formation method, specifically, an oxide semiconductor layer having a CAAC structure, can be referred to as an axial growth CAAC (AG CAAC).

With the use of the method for forming the oxide semiconductor layer of one embodiment of the present invention, the first layer and the third layer can have high crystallinity even when they are not formed by a method that facilitates formation of a metal oxide with high crystallinity. The heat treatment has an assist function of increasing the crystallinity of the first layer and the third layer.

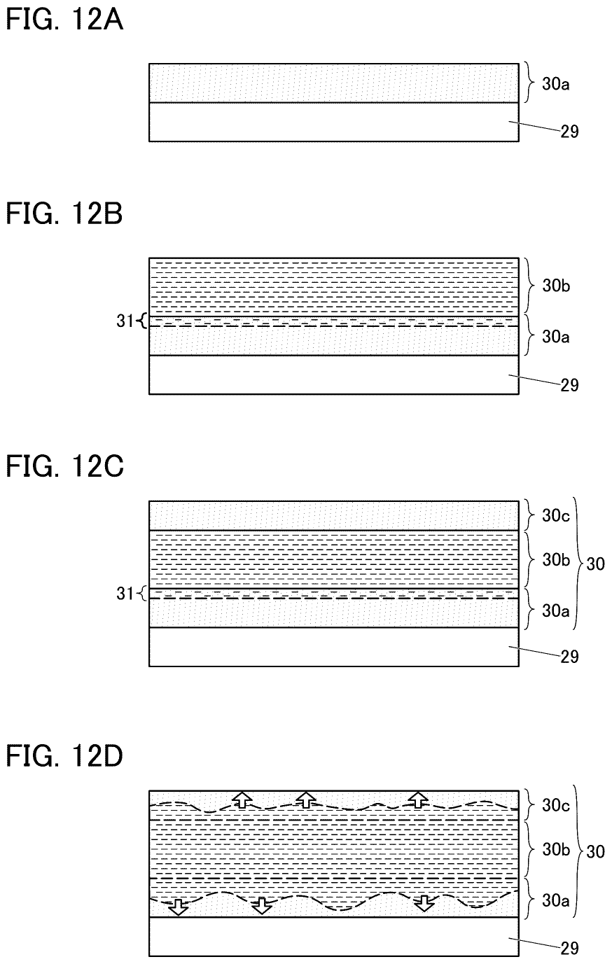

An example of a method for forming an oxide semiconductor 30 will be described below with reference to FIGS. 12A to 12D.

First, a layer 29 is formed. The layer 29 corresponds to an insulating film or a conductive film included in the semiconductor device. The layer 29 can be formed using an insulating film such as a silicon oxide film, a silicon oxynitride film, a silicon nitride film, a silicon nitride oxide film, an aluminum oxide film, or a hafnium oxide film, for example. Alternatively, the layer 29 can be formed using a conductive film functioning as an electrode of the semiconductor device, for example. The layer 29 does not need to have crystallinity. In other words, the layer 29 may have an amorphous structure. In the case where the layer 29 has crystallinity, the layer 29 may have a crystal structure with low lattice matching with the metal oxide included in the oxide semiconductor 30.

Next, an oxide semiconductor 30a is formed over the layer 29 (FIG. 12A).

In the formation method of one embodiment of the present invention, an oxide semiconductor 30b is formed by a sputtering method as described later. In the case where a metal oxide film is formed by a sputtering method, a mixed layer of a component of the metal oxide film to be formed and a component contained in the layer serving as the formation surface may be formed (i.e., alloying may occur) because of sputtered particles ejected from a target or the like or energy or the like applied to the substrate side by sputtered particles or the like, for example. The alloying might hinder crystallization of the oxide semiconductor layer above the mixed layer. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected.

In view of the above, before the formation of the oxide semiconductor 30b, the oxide semiconductor 30a is formed in advance by a film formation method that causes less damage to the formation surface. This can inhibit alloying of the component contained in the oxide semiconductor 30 with the component contained in the layer 29, enabling the alloyed region to be thin or thin enough not to be observed. Here, the oxide semiconductor 30a is formed by an ALD method.

Examples of the ALD method include a thermal ALD method, in which a precursor and a reactant react with each other only by a thermal energy, and a plasma-enhanced ALD (PEALD) method, in which a reactant excited by plasma is used.

Unlike in a film formation method in which particles ejected from a target or the like are deposited, a film is formed by reaction at a surface of an object to be processed in an ALD method. The ALD method enables atomic layers to be deposited one by one, and has advantages such as formation of an extremely thin film, formation of a film on a component with a high aspect ratio, formation of a film on a surface with a large step, formation of a film with few defects such as pinholes, formation of a film with excellent coverage, and low-temperature film formation. By forming the oxide semiconductor 30a and an after-mentioned oxide semiconductor 30c by an ALD method, the oxide semiconductor layer can have good coverage. Thus, the oxide semiconductor layer can suitably cover a step, an opening portion, or the like with a high aspect ratio.

A PEALD method utilizing plasma is preferable because film formation at lower temperatures is possible in some cases. Note that a precursor used in the ALD method sometimes contains an element such as carbon or chlorine. Thus, a film formed by the ALD method may contain an element such as carbon or chlorine in a larger quantity than a film formed by another film formation method.

Here, a method for forming an In-M-Zn oxide as the oxide semiconductor 30a by an ALD method is described.

First, a source gas that contains a precursor containing indium is introduced into a chamber so that the precursor is adsorbed on the surface of the layer 29. Then, an oxidizer is introduced as a reactant into the chamber to react with the adsorbed precursor, and components other than indium are released while indium is adsorbed on the substrate, whereby a layer in which indium and oxygen are bonded to each other is formed.

Subsequently, a source gas that contains a precursor containing the element M is introduced into the chamber, so that the precursor is adsorbed on the layer in which indium and oxygen are bonded to each other. Then, an oxidizer is introduced as a reactant into the chamber to react with the adsorbed precursor, and components other than the element M are released while the element M is adsorbed on the substrate, whereby a layer in which the element M and oxygen are bonded to each other is formed.

Next, a source gas that contains a precursor containing zinc is introduced into the chamber and adsorbed on the layer in which the element M and oxygen are bonded to each other. Then, an oxidizer is introduced as a reactant into the chamber to react with the adsorbed precursor, and components other than zinc are released while zinc is adsorbed on the substrate, whereby a layer in which zinc and oxygen are bonded to each other is formed.

By repeating the above steps, an In-M-Zn oxide can be formed as the oxide semiconductor 30a over the layer 29 by an ALD method.

The substrate heating temperature is preferably a temperature corresponding to the decomposition temperature of the precursor. Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

It is preferable that after the precursor is adsorbed in the above manner, introduction of the source gas containing the precursor be stopped and the chamber be purged so that an excess precursor, a reaction product, and the like are removed from the chamber. Moreover, it is preferable that after the adsorbed precursor reacts with the oxidizer in the above manner, introduction of the oxidizer be stopped and the chamber be purged so that an excess reactant, a reaction product, and the like are removed from the chamber.

In the description of this specification and the like, in the case of using ozone, oxygen, and water as a reactant or an oxidizer, they include not only those in gas or molecular states but also those in plasma, radical, and ion states, unless otherwise specified.

When the oxide semiconductor 30a is formed by an ALD method, an oxide semiconductor layer having a microcrystalline structure or an amorphous structure that has lower crystallinity than the CAAC structure may be formed.

Next, as the oxide semiconductor 30b, an In-M-Zn oxide is formed over the oxide semiconductor 30a by a sputtering method (FIG. 12B). The oxide semiconductor 30b preferably has a composition suitable for forming the CAAC structure.

When the oxide semiconductor 30b is formed by a sputtering method, a mixed layer 31 is formed on the surface of the oxide semiconductor 30a or in the vicinity of the surface. A fine crystal region is sometimes formed in the mixed layer 31 by, for example, sputtered particles or energy or the like applied to the substrate side by sputtered particles or the like at the time of forming the oxide semiconductor 30b. In the subsequent heat treatment step, the mixed layer 31 or the fine crystal region formed in the mixed layer 31 serves as a nucleus, and at least part of the oxide semiconductor 30a is crystallized in some cases.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. The DC sputtering method can be suitably used for forming a metal conductive film, and its high film formation rate can increase productivity. The pulsed DC sputtering method can be suitably used for forming a metal conductive film and a semiconductor film. The RF sputtering method can be suitably used for forming an insulating film. A film of a compound such as an oxide, a nitride, or a carbide can be formed by a reactive sputtering method using a reactive gas. The metal oxide film used as the oxide semiconductor layer of one embodiment of the present invention can be formed by any of the above methods selected as appropriate in accordance with, for example, the conductivity of a target used in a sputtering method.

As a target used in a sputtering method, In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen contained in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the case where the metal oxide is formed by a sputtering method, the composition of the formed metal oxide may be different from the composition of the sputtering target. In particular, the zinc content of the formed metal oxide may be reduced to approximately 50% of that of the sputtering target.

In the formation of the oxide semiconductor 30b by a sputtering method, substrate heating is preferably performed. When the substrate temperature (stage temperature) at the time of forming the metal oxide is increased, a metal oxide with high crystallinity can be formed in some cases. In the formation of the oxide semiconductor 30b by a sputtering method, the substrate heating temperature is preferably higher than or equal to 100° C. and lower than or equal to 400° C., further preferably higher than or equal to 200° C. and lower than or equal to 300° C., for example.

Next, the oxide semiconductor 30c is formed over the oxide semiconductor 30b (FIG. 12C). Here, the oxide semiconductor 30c is formed by an ALD method. For the formation of the oxide semiconductor 30c by an ALD method, the method for forming the oxide semiconductor 30a can be referred to.

When the oxide semiconductor 30c having lower crystallinity than the CAAC structure is formed over the oxide semiconductor 30b having the CAAC structure by an ALD method, the oxide semiconductor 30c may epitaxially grow with the oxide semiconductor 30b as a nucleus. Thus, at the time of forming the oxide semiconductor 30c, the oxide semiconductor 30c may include a region having the CAAC structure. The region having the CAAC structure is preferably formed throughout the oxide semiconductor 30c.

The oxide semiconductor 30c can be used for a layer in contact with a gate insulating layer of a transistor, for example. Increasing the crystallinity of the layer in contact with the gate insulating layer can increase the carrier mobility in an on state of the transistor.

Moreover, the formation of the oxide semiconductor 30c by an ALD method causes less damage to the oxide semiconductor 30b, so that the entire oxide semiconductor 30 can have high crystallinity.

When the oxide semiconductor 30a and the oxide semiconductor 30c are formed by an ALD method that offers good coverage, the entire oxide semiconductor layer can have high coverage. Moreover, the oxide semiconductor 30b with high crystallinity is formed by a sputtering method and is subjected to epitaxial growth or the like, so that the crystallinity of the upper and lower oxide semiconductor layers (the oxide semiconductor 30a and the oxide semiconductor 30c) is increased. Thus, the whole layer of the oxide semiconductor 30 can have high crystallinity. Accordingly, the oxide semiconductor 30 can have both high coverage and high crystallinity.

Next, a heat treatment step may be performed.

The heat treatment temperature is higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature is set to 400° C.±25° C. (higher than or equal to 375° C. and lower than or equal to 425° C.). The treatment time is shorter than or equal to 10 hours, longer than or equal to 1 minute and shorter than or equal to 5 hours, or longer than or equal to 1 minute and shorter than or equal to 2 hours. In the case of using a rapid thermal annealing (RTA) apparatus, the treatment time is longer than or equal to 1 second and shorter than or equal to 5 minutes, for example. By the heat treatment, the oxide semiconductor 30c is expected to fill the atomic-level space between crystal parts of the CAAC structure of the oxide semiconductor 30b.

The heating apparatus used for the heat treatment is not limited to a particular apparatus, and may be an apparatus for heating an object to be processed by heat conduction or heat radiation from a heating element such as a resistance heating element. For example, an electric furnace, or an RTA apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. A GRTA apparatus is an apparatus for heat treatment using a high-temperature gas.

By the heat treatment step, the crystallinity of the region having the CAAC structure in the oxide semiconductor 30c is increased in some cases. In the case where the region is formed only below the oxide semiconductor 30c after film formation by an ALD method, the region may be extended upward by the heat treatment step (FIG. 12D). That is, by the heat treatment, the region having the CAAC structure is sometimes formed in the whole oxide semiconductor 30c.

By the heat treatment step, the oxide semiconductor 30b is further repaired by the oxide semiconductor 30c (in other words, crystal molecules formed by an ALD method) that fills the atomic-level space between crystal parts of the CAAC structure of the oxide semiconductor 30b in some cases.

At least part of the oxide semiconductor 30a preferably has the CAAC structure owing to the heat treatment step (FIG. 12D). The CAAC structure is expected to be easily generated when the mixed layer 31 formed in the oxide semiconductor 30a in the formation of the oxide semiconductor 30b becomes a nucleus or a seed. The oxide semiconductor 30a preferably has a large CAAC region, and the CAAC region preferably extends to the vicinity of the layer 29.

Since the CAAC region extends from the upper portion to the lower portion of the oxide semiconductor 30a, the CAAC region can extend to the vicinity of the layer 29, regardless of the material and crystallinity of the layer 29. For example, even when the layer 29 has an amorphous structure, the oxide semiconductor 30a having high crystallinity can be formed. Thus, the method for forming the oxide semiconductor layer of one embodiment of the present invention is particularly suitable for the case where a layer serving as the formation surface has an amorphous structure.

After the formation of the oxide semiconductor 30c, microwave treatment may be performed.

Here, the microwave treatment refers to, for example, treatment using an apparatus including a power source for generating high-density plasma using microwaves. In this specification and the like, a microwave refers to an electromagnetic wave having a frequency higher than or equal to 300 MHz and lower than or equal to 300 GHz. The microwave treatment can also be referred to as microwave excitation high-density plasma treatment.

The impurity concentration in the oxide semiconductor 30 is preferably reduced by performing microwave treatment in an oxygen-containing atmosphere. Examples of the impurity especially include hydrogen and carbon. Although the microwave treatment in an oxygen-containing atmosphere is performed on the metal oxide in the above example, one embodiment of the present invention is not limited thereto. For example, the microwave treatment in an oxygen-containing atmosphere may be performed on an insulating film, more specifically a silicon oxide film, which is positioned in the vicinity of the metal oxide. Furthermore, the crystallinity of the oxide semiconductor layer is sometimes increased by heat in the microwave treatment.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. It is preferable to perform the microwave treatment with the substrate heated. The substrate temperature can be higher than or equal to room temperature (e.g., 25° C.) and lower than or equal to 750° C., preferably higher than or equal to 100° C. and lower than or equal to 500° C., further preferably higher than or equal to 200° C. and lower than or equal to 500° C., still further preferably higher than or equal to 300° C. and lower than or equal to 500° C., yet further preferably higher than or equal to 400° C. and lower than or equal to 500° C. The substrate temperature can be higher than or equal to 400° C. and lower than or equal to 450° C., for example.

The microwave treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

The microwave treatment can be performed using an oxygen gas and an argon gas, for example. The microwave treatment in an oxygen-containing atmosphere converts an oxygen gas into plasma using a high-frequency wave such as a microwave or RF and applies the oxygen plasma to the oxide semiconductor layer. By the effects of plasma, a microwave, and the like, a defect that is an oxygen vacancy into which hydrogen has entered (hereinafter sometimes referred to as VoH) in the oxide semiconductor layer can be divided into an oxygen vacancy and hydrogen, and hydrogen which is an impurity can be removed from the oxide semiconductor layer. In this manner, VoH contained in the oxide semiconductor layer can be reduced. At this time, carbon bonded to oxygen, hydrogen, or the like can also be removed in some cases. Performing the microwave treatment in such a manner can reduce impurities such as carbon and hydrogen. In addition, oxygen radicals generated by the oxygen plasma can be supplied to oxygen vacancies formed in the oxide semiconductor layer, thereby further reducing oxygen vacancies in the oxide semiconductor layer.

Oxygen implanted into the oxide semiconductor layer has a variety of forms such as an oxygen atom, an oxygen molecule, an oxygen ion, and an oxygen radical (also referred to as an O radical, which is an atom, a molecule, or an ion having an unpaired electron). The oxygen implanted into the oxide semiconductor layer has any one or more of the above forms; an oxygen radical is particularly preferable.

In the above manner, impurities in the oxide semiconductor layer can be reduced. Crystal growth of the oxide semiconductor layer with a low impurity concentration can further make crystallinity higher.

Note that one or both of the heat treatment and the microwave treatment may be performed directly on the oxide semiconductor layer or performed on an insulating film or the like formed over the oxide semiconductor layer.

The oxide semiconductor layer having the CAAC structure formed by the two kinds of film formation methods sometimes has one or more of a higher dielectric constant, higher film density, and higher film hardness than the oxide semiconductor layer having the CAAC structure formed by one kind of film formation method.

With the use of the oxide semiconductor layer having the CAAC structure formed by the two kinds of film formation methods for a channel formation region of a transistor, the transistor can have excellent characteristics (e.g., a high on-state current, high field-effect mobility, a low S value, excellent frequency characteristics (also referred to as f characteristics), or high reliability).

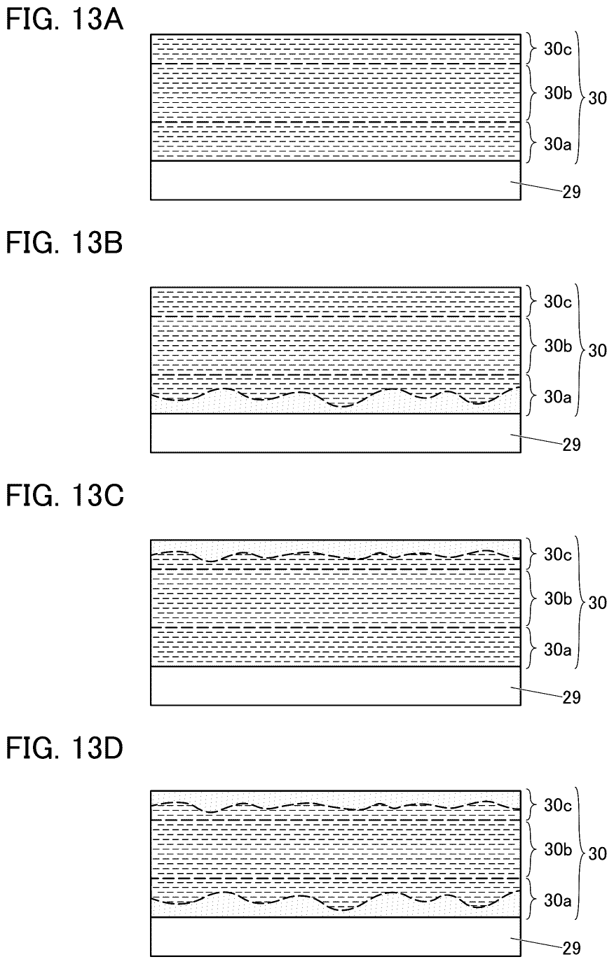

The region having the CAAC structure preferably spreads in the whole oxide semiconductor 30 including the oxide semiconductor 30a and the oxide semiconductor 30c. FIG. 13A illustrates a state where the oxide semiconductors 30a, 30b, and 30c are each crystallized. Crystals in the region having the CAAC structure in the oxide semiconductor 30a are connected to crystals in the region having the CAAC structure in the oxide semiconductor 30b. Crystals in the region having the CAAC structure in the oxide semiconductor 30c are connected to the crystals in the region having the CAAC structure in the oxide semiconductor 30b. The oxide semiconductor 30 may be expressed as one layer where the interfaces are not clearly observed. The oxide semiconductor 30 may be expressed as a single layer in some cases.

In cross-sectional observation with a high-resolution TEM, for example, bright spots arranged parallel to the formation surface are observed in the region having the CAAC structure in each of the oxide semiconductors 30a, 30b, and 30c. The c-axis of the CAAC structure included in each of the oxide semiconductors 30a, 30b, and 30c is preferably substantially parallel to the normal direction of the formation surface of the oxide semiconductor layer.

Part of the oxide semiconductor 30a or part of the oxide semiconductor 30c is not crystallized in some cases. An example illustrated in FIG. 13B illustrates a state where the vicinity of the interface between the oxide semiconductor 30a and the layer 29 is not crystallized. FIG. 13C illustrates a state where the vicinity of the surface of the oxide semiconductor 30c is not crystallized. FIG. 13D illustrates a state where the vicinity of the interface between the oxide semiconductor 30a and the layer 29 and the vicinity of the surface of the oxide semiconductor 30c are not crystallized.

The whole oxide semiconductor layer of one embodiment of the present invention has high crystallinity. Thus, in the oxide semiconductor 30, the boundaries between the stacked films of the oxide semiconductors 30a, 30b, and 30c are not observed in some cases. In particular, after heat treatment is performed, the boundaries between the stacked films are difficult to observe in some cases. Whether the boundaries between the stacked films are present can be checked with a cross-sectional TEM or a cross-sectional STEM, for example.

It is preferable that crystals included in the oxide semiconductor 30b and crystals included in the oxide semiconductor 30a or 30c have a small lattice mismatch. Thus, the oxide semiconductor 30a or 30c can form crystals reflecting the orientation of crystals included in the oxide semiconductor 30b. In that case, for example, in cross-sectional observation of the semiconductor 30 using a high-resolution TEM, bright spots arranged in a layered manner in a direction parallel to the formation surface are observed in the oxide semiconductor 30a or 30c.

There is no particular limitation on the crystal structure of the oxide semiconductor 30a or 30c as long as crystals included in the oxide semiconductor 30b and crystals included in the oxide semiconductor 30a or 30c have a small lattice mismatch. The crystal structure of the oxide semiconductor 30a or 30c may be any of a cubic crystal structure, a tetragonal crystal structure, an orthorhombic crystal structure, a hexagonal crystal structure, a monoclinic crystal structure, and a trigonal crystal structure.

In the case where one or both of microwave treatment and heat treatment is/are performed in the step of forming the oxide semiconductor 30, the oxide semiconductor 30b is not necessarily formed in some cases. For example, when one or both of microwave treatment and heat treatment is/are performed after the oxide semiconductor 30a is formed as described above, the crystallinity of the oxide semiconductor 30a can be increased, and the crystallinity of the oxide semiconductor 30c can be increased using the oxide semiconductor 30a as a nucleus or a seed. When one or both of microwave treatment and heat treatment is/are performed after the oxide semiconductor 30c is formed, the crystallinity of the oxide semiconductor 30 can be increased. Accordingly, the CAAC structure can be formed in the oxide semiconductor 30.

In addition, a metal oxide layer can be provided between the layer 29 and the oxide semiconductor 30, for example.

The metal oxide layer is preferably formed using a metal oxide material that can be used as the oxide semiconductor 30. The metal oxide layer preferably contains one or both of gallium and zinc, for example. A single layer or stacked layers of gallium oxide, zinc oxide, indium gallium oxide, gallium zinc oxide, aluminum zinc oxide, indium gallium zinc oxide, or the like can be used, for example. In the case of using indium gallium zinc oxide, a metal oxide with a composition of In:M:Zn=1:3:2 [atomic ratio] or in the neighborhood thereof or a composition of In:M:Zn=1:3:4 [atomic ratio] or in the neighborhood thereof is specifically used.

The thickness of the metal oxide layer can be smaller than that of the oxide semiconductor 30 and is, for example, greater than or equal to 0.1 nm and less than or equal to 1 nm, or greater than or equal to 0.1 nm and less than or equal to 0.5 nm.

When the metal oxide layer contains gallium, oxygen contained in the oxide semiconductor 30 can be inhibited from diffusing into the layer 29 or the like, and oxygen vacancies can be inhibited from being formed in the oxide semiconductor 30. The metal oxide layer containing zinc can have increased crystallinity and improve the crystallinity of the oxide semiconductor 30 provided over the metal oxide layer. When the metal oxide layer is provided between the layer 29 and the oxide semiconductor 30, impurity components such as hydrogen contained in the layer 29 can be inhibited from diffusing into the oxide semiconductor 30.

As described above, even when the oxide semiconductor 30b is not provided, the metal oxide layer included in the oxide semiconductor 30a or the layer 29 can be used as a nucleus or a seed for solid-phase growth of the upper oxide semiconductor, thereby forming a highly crystalline oxide semiconductor. An oxide semiconductor formed by such a film formation method can also be referred to as an AG CAAC. That is, the AG CAAC can be formed without using the first film formation method (e.g., a sputtering method or a PLD method). In other words, the AG CAAC can be formed also by the second film formation method (e.g., an ALD method or a CVD method) and one or both of microwave treatment and heat treatment.

The oxide semiconductor layer of one embodiment of the present invention can be used as a semiconductor layer of a transistor.

In the case where the oxide semiconductor 30 is used for a semiconductor layer of a transistor, the thickness of the oxide semiconductor 30 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, or yet still further preferably greater than or equal to 20 nm and less than or equal to 50 nm, for example. In a transistor used for a miniaturized semiconductor device, the thickness of the oxide semiconductor 30 is preferably greater than or equal to 1 nm and less than or equal to 20 nm, further preferably greater than or equal to 3 nm and less than or equal to 15 nm, still further preferably greater than or equal to 5 nm and less than or equal to 12 nm.

The thickness of the oxide semiconductor 30b is preferably less than or equal to 200 nm, for example. In the case where the oxide semiconductor 30b is in a form of layer, the thickness of the oxide semiconductor 30b is preferably greater than or equal to 1 nm and less than or equal to 200 nm, further preferably greater than or equal to 1 nm and less than or equal to 100 nm, still further preferably greater than or equal to 2 nm and less than or equal to 100 nm, for example.

Alternatively, when the oxide semiconductor 30b can function as a crystal nucleus, the oxide semiconductor 30b is not in a form of layer and may be an aggregate of island-shaped regions. For example, such island-shaped regions included in the oxide semiconductor 30b are discretely located.

The thickness of each of the oxide semiconductors 30a and 30c is preferably greater than or equal to 1 nm and less than or equal to 50 nm, further preferably greater than or equal to 1 nm and less than or equal to 30 nm, still further preferably greater than or equal to 1 nm and less than or equal to 20 nm, yet further preferably greater than or equal to 2 nm and less than or equal to 20 nm, for example.

The thickness of the region formed by alloying of the component contained in the oxide semiconductor 30 and the component contained in the layer 29 is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 12A and 12B illustrate an example in which an alloyed region is not formed between the layer 29 and the oxide semiconductor 30a.

Note that the thickness of the alloyed region can sometimes be calculated by performing secondary ion mass spectrometry (SIMS) or composition line analysis by energy dispersive X-ray spectroscopy (EDX) on the region and its vicinity.

For example, EDX line analysis is performed on the region and its vicinity with the direction perpendicular to the formation surface of the oxide semiconductor 30a regarded as the depth direction. Next, in profiles of quantitative values of elements in the depth direction obtained by the analysis, the depth at which the quantitative value of a metal that is the main component of the oxide semiconductor 30a and is not the main component of a layer (here, the layer 29) serving as a formation surface (the metal is In when the oxide semiconductor 30a contains In) becomes half is defined as a depth (position) of the interface between the region and the oxide semiconductor 30a. Furthermore, the depth at which the quantitative value of an element (e.g., Si) that is the main component of the layer serving as the formation surface and that is not the main component of the oxide semiconductor 30a becomes half is defined as a depth (position) of the interface between the region and the layer serving as the formation surface. In the above manner, the thickness of the alloyed region can be calculated.

For example, in the case where SIMS analysis of the oxide semiconductor 30 formed over the layer 29 that is formed using a silicon oxide layer is performed, the depth at which the silicon concentration is 50% of the maximum value of the silicon concentration of the layer 29 is defined as an interface, and the distance between the interface and the depth at which the silicon concentration decreases to 1.0×10²¹ atoms/cm⁻³, preferably 5.0×10²⁰ atoms/cm⁻³, further preferably 1.0×10²⁰ atoms/cm⁻³ is defined as a thickness t_s. The thickness t_s is preferably less than or equal to 3 nm, further preferably less than or equal to 2 nm.

Note that when the alloyed region is reduced, the CAAC structure can be formed in the vicinity of the formation surface. Here, the vicinity of the formation surface refers to, for example, a region ranging from the formation surface of the oxide semiconductor 30 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor 30.

The oxide semiconductor 30a includes a region positioned in a range of 0 nm to 3 nm, both inclusive, from the top surface of the layer 29, for example. The oxide semiconductor 30c is positioned in a range of 0 nm to 3 nm, both inclusive, from the top surface of the oxide semiconductor 30. The oxide semiconductors 30a, 30b, and 30c have substantially the same thickness, for example. Alternatively, the oxide semiconductors 30a, 30b, and 30c may have different thicknesses.

### [C-Axis Alignment Proportion]

The oxide semiconductor layer of one embodiment of the present invention has the CAAC structure. The degree of the crystallinity of the oxide semiconductor layer of one embodiment of the present invention can be evaluated with the use of crystal orientation, for example.

The CAAC structure in the oxide semiconductor layer can be evaluated from a map showing crystal orientation in some cases. In a region having the CAAC structure, for example, a state where crystals have c-axis alignment is observed.

The map showing crystal orientation can be obtained by, for example, obtaining a cross-sectional TEM image, performing fast Fourier transform (FFT) processing on each region in the cross-sectional TEM image to create an FFT pattern, and calculating the direction of the crystal axis in each region. Specifically, for example, two spots with high intensity are observed in the FFT pattern of the region including a layered crystal part. The direction of the crystal axis in the region can be obtained from the angle of a line segment connecting the two spots. The FFT pattern reflects reciprocal lattice space information like an electron diffraction pattern.

By calculating the proportion of regions having c-axis alignment from the map showing crystal orientation, the c-axis alignment proportion can be calculated.

In the oxide semiconductor layer of one embodiment of the present invention, the c-axis alignment proportion can be calculated using, for example, the above-described map indicating crystal orientation obtained through cross-sectional or plan-view TEM observation of the oxide semiconductor layer. A region subjected to FFT (also referred to as FFT window) can be a circle with a diameter of 1.0 nm, for example. Note that the region where the FFT is performed is not limited to a circle.

In the case where analysis is performed using a cross-sectional TEM image, the cross-sectional TEM image observation range is, for example, a region having a width of 100 nm in the horizontal direction with a direction perpendicular to the formation surface regarded as the vertical direction. Note that the observation range is not limited to this.

When the proportion of regions where the orientation is deviated from the c-axis by less than or equal to 200 is calculated as the c-axis alignment proportion in the oxide semiconductor layer of one embodiment of the present invention, for example, the c-axis alignment proportion is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%.

The c-axis alignment proportions of a region formed as the oxide semiconductor 30a, a region formed as the oxide semiconductor 30b, and a region formed as the oxide semiconductor 30c are Rc1, Rc2, and Rc3, respectively. Here, the c-axis alignment proportion is calculated as the proportion of regions where the orientation is deviated from the c-axis by less than or equal to 20°, for example. Rc2 is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%. Rc3/Rc1 is preferably higher than 1. Furthermore, Rc2/Rc1 is preferably higher than 1.

### [Composition of Oxide Semiconductor Layer]

The oxide semiconductor 30a preferably has a composition different from that of the oxide semiconductor 30b. The oxide semiconductor 30c preferably has a composition different from that of the oxide semiconductor 30b. The oxide semiconductor 30a can have the same composition as the oxide semiconductor 30c. Alternatively, the oxide semiconductors 30a and 30c can have different compositions.

The oxide semiconductor 30b preferably has a composition suitable for forming the CAAC structure. The oxide semiconductor 30b preferably contains zinc, for example. The oxide semiconductor 30b containing zinc can be a metal oxide with high crystallinity. The oxide semiconductor 30b preferably contains the element M in addition to zinc. When the oxide semiconductor 30b contains the element M, formation of oxygen vacancies in the metal oxide can be inhibited, for example. As the oxide semiconductor 30b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof is specifically used. Note that a composition in the neighborhood includes ±30% of an intended atomic ratio. It is preferable to use one or more of gallium, tin, yttrium, and aluminum as the element M.

The oxide semiconductor 30b may have a structure not containing the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of compositions include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductors 30a and 30c can be metal oxides with a high proportion of In. It is particularly preferable that the oxide semiconductors 30a and 30c each be a metal oxide having a higher proportion of In than that of the oxide semiconductor 30b. The oxide semiconductors 30a and 30c can each be formed by an ALD method, for example. It is particularly preferable to use a metal oxide in which the proportion of In is higher than that of the element M. With the use of a metal oxide having a high proportion of In, the on-state current can be increased and the frequency characteristics can be enhanced in a transistor including an oxide semiconductor layer.

An oxide semiconductor with a high In content tends to be polycrystallized. The use of a metal oxide having a polycrystalline structure for a transistor adversely affects the initial characteristics or reliability of the transistor. In the oxide semiconductor layer of one embodiment of the present invention, the crystal orientation of the oxide semiconductor 30b can be reflected in the oxide semiconductors 30a and 30c each having a high In content. Thus, polycrystallization can be inhibited even in the case where a metal oxide with a high In content is used as each of the oxide semiconductors 30a and 30c.

Alternatively, the oxide semiconductors 30a and 30c may each have a structure not containing the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed for the oxide semiconductors 30a and 30c. Specifically, a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, or a composition of In:Sn:Zn=2:0.1:1 [atomic ratio] or in the neighborhood thereof can be used.

As the oxide semiconductors 30a and 30c, a metal oxide having a high Ga proportion can be used. For example, as the oxide semiconductors 30a and 30c, a metal oxide having a Ga proportion higher than that of the oxide semiconductor 30b can be used. For the oxide semiconductors 30a and 30c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductors 30a and 30c can be larger than that of the oxide semiconductor 30b in some cases. Thus, the oxide semiconductor 30b is sandwiched between the oxide semiconductors 30a and 30c each having a wide band gap, so that the oxide semiconductor 30b can mainly function as a current path (channel). Furthermore, trap states at and near the interfaces with the oxide semiconductor 30b can be reduced. Accordingly, a buried-channel transistor where a channel is away from the interface with an insulating layer can be achieved, whereby the field-effect mobility can be increased. Furthermore, the influence of interface states that might be formed on the back channel side is reduced, so that photodeterioration (e.g., negative bias photodeterioration) of the transistor can be inhibited and the reliability of the transistor can be increased.

Alternatively, one of the oxide semiconductors 30a and 30c can be a metal oxide with a higher In proportion than the oxide semiconductor 30b, and the other can be a metal oxide with a higher Ga proportion than the oxide semiconductor 30b.

The oxide semiconductors 30a, 30b, and 30c may each include a stack of layers having the above compositions. For example, the oxide semiconductor 30c may have a structure where a metal oxide with a high Ga proportion is stacked over a metal oxide with a high In proportion.

A metal oxide having the same composition as the oxide semiconductor 30b may be used for the oxide semiconductors 30a and 30c. By using the same composition, the oxide semiconductors easily have the CAAC structure after heat treatment in some cases.

In the oxide semiconductor layer of one embodiment of the present invention, even in the case where a composition in which the CAAC structure is less likely to be formed in the formation of a single layer is used for the oxide semiconductors 30a and 30c, crystal growth occurs with the oxide semiconductor 30b as a nucleus, so that the whole oxide semiconductor layer including the oxide semiconductors 30a and 30c can have the CAAC structure. Alternatively, the CAAC structure can be formed in a region that includes the oxide semiconductor 30b and at least part of each of the oxide semiconductors 30a and 30c.

Analysis of the composition of the metal oxide used as the oxide semiconductor 30 can be performed by EDX, X-ray photoelectron spectroscopy (XPS), inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [Impurities in Oxide Semiconductor]

The influence of impurities in the oxide semiconductor will be described here. The impurities contained in the oxide semiconductor can be quantified by XPS, SIMS, EDX, ICP-MS, ICP-AES, or the like.

It is preferable that a channel formation region of a transistor including an oxide semiconductor in a semiconductor layer contain less oxygen vacancies or have a lower concentration of impurities such as hydrogen, nitrogen, and a metal element than a source region and a drain region. When oxygen vacancies (Vo) and impurities are in a channel formation region of an oxide semiconductor, electrical characteristics of the transistor may easily vary and the reliability thereof may worsen. In some cases, hydrogen in the vicinity of the oxygen vacancies forms VoH and generates an electron serving as a carrier. Thus, if the channel formation region in the oxide semiconductor includes oxygen vacancies, the transistor tends to have normally-on characteristics. Thus, VoH in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the concentration of impurities in the oxide semiconductor is effective. Examples of the impurities include hydrogen, carbon, and nitrogen. Note that impurities in an oxide semiconductor refer to, for example, elements other than the main components of the oxide semiconductor. For example, an element with a concentration lower than 1 atomic % or lower than 0.1 atomic % is an impurity in some cases.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm⁻³, preferably lower than or equal to 5×10¹⁹ atoms/cm⁻³, further preferably lower than or equal to 3×10¹⁹ atoms/cm⁻³, still further preferably lower than or equal to 1×10¹⁹ atoms/cm⁻³, yet further preferably lower than or equal to 3×10¹⁸ atoms/cm⁻³, yet still further preferably lower than or equal to 1×10¹⁸ atoms/cm⁻³. The silicon concentration in the channel formation region of the oxide semiconductor, which is measured by SIMS, is lower than or equal to 1×10²⁰ atoms/cm⁻³, preferably lower than or equal to 5×10¹⁹ atoms/cm⁻³, further preferably lower than or equal to 3×10¹⁹ atoms/cm⁻³, still further preferably lower than or equal to 1×10¹⁹ atoms/cm⁻³, yet further preferably lower than or equal to 3×10¹⁸ atoms/cm⁻³, yet still further preferably lower than or equal to 1×10¹⁸ atoms/cm⁻³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm⁻³, preferably lower than or equal to 5×10¹⁹ atoms/cm⁻³, further preferably lower than or equal to 1×10¹⁹ atoms/cm⁻³, still further preferably lower than or equal to 5×10¹⁸ atoms/cm⁻³, yet further preferably lower than or equal to 1×10¹⁸ atoms/cm⁻³, yet still further preferably lower than or equal to 5×10¹⁷ atoms/cm⁻³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier in some cases. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm⁻³, preferably lower than 5×10¹⁹ atoms/cm⁻³, further preferably lower than 1×10¹⁹ atoms/cm⁻³, still further preferably lower than 5×10¹⁸ atoms/cm⁻³, yet further preferably lower than 1×10¹⁸ atoms/cm⁻³, yet still further preferably lower than 1×10¹⁷ atoms/cm⁻³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm⁻³, preferably lower than or equal to 2×10¹⁶ atoms/cm⁻³.

When an oxide semiconductor with sufficiently reduced impurities is used for a channel formation region of a transistor, the transistor can have stable electrical characteristics.

The average thickness of the oxide semiconductor 30 in the channel formation region is preferably less than or equal to 30 nm, further preferably less than or equal to 15 nm, still further preferably less than or equal to 10 nm.

The oxide semiconductor 30a is an oxide semiconductor layer formed on the formation surface. The thickness of the oxide semiconductor 30a is preferably greater than or equal to 0.5 nm and less than or equal to 3 nm.

In cross-sectional observation of the oxide semiconductor 230 in the semiconductor device of one embodiment of the present invention, a state can sometimes be observed where metal atoms included in a metal oxide are arranged in a layered manner in a region having the CAAC structure. In that case, the metal atoms are arranged in a direction perpendicular or substantially perpendicular to the substrate surface, for example.

The metal atoms arranged in a layered manner in the region having the CAAC structure can be observed as arranged bright spots in the cross-sectional TEM image of the oxide semiconductor layer. Thus, when a cross section of the oxide semiconductor 230 in the semiconductor device of one embodiment of the present invention is observed, a state can sometimes be observed where bright spots are arranged in a direction perpendicular or substantially perpendicular to the substrate surface.

The oxide semiconductor 30 that is the AG CAAC can be used as the oxide semiconductor 230 of the transistor 200. FIG. 2A is an enlarged view of the oxide semiconductor 230 and it vicinity in FIG. 1B in the case where the oxide semiconductor 230 includes the oxide semiconductor 230a, the oxide semiconductor 230b in contact with the oxide semiconductor 230a, and the oxide semiconductor 230c in contact with the oxide semiconductor 230b. Here, the oxide semiconductors 230a, 230b, and 230c correspond to the oxide semiconductors 30a, 30b, and 30c, respectively. FIG. 2B is an enlarged view of the oxide semiconductor 230 and its vicinity in FIG. 1C in the case where the oxide semiconductor 230 includes the oxide semiconductor 230a, the oxide semiconductor 230b in contact with the oxide semiconductor 230a, and the oxide semiconductor 230c in contact with the oxide semiconductor 230b.

Here, the above-described pillar (the insulator 223 described later) corresponds to the layer 29. That is, the formation surface of the oxide semiconductor 230 is the pillar, and the pillar is removed in the transistor 200. In the manufacturing process, one side surface of the oxide semiconductor 230a is in contact with the pillar, and the other side surface thereof is in contact with the oxide semiconductor 230b. After the pillar is removed, the one side surface of the oxide semiconductor 230a is in contact with the insulator 250. One side surface of the oxide semiconductor 230b is in contact with the oxide semiconductor 230a, and the other side surface thereof is in contact with the oxide semiconductor 230c. One side surface of the oxide semiconductor 230c is in contact with the oxide semiconductor 230b, and the other side surface thereof is in contact with the insulator 250. Note that the side surface of the pillar is perpendicular or substantially perpendicular to the substrate surface (also referred to as the surface of the insulator 222); thus, the side surface of the oxide semiconductor 230 (the oxide semiconductors 230a to 230c) is also perpendicular or substantially perpendicular to the substrate surface.

As described above, a state where metal atoms are arranged in a layered manner in a direction parallel or substantially parallel to the formation surface is observed in a cross-sectional TEM image of the oxide semiconductor 230 (the oxide semiconductors 230a to 230c). In other words, a state where the metal atoms are arranged in a layered manner in a direction perpendicular or substantially perpendicular to the substrate surface is observed in the cross-sectional TEM image of the oxide semiconductor 230 (the oxide semiconductors 230a to 230c). The c-axis of the AG CAAC can be regarded as being substantially parallel to the normal direction of the side surface of the oxide semiconductor 230.

With the use of the oxide semiconductor 230 that is the AG CAAC in the channel formation region of the transistor 200 in this manner, the transistor can have a high on-state current, high field-effect mobility, a low S-value, excellent frequency characteristics, and high reliability.

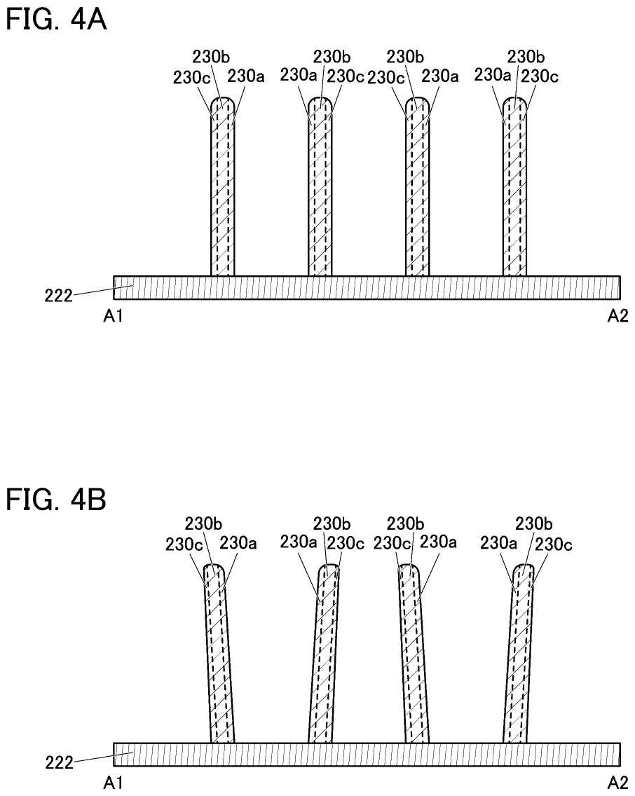

In the case where the oxide semiconductor 230 has a three-layer structure of the oxide semiconductors 230a to 230c as described above, the oxide semiconductor 230a is the closest to a region where the pillar has been formed, followed in order by the oxide semiconductor 230b and the oxide semiconductor 230c. Thus, as illustrated in FIG. 4A, the oxide semiconductor 230c, the oxide semiconductor 230b, the oxide semiconductor 230a, the oxide semiconductor 230a, the oxide semiconductor 230b, and the oxide semiconductor 230c are symmetrically arranged in this order in a cross-sectional view in the channel width direction. That is, in order that the oxide semiconductor 230 can have a symmetrical structure in a cross-sectional view, the oxide semiconductor 230a and the oxide semiconductor 230c preferably have substantially the same composition. In addition, the oxide semiconductor 230a and the oxide semiconductor 230c preferably have substantially the same thickness. In the case where the angle θ in FIG. 2A is greater than or equal to 80° and less than 90°, i.e., the side surface of the oxide semiconductor 230 is slightly inclined, the oxide semiconductors 230 are inclined symmetrically in pairs as illustrated in FIG. 4B. In the case where the oxide semiconductor 230 is formed to be inclined, the upper portion of the oxide semiconductor 230 might be thinner than the lower portion of the oxide semiconductor 230 as illustrated in FIG. 4B.

The insulator 250 in contact with the channel formation region in the oxide semiconductor 230 preferably has a function of capturing or fixing hydrogen. This can reduce the hydrogen concentration in the channel formation region in the oxide semiconductor 230. Thus, VoH in the channel formation region can be reduced, so that the channel formation region can be an i-type or substantially i-type region.

As illustrated in FIG. 3A, the insulator 250 preferably has a stacked-layer structure including the insulator 250a in contact with the oxide semiconductor 230, the insulator 250b over the insulator 250a, the insulator 250c over the insulator 250b, and the insulator 250d over the insulator 250c. In that case, the insulators 250a and 250c preferably have a function of capturing or fixing hydrogen.

An example of the insulator having a function of capturing or fixing hydrogen is a metal oxide having an amorphous structure. As the insulators 250a and 250c, for example, a metal oxide, such as magnesium oxide or an oxide containing aluminum and/or hafnium, is preferably used. In such a metal oxide having an amorphous structure, an oxygen atom has a dangling bond with which hydrogen is captured or fixed in some cases. That is, the metal oxide having an amorphous structure has high capability of capturing or fixing hydrogen.

Moreover, a high dielectric constant (high-k) material is preferably used for the insulators 250a and 250c. An example of the high-k material is an oxide containing one or both of aluminum and hafnium. With the use of the high-k material for the insulators 250a and 250c, a gate potential applied in the operation of the transistor can be reduced while the physical thickness of the gate insulator is maintained. In addition, the equivalent oxide thickness (EOT) of the insulator functioning as the gate insulator can be reduced.

For the insulators 250a and 250c, an oxide containing aluminum and/or hafnium is preferably used, and an oxide containing aluminum and/or hafnium and having an amorphous structure is further preferably used.

In this embodiment, an aluminum oxide film is used as the insulator 250a. The aluminum oxide film preferably has an amorphous structure. When the insulator 250a is provided in contact with the oxide semiconductor 230, hydrogen contained in the oxide semiconductor 230 or the like can be captured or fixed more effectively.

In this embodiment, hafnium oxide is used for the insulator 250c. When the insulator 250c is provided between the insulator 250b and the insulator 250d, hydrogen contained in the insulator 250b or the like can be captured or fixed more effectively.

An insulator having thermal stability, such as silicon oxide or silicon oxynitride, is preferably used as the insulator 250b. Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

A silicon oxide film used as the insulator 250b is preferably formed by a PEALD method.

In order to inhibit oxidation of the conductors 242a, 242b, and 260, a barrier insulator against oxygen is preferably provided in the vicinity of each of the conductors 242a, 242b, and 260. In the semiconductor device described in this embodiment, the insulator corresponds to, for example, the insulator 250a, the insulator 250d, the insulator 250c, and the insulator 275.

Note that in this specification and the like, a barrier insulator refers to an insulator having a barrier property. In this specification and the like, “having a barrier property” means having a property of hindering the permeation of a target substance (also referred to as having a low permeability). For example, an insulator having a barrier property hardly allows a target substance to diffuse into the insulator. As another example, an insulator having a barrier property has a function of capturing or fixing (also referred to as gettering) a target substance in the insulator.

Examples of the barrier insulator against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulators 250a, 250c, 250d, and 275 preferably has a single-layer structure or a stacked-layer structure of the barrier insulator against oxygen.

The insulator 250a preferably has a barrier property against oxygen. The insulator 250a is preferably less permeable to oxygen than at least the insulator 280 is. The insulator 250a includes a region in contact with the side surface of the conductor 242a and the side surface of the conductor 242b. When the insulator 250a has a barrier property against oxygen, oxidation of the side surfaces of the conductors 242a and 242b and formation of oxide films on the side surfaces can be inhibited. Accordingly, a reduction in on-state current or field-effect mobility of the transistor 200 can be inhibited.

The insulator 250a is provided in contact with the top and side surfaces of the oxide semiconductor 230 and the top surface of the insulator 222. When the insulator 250a has a barrier property against oxygen, release of oxygen from the channel formation region in the oxide semiconductor 230 caused by heat treatment or the like can be prevented. This can inhibit formation of oxygen vacancies in the oxide semiconductor 230.

When the insulator 250a is provided, oxygen can be inhibited from being excessively supplied from the insulator 280 to the oxide semiconductor 230, and an appropriate amount of oxygen can be supplied to the oxide semiconductor 230. Thus, excessive oxidation of the source and drain regions can be inhibited, and a reduction in on-state current or field-effect mobility of the transistor 200 can be inhibited.

The oxide containing aluminum and/or hafnium has a barrier property against oxygen and thus can be suitably used for the insulator 250a.

The insulator 250d also preferably has a barrier property against oxygen. The insulator 250d is provided between the conductor 260 and the channel formation region in the oxide semiconductor 230 and between the insulator 280 and the conductor 260. Such a structure can inhibit oxygen contained in the channel formation region in the oxide semiconductor 230 from diffusing into the conductor 260 and thus can inhibit formation of oxygen vacancies in the channel formation region in the oxide semiconductor 230. Oxygen contained in the oxide semiconductor 230 and oxygen contained in the insulator 280 can be inhibited from diffusing into the conductor 260 and oxidizing the conductor 260. The insulator 250d is preferably less permeable to oxygen than at least the insulator 280 is. For example, a silicon nitride film is preferably used as the insulator 250d. In that case, the insulator 250d contains at least nitrogen and silicon.

The insulator 250d preferably has a barrier property against hydrogen. This can prevent diffusion of impurities contained in the conductor 260, such as hydrogen, into the oxide semiconductor 230.

The insulator 275 also preferably has a barrier property against oxygen. The insulator 275 is provided between the insulator 280 and the conductor 242a and between the insulator 280 and the conductor 242b. The insulator 275 is provided in contact with the side surface of the conductor 242, the side surface of the oxide semiconductor 230, and the top surface of the insulator 222. This structure can inhibit diffusion of oxygen contained in the insulator 280 into the conductor 242. Accordingly, oxidation of the conductor 242 by oxygen contained in the insulator 280 can be inhibited, so that an increase in resistivity due to the oxidation can be inhibited. The insulator 275 is preferably less permeable to oxygen than at least the insulator 280 is. For example, silicon nitride is preferably used for the insulator 275. In that case, the insulator 275 contains at least nitrogen and silicon.

In order to inhibit a reduction in the hydrogen concentration in the source and drain regions in the oxide semiconductor 230, a barrier insulator against hydrogen is preferably provided in the vicinity of each of the source and drain regions. In the semiconductor device described in this embodiment, the barrier insulator against hydrogen corresponds to, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

Providing the insulator 275 described above can reduce the amount of hydrogen diffusing from the source and drain regions to the outside, so that a reduction in the hydrogen concentration in the source and drain regions can be inhibited. Thus, the source and drain regions can be n-type regions.

With the above structure, the i-type or substantially i-type channel formation region and the n-type source and drain regions can be formed; therefore, a semiconductor device with favorable electrical characteristics can be provided. The semiconductor device with the above structure can have favorable electrical characteristics even when being miniaturized or highly integrated. Furthermore, miniaturization of the transistor 200 can improve the high-frequency characteristics. Specifically, the cutoff frequency can be improved.

The insulators 250a to 250d function as a part of the gate insulator. The insulators 250a to 250d are provided together with the conductor 260 in the opening formed in the insulator 280 and the like. The thickness of each of the insulators 250a to 250d is preferably small for miniaturization of the transistor 200. The thickness of each of the insulators 250a to 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each of the insulators 250a to 250d at least partly includes a region with the above thickness.

The thickness of the silicon oxide film used as the insulator 250b is preferably greater than or equal to 0.7 nm and less than or equal to 3 nm.

In order that the insulators 250a to 250d have small thicknesses as described above, an atomic layer deposition (ALD) method is preferably employed. Furthermore, in order that the insulators 250a to 250d be provided in the opening in the insulator 280 and the like, an ALD method is preferably employed. Examples of the ALD method include a thermal ALD method, in which a precursor and a reactant react with each other only by a thermal energy, and a plasma-enhanced ALD (PEALD) method, in which a reactant excited by plasma is used. The use of plasma is sometimes preferable because film formation at a lower temperature is possible in a PEALD method.

The ALD method enables atomic layers to be deposited one by one, and has advantages such as formation of an extremely thin film, formation of a film on a component with a high aspect ratio, formation of a film with few defects such as pinholes, formation of a film with excellent coverage, and low-temperature film formation. Thus, the insulator 250 can be formed on the side surface of the opening formed in the insulator 280, the side end portions of the conductors 242a and 242b, and the like to have a small thickness as described above and to have excellent coverage.

Note that a precursor used in the ALD method sometimes contains carbon or the like. Thus, a film formed by the ALD method may contain impurities such as carbon in a larger amount than a film formed by another film formation method. Note that impurities can be quantified by secondary ion mass spectrometry (SIMS), X-ray photoelectron spectroscopy (XPS), or auger electron spectroscopy (AES).

Although the case where the insulator 250 has a four-layer structure of the insulators 250a to 250d is described above, the present invention is not limited to this structure. The insulator 250 can have a structure including at least one of the insulators 250a to 250d. When the insulator 250 is formed of one, two, or three layer(s) of the insulators 250a to 250d, the manufacturing process of a semiconductor device can be simplified and the productivity can be improved.

For example, as illustrated in FIG. 3B, the insulator 250 may have a three-layer structure. In that case, the insulator 250 preferably has a stacked-layer structure of the insulator 250a, the insulator 250b over the insulator 250a, and the insulator 250c over the insulator 250b. That is, the stacked-layer structure is obtained by removing the insulator 250d from the structure illustrated in FIG. 3A.

In the formation of the insulator 250, an ALD process is preferably used twice or more. For example, the insulator 250 preferably has a stacked-layer structure of a plurality of insulating films, and two or more of the plurality of insulating films are preferably formed through an ALD process. When at least two insulating films are formed through an ALD process, the coverage with the insulator 250 and the thickness uniformity of the insulator 250 can be improved. Moreover, the productivity can be increased when two or more kinds of different films, e.g., two or more insulating films, are successively formed through an ALD process.

In addition to the above structure, a structure is preferably employed in which entry of hydrogen into the transistor 200 and the like is inhibited. For example, an insulator having a function of inhibiting diffusion of hydrogen is preferably provided over and/or under the transistor 200 and the like. In the semiconductor device described in this embodiment, the insulator corresponds to, for example, the insulator 283, the insulator 282, the insulator 222, and the insulator 221. The insulator 215 provided under the transistor 200 may have a structure similar to the structure(s) of the insulator 282 and/or the insulator 283. In that case, the insulator 215 may have a stacked-layer structure of the insulator 282 and the insulator 283; the insulator 283 may be positioned over the insulator 282 or the insulator 282 may be positioned over the insulator 283.

At least one of the insulators 283, 282, 222, and 221 preferably functions as a barrier insulator that inhibits diffusion of impurities such as water and hydrogen into the transistor 200 and the like from the substrate side or from above the transistor 200 and the like. Therefore, at least one of the insulators 283, 282, 222, and 221 preferably contains an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material through which the above impurities are less likely to pass. Alternatively, at least one of the insulators 283, 282, 222, and 221 preferably contains an insulating material having a function of inhibiting diffusion of oxygen (e.g., at least one of an oxygen atom, an oxygen molecule, and the like), that is, an insulating material through which the oxygen is less likely to pass.

Each of the insulators 283, 282, 222, and 221 preferably includes an insulator having a function of inhibiting diffusion of oxygen and impurities such as water and hydrogen. Examples of the insulator include aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, silicon nitride, and silicon nitride oxide. For example, silicon nitride, which has a higher hydrogen barrier property, is preferably used for the insulators 283 and 221. For example, aluminum oxide, which has high capability of capturing or fixing hydrogen, is preferably used for the insulator 282. For example, hafnium oxide, which has high capability of capturing or fixing hydrogen and is a high dielectric constant (high-k) material, is preferably used for the insulator 222.

Note that at least one of the insulators 221 and 222 can have a stacked-layer structure of the above-described material and silicon oxide or silicon oxynitride. For example, the insulator 221 can have a stacked-layer structure of silicon nitride and silicon oxide. For example, the insulator 222 can be a stack of hafnium oxide and silicon oxide.

Such a structure can inhibit impurities such as water and hydrogen from diffusing into the transistor 200 or the like from an interlayer insulating film or the like positioned above the insulator 283. Furthermore, impurities such as water and hydrogen can be inhibited from diffusing into the transistor 200 or the like from an interlayer insulating film or the like positioned below the insulator 221. Moreover, hydrogen contained in the insulators 280 and 250 and the like can be captured and fixed in the insulator 282 or the insulator 222. Providing the insulators 282 and 283 can inhibit oxygen contained in the insulator 280 and the like from diffusing to the components over the transistor 200 or the like. Providing the insulators 222 and 221 can inhibit oxygen contained in the oxide semiconductor 230 and the like from diffusing to the components under the transistor 200 or the like. With such a structure where the transistor 200 is surrounded by upper and lower insulators having a function of inhibiting diffusion of oxygen and impurities such as water and hydrogen, excess oxygen and hydrogen can be prevented from diffusing into the oxide semiconductor. This can improve the electrical characteristics and reliability of the semiconductor device.

Moreover, silicon nitride, which has a higher hydrogen barrier property, is preferably used for the insulators 275 and 250d, for example. Aluminum oxide, which has high capability of capturing or fixing hydrogen, is preferably used for the insulator 250a, for example. Hafnium oxide, which has high capability of capturing or fixing hydrogen, is preferably used for the insulator 250c, for example.

### <Materials for Semiconductor Device>

Materials that can be used for the semiconductor device will be described below. Note that the layers included in the semiconductor device may each have a single-layer structure or a stacked-layer structure.

### <<Substrate>>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, such as a silicon-on-insulator (SOI) substrate. Examples of the conductor substrate include a graphite substrate, a metal substrate, an alloy substrate, and a conductive resin substrate. Examples of the substrate include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided over the substrate include a capacitor, a resistor, a switching element, a light-emitting element, and a memory element.

### <<Insulator>>

Examples of the insulators 215, 216, 221, 222, 241, 250, 275, 280, 282, 283, 285, 315, 320, 322, 324, 326, 454, and the like include an insulating oxide, an insulating nitride, an insulating oxynitride, an insulating nitride oxide, an insulating metal oxide, an insulating metal oxynitride, and an insulating metal nitride oxide.

With miniaturization and high integration of a transistor, for example, a problem such as generation of leakage current may arise because of a thin gate insulator. When a high-k material is used for the insulator functioning as a gate insulator, the voltage at the time of operation of the transistor can be reduced while the physical thickness is maintained. By contrast, when a material having a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting passage of oxygen and impurities such as hydrogen. The insulator having a function of inhibiting passage of oxygen and impurities such as hydrogen can have, for example, a single-layer structure or a stacked-layer structure of an insulator(s) including one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating can be provided in contact with the oxide semiconductor 230 to compensate for the oxygen vacancies in the oxide semiconductor 230.

### <<Conductor>>

For the conductors 240, 242, 260, 316, 328, 330, 413, 413b, 456, and the like, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductors include tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high conductivity, typified by polycrystalline silicon containing an impurity element such as phosphorus, or silicide such as nickel silicide may be used.

In the case where a stacked-layer structure of conductors is used, for example, a stacked-layer structure combining a material containing any of the metal elements and a conductive material containing oxygen, a stacked-layer structure combining a material containing any of the metal elements and a conductive material containing nitrogen, or a stacked-layer structure combining a material containing any of the above metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing any of the above metal elements and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where a channel is formed can be captured in some cases. Hydrogen entering from an outer insulator or the like can also be captured in some cases.

### Example 1 of Method for Manufacturing Semiconductor Device

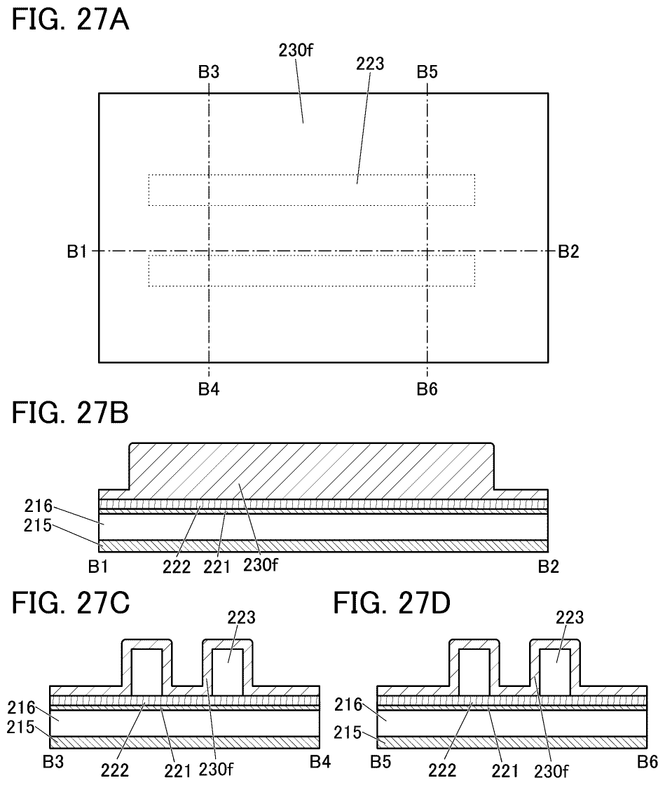

An example of a method for manufacturing the semiconductor device of one embodiment of the present invention will be described with reference to FIGS. 27A to 34D. Here, the case of manufacturing the semiconductor device illustrated in FIGS. 14A to 15B will be described as an example.

In the following steps, an insulating material for forming an insulator, a conductive material for forming a conductor, or a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of the sputtering method include an RF sputtering method in which a high-frequency power source is used for a sputtering power source, a DC sputtering method in which a DC power source is used, and a pulsed DC sputtering method in which voltage applied to an electrode is changed in a pulsed manner. The RF sputtering method is mainly used for forming an insulating film, and the DC sputtering method is mainly used for forming a metal conductive film. The pulsed DC sputtering method is mainly used for forming a film of a compound such as an oxide, a nitride, or a carbide by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during film formation.

As the ALD method, a thermal ALD method, in which a precursor and a reactant react with each other only by a thermal energy, a PEALD method, in which a reactant excited by plasma is used, or the like can be used.

A CVD method and an ALD method differ from a sputtering method in which particles ejected from a target or the like are deposited. Thus, a CVD method and an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method in which a plurality of different kinds of precursors are introduced at a time enables formation of a film with a desired composition. In the case where a plurality of different kinds of precursors are introduced, the number of cycles for each precursor is controlled, whereby a film with a desired composition can be formed.

In the following steps, dry etching, wet etching, or the like can be used in etching treatment.

As an etching gas for the dry etching treatment, for example, a gas containing a halogen can be used.

As the gas containing a halogen, for example, an etching gas containing one or more of fluorine, chlorine, and bromine can be used. A fluorocarbon gas, a hydrofluorocarbon gas, a SF₆ gas, a Cl₂ gas, a BCl₃ gas, a SiCl₄ gas, a BBr₃ gas, and the like can be used alone or in combination. As the fluorocarbon gas, a gas represented by CₓF_{y} (y≤2x+2) can be used. Examples of the fluorocarbon gas satisfying y=2x+2 include saturated carbon fluoride compounds such as CF₄, C₂F₆, C₃F₈, C₄F₁₀, and CsF₁₂. Examples of the fluorocarbon gas satisfying y<2x+2 include unsaturated carbon fluoride compounds such as C₂F₄, C₂F₂, C₃F₇, C₃F₄, C₄F₈, C₄F₆, C₄F₄, C₄F₂, C₅F₁₀, C₅F₈, C₅F₆, and C₅F₄. Examples of the hydrofluorocarbon gas include a CHF₃ gas and a CH₂F₂ gas.

In the case where the gas containing a halogen is used as the etching gas, an oxygen (O₂) gas, a carbonic acid gas, a nitrogen (N₂) gas, a helium gas, an argon gas, a hydrogen gas, a hydrocarbon gas, or the like can be added as appropriate.

A gas containing a hydrocarbon gas or a hydrogen gas and not containing a halogen gas can be used as the etching gas.

As the hydrocarbon gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used, for example.

In the case where the hydrocarbon gas is used as the etching gas, a nitrogen gas, a helium gas, an argon gas, a hydrogen gas, or the like can be added as appropriate.

As a dry etching apparatus, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, different high-frequency voltages may be applied to one of the parallel plate electrodes. Further alternatively, high-frequency voltages with the same frequency may be applied to the parallel plate electrodes. Still further alternatively, high-frequency voltages with different frequencies may be applied to the parallel plate electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched.

In the method for manufacturing the semiconductor device of one embodiment of the present invention, a lithography method can be suitably used. In the lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to KrF excimer laser light, ArF excimer laser light, or extreme ultraviolet (EUV) light, for example. A liquid immersion technique may be employed in which a portion between a substrate and a projection lens is filled with a liquid (e.g., water) to perform light exposure. An electron beam or an ion beam may be used instead of the above-mentioned light. Note that a mask may be unnecessary in the case of using an electron beam or an ion beam in some cases.

To remove the resist mask which is no longer needed after the processing, dry etching treatment such as ashing using oxygen plasma (hereinafter referred to as oxygen plasma treatment in some cases) or wet etching treatment may be performed. Alternatively, wet etching treatment may be performed after dry etching treatment, or dry etching treatment may be performed after wet etching treatment.

A hard mask formed of an insulator or a conductor may be used under the resist mask. In the case of using a hard mask, a hard mask with a desired shape can be formed in the following manner: an insulating film or a conductive film that is the material of the hard mask is formed over a conductive film, an insulating film, a semiconductor film, or the like to be processed, a resist mask is formed thereover, and then the hard mask material is etched. The etching of the conductive film, the insulating film, the semiconductor film, or the like may be performed after or without removal of the resist mask. In the latter case, the resist mask sometimes disappears during the etching. The hard mask may be removed by etching after the etching of the conductive film, the insulating film, the semiconductor film, or the like. The hard mask does not need to be removed when the hard mask material does not affect the following process or can be utilized in the following process.

A spin on carbon (SOC) film and a spin on glass (SOG) film may be formed between an object to be processed and the resist mask. Using the SOC film and the SOG film as a mask can improve the durability of a mask pattern. For example, the SOC film, the SOG film, and the resist mask are formed in this order over the object to be processed and lithography can be performed.

First, a substrate (not illustrated) is prepared, and the insulator 215 is formed over the substrate (see FIGS. 27A to 27D).

FIGS. 27A, 28A, 29A, 30A, 31A, 32A, 33A, and 34A are plan views. FIGS. 27B, 28B, 29B, 30B, 31B, 32B, 33B, and 34B are cross-sectional views taken along the dashed-dotted lines B1-B2 in FIGS. 27A, 28A, 29A, 30A, 31A, 32A, 33A, and 34A. FIGS. 27C, 28C, 29C, 30C, 31C, 32C, 33C, and 34C are cross-sectional views taken along the dashed-dotted lines B3-B4 in FIGS. 27A, 28A, 29A, 30A, 31A, 32A, 33A, and 34A. FIGS. 27D, 28D, 29D, 30D, 31D, 32D, 33D, and 34D are cross-sectional views taken along the dashed-dotted lines B5-B6 in FIGS. 27A, 28A, 29A, 30A, 31A, 32A, 33A, and 34A. For simplification, some components are not illustrated in the plan views in FIGS. 27A, 28A, 29A, 30A, 31A, 32A, 33A, and 34A.

As described above, the insulator 215 can be formed with the same insulator as either the insulator 282 or the insulator 283 or a stacked film including both of them. The insulator 215 can be formed by a sputtering method, a CVD method, an MBE method, a PLD method, or an ALD method, for example. A sputtering method which does not need to use a molecule containing hydrogen as a film formation gas is preferably used, in which case the hydrogen concentration in the insulator 215 can be reduced.

Next, the insulator 216 is formed over the insulator 215. The insulator 216 is preferably formed by a sputtering method. By using a sputtering method that does not need to use a molecule containing hydrogen as a film formation gas, the hydrogen concentration in the insulator 216 can be reduced. Note that the insulator 216 can be formed by a CVD method, an MBE method, a PLD method, or an ALD method, for example, instead of the sputtering method. In this embodiment, a silicon oxide film is formed as the insulator 216 by a sputtering method.

The insulators 215 and 216 are preferably formed successively without exposure to the air. For example, a multi-chamber film formation apparatus is used. As a result, the amount of hydrogen in the formed insulators 215 and 216 can be reduced, and furthermore, entry of hydrogen in the films, adsorption of moisture on the film surfaces, and the like between film formation steps can be inhibited.

When an opening reaching the insulator 215 is formed in the insulator 216 and the conductor 205 is formed in the opening, the conductor 205 included in the transistor 200 illustrated in FIGS. 11A to 11D can be formed. Specifically, for example, the conductor 205 is formed in the following manner: a conductive film that can be used for the conductor 205 is formed to fill the opening and part of the conductive film is removed by CMP treatment.

Next, the insulator 221 is formed over the insulator 216 (see FIGS. 27A to 27D).

The above-described insulator having a barrier property against oxygen, hydrogen, and water is used as the insulator 221. The insulator 221 can be formed by a sputtering method, a CVD method, an MBE method, a PLD method, or an ALD method, for example. In this embodiment, a silicon nitride film is formed as the insulator 221 by a PEALD method.

Next, the insulator 222 is formed over the insulator 221 (see FIGS. 27A to 27D).

The insulator 222 is preferably formed using an insulator containing an oxide of one or both of aluminum and hafnium. Note that as the insulator containing an oxide of one or both of aluminum and hafnium, aluminum oxide, hafnium oxide, or an oxide containing aluminum and hafnium (hafnium aluminate) is preferably used, for example. Alternatively, hafnium zirconium oxide is preferably used. The insulator containing an oxide of one or both of aluminum and hafnium has a barrier property against oxygen, hydrogen, and water. When the insulator 222 has a barrier property against hydrogen and water, hydrogen and water contained in a component provided around the transistor can be inhibited from diffusing into the transistor through the insulator 222, and accordingly oxygen vacancies can be inhibited from being generated in the oxide semiconductor 230.

The insulator 222 can be formed by a sputtering method, a CVD method, an MBE method, a PLD method, or an ALD method, for example. In this embodiment, a hafnium oxide film is formed as the insulator 222 by a thermal ALD method.

In this embodiment, a silicon nitride film is formed as the insulator 221 by a PEALD method, and a hafnium oxide film is formed as the insulator 222 by a thermal ALD method. The use of silicon nitride having a function of inhibiting diffusion of hydrogen for the insulator 221 can inhibit diffusion of hydrogen from a layer below the transistor 200. Furthermore, the use of hafnium oxide having a function of capturing or fixing hydrogen for the insulator 222 enables hydrogen contained in the oxide semiconductor 230 to be captured or fixed by the insulator 222. This can reduce the hydrogen concentration in the oxide semiconductor 230 and in the vicinity thereof.

Next, an insulating film is formed over the insulator 222 and etched, whereby the insulator 223 is formed (see FIGS. 27A to 27D). The insulator 223 functions as a template for forming the oxide semiconductor 230. The insulator 223 can be formed using an insulator that can be used as the insulator 216, for example.

The insulator 223 can be formed by a sputtering method, a CVD method, an MBE method, a PLD method, or an ALD method, for example. In this embodiment, a silicon oxide film is formed as the insulator 223 by a sputtering method.

The insulator 223 is processed into an island shape by a lithography method. The processing can be performed by a dry etching method or a wet etching method. A dry etching method is suitable for microfabrication. In this embodiment, two columnar insulators 223 are formed so as to be arranged in the B3-B4 direction as illustrated in FIGS. 27A to 27D.

As illustrated in FIGS. 27B to 27D, the side surface of the insulator 223 may be perpendicular or substantially perpendicular to the top surface of the insulator 222. This structure enables a plurality of transistors to be provided in a small area at high density.

Next, an oxide semiconductor film 230f to be the oxide semiconductor 230 is formed to cover the insulator 223 (see FIGS. 27A to 27D). The oxide semiconductor film 230f is a metal oxide film to be the oxide semiconductor 230 in a later step, and the above-described metal oxide film can be used as the oxide semiconductor film 230f. The oxide semiconductor film 230f can be formed by a sputtering method, a CVD method, an MBE method, a PLD method, or an ALD method, for example.

The oxide semiconductor film 230f preferably has excellent coverage so that the oxide semiconductor film 230f is formed along the insulator 223. Accordingly, the oxide semiconductor film 230f is preferably formed by an ALD method or the like, which offers excellent coverage. The oxide semiconductor 230 preferably has a high aspect ratio; thus, the oxide semiconductor film 230f is preferably thin. Hence, the oxide semiconductor film 230f is preferably formed by an ALD method that allows the thickness of a thin film to be adjusted. The oxide semiconductor film 230f formed in this manner is in contact with the top and side surfaces of the insulator 223.

Here, the oxide semiconductor film 230f is preferably formed by the same method as the oxide semiconductor 30 described above. When the oxide semiconductor film 230f is formed using such a method, the oxide semiconductor film 230f and the oxide semiconductor 230 are formed to be parallel or substantially parallel to the formation surface. The formation surface of the oxide semiconductor 230 corresponds to, for example, the top surface of the insulator 222, the side surface of the insulator 223, and the top surface of the insulator 223.

The oxide semiconductor 230 preferably has the CAAC structure. An oxide semiconductor layer having the CAAC structure includes a layered crystal part, and metal atoms are arranged in the crystal part in a layered manner, for example. The metal atoms arranged in a layered manner are arranged in a direction parallel to the formation surface, for example. In the case where the side surface of the insulator 223 is perpendicular or substantially perpendicular to the top surface of the insulator 222, the metal atoms in the oxide semiconductor 230 are arranged in a direction perpendicular or substantially perpendicular to the top surface of the insulator 222, for example.

In the case where the oxide semiconductor 230 has a three-layer structure of the oxide semiconductors 230a to 230c as illustrated in FIG. 2A and the like, films to be the oxide semiconductors 230a and 230c may be formed by an ALD method and a film to be the oxide semiconductor 230b may be formed by a sputtering method. Specifically, the film to be the oxide semiconductor 230a can be formed to have a composition of In:Zn=2:1 [atomic ratio] or in the neighborhood thereof. Alternatively, indium oxide may be used for the film to be the oxide semiconductor 230a. The film to be the oxide semiconductor 230b can be formed using an oxide target with a composition of In:Sn:Zn=4:0.1:1 [atomic ratio] or in the neighborhood thereof. The film to be the oxide semiconductor 230c can be formed to have a composition of In:Zn=2:1 [atomic ratio] or in the neighborhood thereof. Alternatively, indium oxide may be used for the film to be the oxide semiconductor 230c. Note that the three-layer structure of the oxide semiconductors 230a to 230c is not limited to the above example. For example, each of the oxide semiconductors 230a to 230c can be formed by an ALD method. Since a sputtering method is not used in such a case, successive formation in one manufacturing apparatus can be performed and thus the manufacturing cost can be reduced. Note that microwave treatment may be performed after each of the oxide semiconductors 230a to 230c is formed. The microwave treatment can improve the crystallinity of the oxide semiconductor 230.

Next, heat treatment is preferably performed. The heat treatment is preferably performed in a temperature range where the oxide semiconductor film 230f does not become polycrystal. The heat treatment of the oxide semiconductor film 230f can be performed by the same method as the heat treatment of the oxide semiconductor 30 described above.

For example, heat treatment can be performed at 450° C. for one hour at a flow rate ratio of a nitrogen gas to an oxygen gas of 4:1.

When the oxide semiconductor 230 is formed by the above-described method and heat treatment is performed, the oxide semiconductor 230 can be the AG CAAC. Accordingly, the on-state current, the S value, the field-effect mobility, the frequency characteristics, and the like of the transistor 200 can be improved, so that a semiconductor device having favorable electrical characteristics can be provided. Moreover, a highly reliable semiconductor device can be provided.

Note that the heat treatment is preferably performed in a nitrogen gas atmosphere, an inert gas atmosphere, or an atmosphere containing an oxidizing gas at 10 ppm or more, 1% or more, or 10% or more. The heat treatment may be performed under reduced pressure. Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is preferably less than or equal to 1 ppb, further preferably less than or equal to 0.1 ppb, still further preferably less than or equal to 0.05 ppb. The heat treatment using a highly purified gas can prevent the entry of moisture or the like into the oxide semiconductor film 230f and the like as much as possible. Note that a highly purified gas can also be used in heat treatment before this step and heat treatment after this step.

With the heat treatment using the above-described oxygen gas, impurities such as carbon, water, and hydrogen in the oxide semiconductor film 230f can be reduced. Impurities in the film are reduced in the above manner, whereby the crystallinity of the oxide semiconductor film 230f can be improved and a denser structure can be obtained. Accordingly, the crystal region in the oxide semiconductor film 230f can be increased, and in-plane variation of crystal regions in the oxide semiconductor film 230f can be reduced. Thus, in-plane variation in the electrical characteristics of the transistors can be reduced.

The heat treatment can supply oxygen to the oxide semiconductor film 230f to reduce oxygen vacancies in the oxide semiconductor film 230f. Thus, the reliability of the transistor 200 can be improved.

By the heat treatment, hydrogen contained in the oxide semiconductor film 230f is transferred to the insulator 222 and is absorbed by the insulator 222. In other words, hydrogen contained in the oxide semiconductor film 230f diffuses into the insulator 222. Accordingly, the hydrogen concentration in the insulator 222 increases, whereas the hydrogen concentration in the oxide semiconductor film 230f decreases. Note that the insulator 221 is provided in contact with the bottom surface of the insulator 222, whereby entry of moisture or impurities such as hydrogen from below the insulator 221, which is caused by the heat treatment, can be prevented.

Specifically, the oxide semiconductor film 230f (to be the oxide semiconductor 230 later) functions as the channel formation region of the transistor 200. The transistor 200 formed using the oxide semiconductor film 230f with a reduced hydrogen concentration is preferable because of its high reliability.

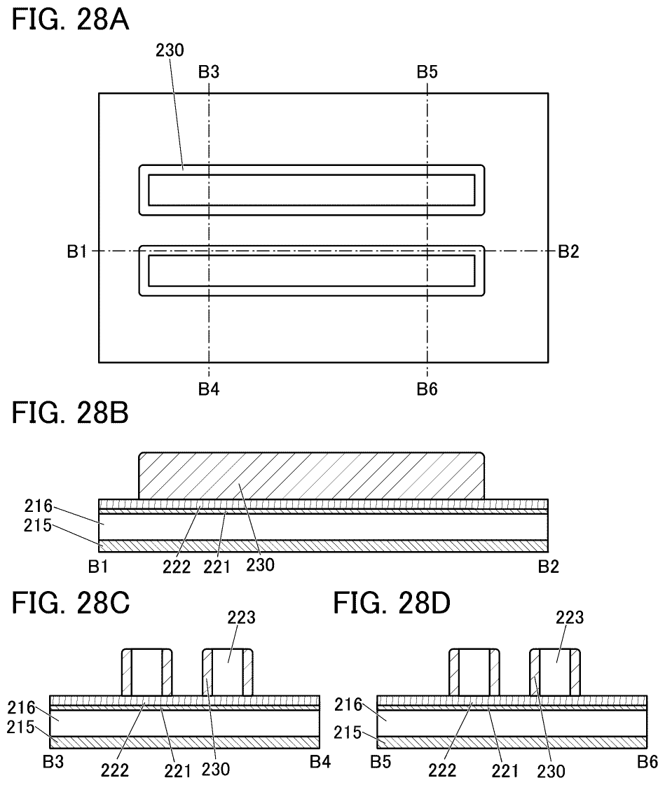

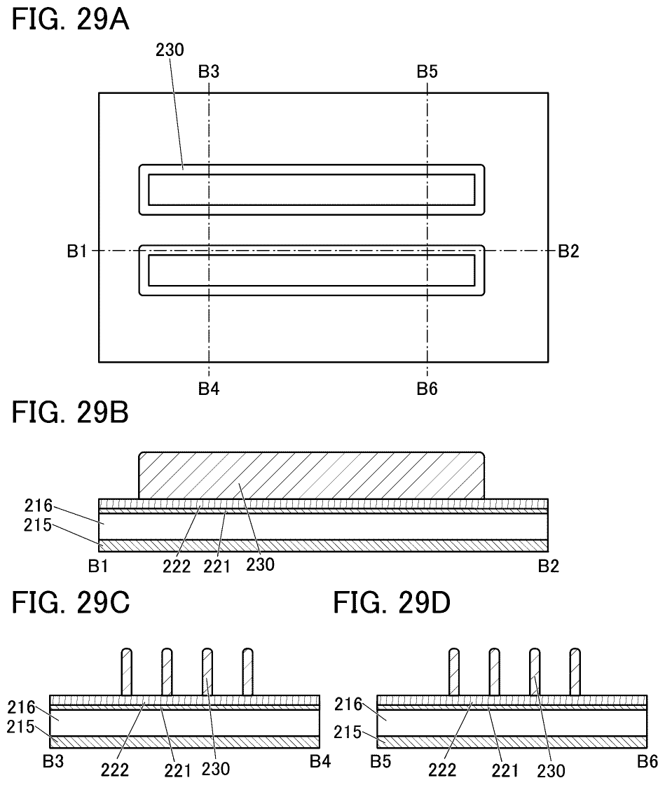

Next, part of the oxide semiconductor film 230f is removed by anisotropic etching (see FIGS. 28A to 28D). A portion of the oxide semiconductor film 230f that is parallel to the substrate surface is mainly etched, so that the oxide semiconductor 230 having a sidewall shape is formed in contact with the side surface of the insulator 223. Next, the insulator 223 is removed (see FIGS. 29A to 29D).

Although FIG. 29B illustrates a structure in which both the B1 side and the B2 side of the upper portion of the oxide semiconductor 230 have a curved shape, the present invention is not limited thereto, and only the side of the oxide semiconductor 230 that is not in contact with the insulator 223 may have a curved shape. Although FIGS. 29C and 29D illustrate a structure in which both the B3 side and the B4 side of the upper portion of the oxide semiconductor 230 have a curved shape, the present invention is not limited thereto, and only the side of the oxide semiconductor 230 that is not in contact with the insulator 223 may have a curved shape.

The oxide semiconductor 230 having a high aspect ratio can be formed by anisotropic etching. The use of the oxide semiconductor 230 enables the transistor 200 to have a larger channel width without an increase in the area occupied by the transistor 200, so that the on-state current and frequency characteristics of the transistor 200 can be improved. In addition, the contact area between the oxide semiconductor 230 and each of the conductors 242a and 242b can be increased without an increase in the area occupied by the transistor 200, so that the on-state current and frequency characteristics of the transistor 200 can be improved.

As illustrated in FIG. 29A, the top surface shape of the oxide semiconductor 230 is an enclosing shape with no endpoints. The oxide semiconductor 230 can be regarded as having an opening in the center portion. In the case where the enclosing-shaped oxide semiconductor 230 has a three-layer structure of the oxide semiconductors 230a to 230c as described above, the oxide semiconductor 230a is the closest to a region where the insulator 223 has been formed, followed in order by the oxide semiconductor 230b and the oxide semiconductor 230c. Thus, as illustrated in FIG. 4A, the oxide semiconductor 230c, the oxide semiconductor 230b, the oxide semiconductor 230a, the oxide semiconductor 230a, the oxide semiconductor 230b, and the oxide semiconductor 230c are symmetrically arranged in this order in a cross-sectional view in the channel width direction.

Although the structure in which the two enclosing-shaped oxide semiconductors 230 are provided is described above, the present invention is not limited thereto. For example, one or three or more enclosing-shaped oxide semiconductors 230 may be provided. Alternatively, the enclosing-shaped oxide semiconductors 230 may be bonded to each other to form the oxide semiconductor 230 having a plurality of openings. For example, as illustrated in FIG. 5A, the oxide semiconductor 230 can have a shape in which three openings are arranged in the A1-A2 direction in a top view. In that case, three insulators 223 are formed to be adjacent to each other at a short distance in the step illustrated in FIGS. 27A to 27D. As another example, as illustrated in FIG. 5B, the oxide semiconductor 230 can have a lattice shape in a top view. In that case, a lattice-shaped trench is formed in the insulator 223 in the step illustrated in FIGS. 27A to 27D.

Although the oxide semiconductor 230 has an enclosing shape in the top view of FIG. 29A, part of the oxide semiconductor 230 may be further removed by etching treatment. For example, in the top view of FIG. 29A, the oxide semiconductor 230 can be partly removed to have a rectangular shape extending in the B1-B2 direction.

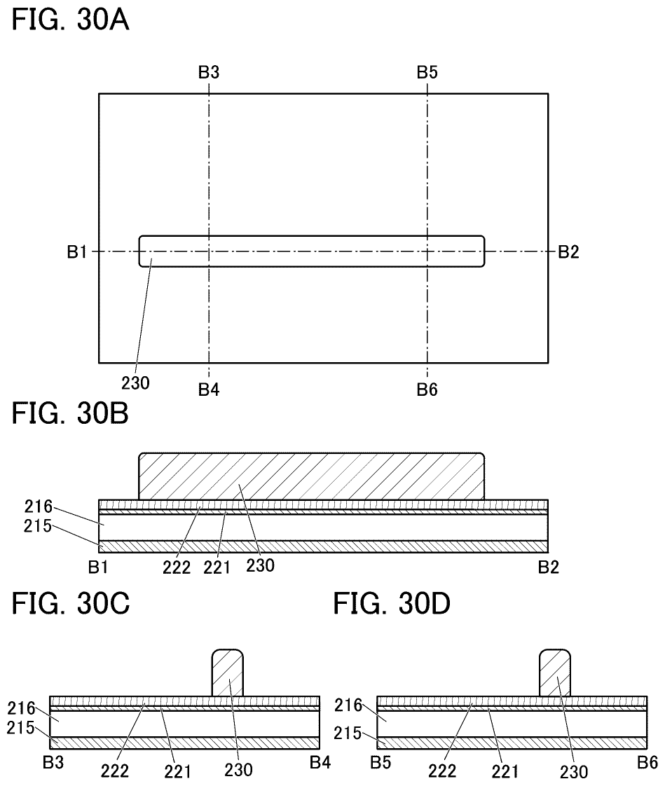

Note that the oxide semiconductor 230 may be formed without using the pillar (the insulator 223). For example, the oxide semiconductor film 230f may be formed in a flat shape over the insulator 222, and the oxide semiconductor 230 having a fin shape may be formed using a mask. When the pillar is not used, the oxide semiconductor 230 can be easily formed in some cases without using a film with high coverage of the side surface of the pillar. For example, the semiconductor device illustrated in FIG. 21A can be manufactured by forming the oxide semiconductor 230 having the shape of one fin using a mask as illustrated in FIGS. 30A to 30D.

Note that in the case where the pillar is not used, the oxide semiconductor film 230f is formed to have a thickness equal or substantially equal to the height of the oxide semiconductor 230. As the thickness of a film increases, the cost for film formation increases. The increase in thickness may cause a problem such as increase of etching time or attachment of a reaction product during etching of the oxide semiconductor film 230f. In the case where the increase in thickness causes an increase in film stress, adhesion of the film to the insulator 222 might be reduced.

In the case where the pillar is not used, the width of the oxide semiconductor 230 having a fin shape is limited by the minimum size of the mask. In the case of using a lithography method, the width of the oxide semiconductor 230 having a fin shape is limited by the minimum exposure size of a light exposure apparatus, for example. In the case where the oxide semiconductor 230 is formed using the pillar, the thickness of the oxide semiconductor film 230f formed on the sidewall of the pillar corresponds to the width of the oxide semiconductor 230; thus, the oxide semiconductor 230 can be formed to have a smaller width.

A dry etching method is preferably used for anisotropic etching of the oxide semiconductor film 230f.

In the case where the oxide semiconductor film 230f is etched by dry etching, hydrofluorocarbon, CH₄, BBr₃, HBr, SiCl₄, BCl₃, Cl₂, or the like can be used as an etching gas. In addition to these gases, Ar, O₂, H₂, N₂, or the like can be used. Specifically, a mixed gas of CH₄ and Ar can be used, for example.

Note that the insulator 223 can be removed by a dry etching method or a wet etching method. For example, the insulator 223 is removed by a wet etching method.

The insulator 222 formed using a hard-to-etch material such as hafnium oxide can function as an etching stopper in the etching treatment of the oxide semiconductor film 230f and the insulator 223.

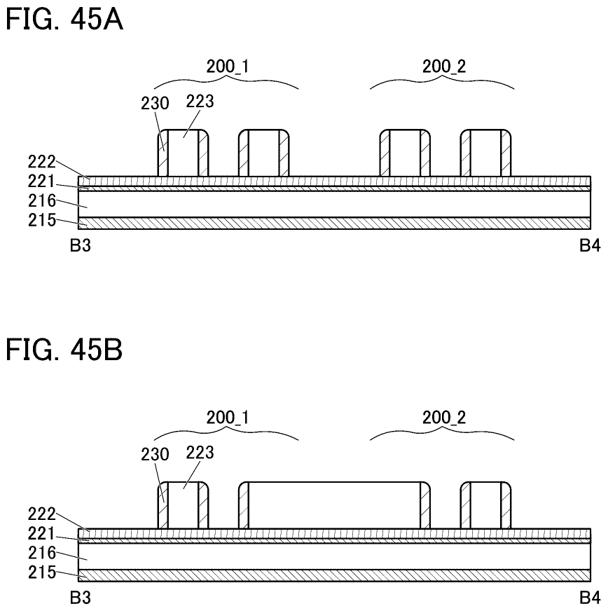

Although FIGS. 29A to 29D illustrate the structure in which the two insulators 223 and the two oxide semiconductors 230 are provided for the transistor 200, the present invention is not limited thereto. As illustrated in FIG. 45A, the two insulators 223 and the two oxide semiconductors 230 may be provided for each of two transistors (a transistor 200_1 and a transistor 200_2). Alternatively, as illustrated in FIG. 45B, a structure may be employed in which insulators 223 having different widths are provided and three fin-shaped oxide semiconductors 230 are provided for each of the transistor 200_1 and the transistor 200_2 in a cross-sectional view in the B3-B4 direction. In that case, the oxide semiconductor 230 is partly removed to have a linear top surface shape extending in the B1-B2 direction, so that the oxide semiconductor 230 of the transistor 200_1 and the oxide semiconductor 230 of the transistor 200_2 are separated from each other.

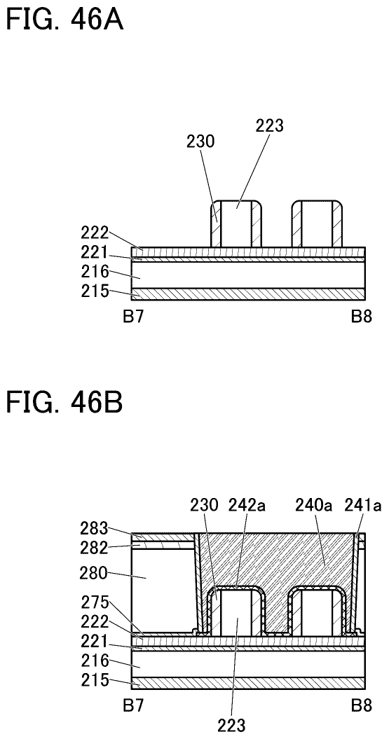

Although FIGS. 29A to 29D illustrate a structure in which the insulator 223 is removed, the present invention is not limited thereto. For example, part of the insulator 223 can be left as illustrated in FIG. 46A. Here, the insulator 223 is left in a region where the conductor 240 is to be provided in a later step. For example, a mask is provided by a lithography method in the region where the conductor 240 is to be provided, so that the insulator 223 is left in that region in the above-described step of removing the insulator 223. The insulator 223 is formed to fill the inside of the enclosing-shaped oxide semiconductor 230 as illustrated in FIG. 46A. The conductors 242a and 240a are formed to cover the oxide semiconductor 230 and the insulator 223 in the transistor 200 as illustrated in FIG. 46B. The conductor 242a is in contact with the top and side surfaces of the oxide semiconductor 230 and the top surface of the insulator 223.

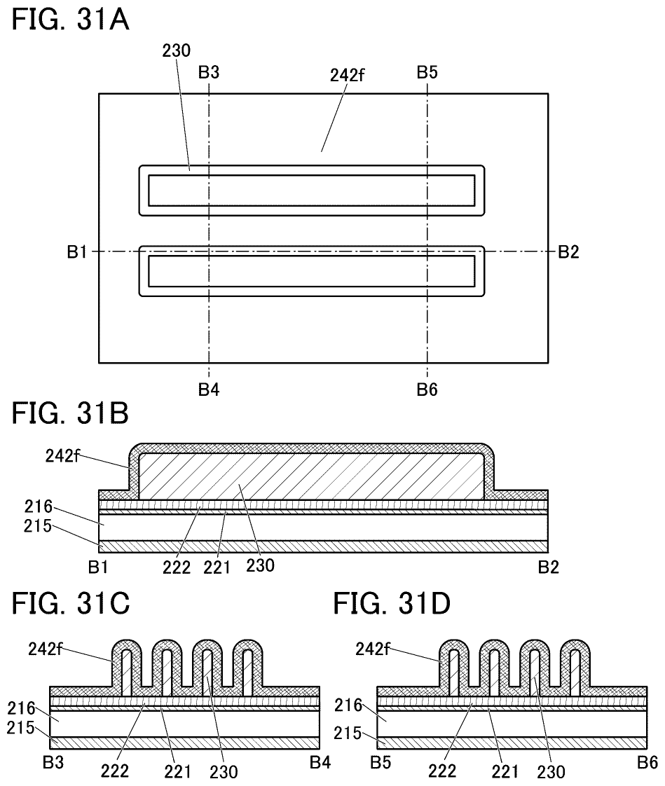

Next, a conductive film 242f is formed over the insulator 222 and the oxide semiconductor 230 (see FIGS. 31A to 31D). The conductive film 242f is a conductive film to be the conductor 242 in a later step.

The conductive film 242f can be formed by a sputtering method, a CVD method, an MBE method, a PLD method, or an ALD method, for example. A stacked-layer film of a tantalum nitride film formed by a sputtering method and a tungsten film formed by a sputtering method over the tantalum nitride film is used as the conductive film 242f. Since the conductive film 242f is formed to cover the oxide semiconductor 230, the contact area between the oxide semiconductor 230 and the conductor 242 can be increased without an increase in the area occupied by the transistor 200. This can improve the on-state current and frequency characteristics of the transistor 200.

With the use of a sputtering method, a conductive film with high conductivity can be formed with high mass productivity. Thus, the conductive film 242f is preferably formed by a sputtering method. Note that a sputtering method provides lower coverage in some cases than an ALD method or the like. For example, the conductive film 242f is sometimes thinner in its region covering the sidewall of the oxide semiconductor 230 than in its regions covering the top surface of the oxide semiconductor 230 and the top surface of the insulator 222. In such a case, when the oxide semiconductor 230 is made to have a low resistance so as to function as an electrode, a circuit including the transistor 200 and the capacitor 460 can be favorably operated. Note that the oxide semiconductor 230 is sometimes expressed as functioning as an auxiliary electrode of the conductor 242b.

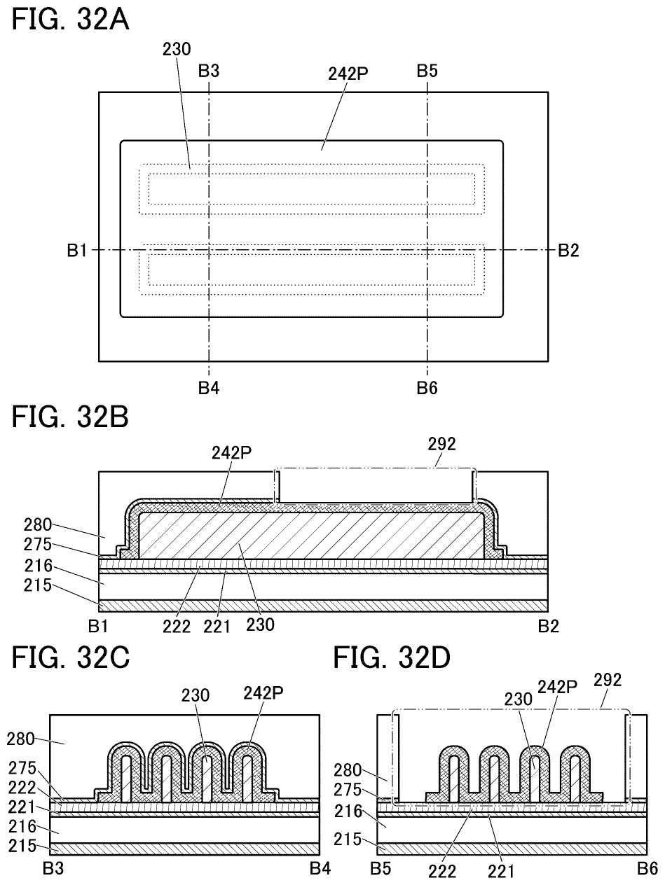

Next, the conductive film 242f is processed into an island shape by a lithography method to form a conductor 242P (see FIGS. 32A to 32D). At this time, the conductor 242P is preferably formed to cover the oxide semiconductor 230. The insulator 222 in a region not overlapping with the conductor 242P is exposed.

The processing can be performed by a dry etching method or a wet etching method. A dry etching method is suitable for microfabrication. Note that the above description can be referred to for the conditions and an apparatus for the dry etching method.

The side surface of the conductor 242P may be perpendicular or substantially perpendicular to the top surface of the insulator 222. This structure enables a plurality of transistors to be provided in a small area at high density.

Not being limited to the above, the side surfaces of the oxide semiconductor 230 and the conductor 242P may each have a tapered shape. The taper angle of the side surfaces of the oxide semiconductor 230 and the conductor 242P may be, for example, greater than or equal to 60° and less than 90°. With such tapered side surfaces, the coverage with the insulator 275 and the like can be improved in a later step, so that the number of defects such as voids can be reduced.

Next, the insulator 275 is formed to cover the conductor 242P, and the insulator 280 is formed over the insulator 275 (see FIGS. 32A to 32D).

Each of the insulators 275 and 280 can be formed by a sputtering method, a CVD method, an MBE method, a PLD method, or an ALD method, for example.

Here, the insulator 275 is preferably in contact with the top surface of the insulator 222.

The insulator 275 is preferably formed using an insulator having a function of inhibiting passage of oxygen. For example, a silicon nitride film is preferably formed as the insulator 275 by a PEALD method. Alternatively, as the insulator 275, it is preferable that an aluminum oxide film be formed by a sputtering method and a silicon nitride film be formed thereover by a PEALD method. When the insulator 275 has such a stacked-layer structure, the function of inhibiting diffusion of oxygen and impurities such as water and hydrogen can be improved.

In this manner, the oxide semiconductor 230 and the conductor 242P can be covered with the insulator 275 having a function of inhibiting diffusion of oxygen. This can inhibit direct diffusion of oxygen from the insulator 280 or the like into the oxide semiconductor 230 and the conductor 242P in a later step.

As the insulator 280, an insulator having a flat top surface is preferably formed in the following manner: an insulating film to be the insulator 280 is formed and then the insulating film is subjected to CMP treatment. Note that a silicon nitride film may be formed over the insulator 280 by a sputtering method, for example, and then subjected to CMP treatment until the insulator 280 is exposed.

A silicon oxide film is preferably formed as the insulator 280 by a sputtering method. When an insulating film to be the insulator 280 is formed by a sputtering method in an oxygen-containing atmosphere, the insulator 280 containing excess oxygen can be formed. By using a sputtering method that does not need to use a molecule containing hydrogen as a film formation gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed on the surface of the insulator 275 and the like and reduce the moisture concentration and the hydrogen concentration in the oxide semiconductor 230. The heat treatment can be performed under the above-described heat treatment conditions.

Next, the insulator 275 and the insulator 280 are processed by a lithography method to form an opening portion 292 reaching the conductor 242P and the insulator 222 (see FIGS. 32A to 32D). The top surface of a portion of the conductor 242P that overlaps with the opening portion 292 is exposed.

The opening portion 292 is formed to overlap with the oxide semiconductor 230 in a region where the capacitor 460 is formed.

In order to process the opening in the insulator 280 finely, an electron beam or short-wavelength light such as EUV light is preferably used in the lithography method.

The processing is preferably performed by a dry etching method. A dry etching method enables anisotropic etching and thus is suitable for forming an opening with a high aspect ratio.

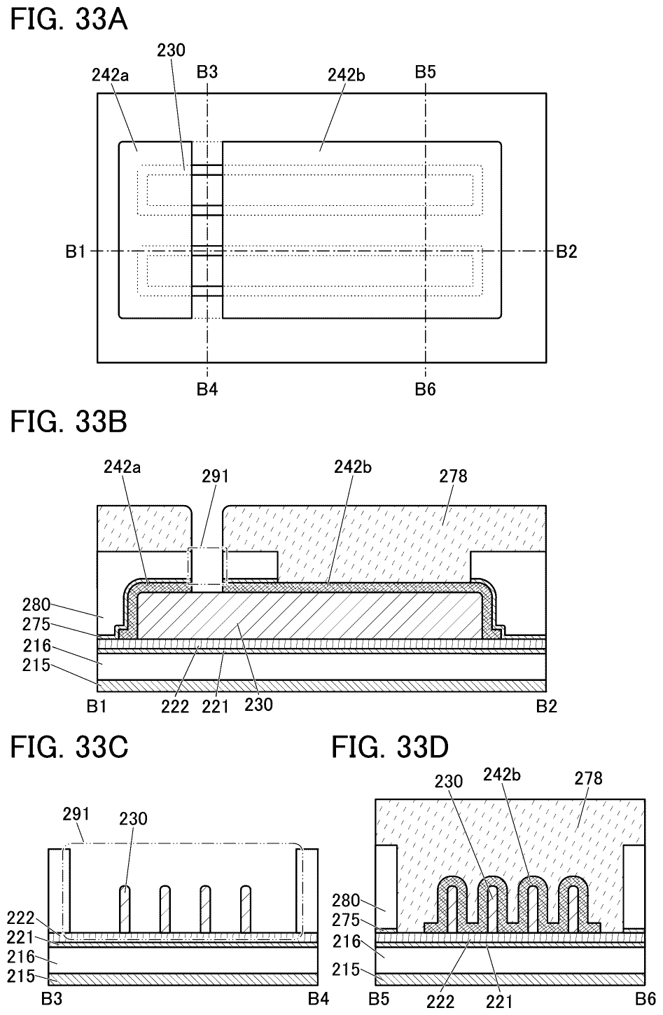

Next, a mask 278 is formed over the insulator 280 and the oxide semiconductor 230 (see FIGS. 33A to 33D).

A resist mask can be used as the mask 278. Alternatively, a stacked-layer structure of an SOC film, an SOG film, and a resist mask may be used.

The mask 278 preferably has an opening in a position overlapping with a region to be the channel formation region of the transistor 200.

Next, regions of the insulator 280, the insulator 275, and the conductor 242P that are not covered with the mask 278 are removed (see FIGS. 33A to 33D). Here, an opening portion 291 is provided in the insulators 280 and 275. In addition, the conductor 242P is divided into the conductor 242a and the conductor 242b. In the region where the conductor 242P is removed, the top surface of the oxide semiconductor 230 that has been covered with the conductor 242P is exposed.

Note that ashing treatment using oxygen plasma may be performed after the processing of the conductor 242P. Such oxygen plasma treatment can remove impurities generated by the above etching and diffused into the oxide semiconductor 230 or the like. The impurities are generated from a component of the object processed by the above etching treatment and a component contained in a gas or the like used for the etching. Examples of the impurities include chlorine, fluorine, tantalum, silicon, and hafnium. In particular, when a chlorine gas is used in the processing of the conductor 242P as in the above-described etching treatment, the oxide semiconductor 230 is exposed to the atmosphere containing the chlorine gas; thus, chlorine attached to the oxide semiconductor 230 is preferably removed. Removal of impurities attached to the oxide semiconductor 230 in this manner can improve the electrical characteristics and reliability of the transistor.

In order to remove the impurities or the like attached to the surface of the oxide semiconductor 230 in the etching step, cleaning treatment may be performed. Examples of cleaning methods include wet cleaning using a cleaning solution or the like (which can also be referred to as wet etching treatment), plasma treatment using plasma, and cleaning by heat treatment, and any of these cleaning methods may be combined as appropriate. The cleaning treatment sometimes makes the groove deeper.

The wet cleaning may be performed using an aqueous solution in which one or more of ammonia water, oxalic acid, phosphoric acid, and hydrofluoric acid are diluted with carbonated water or pure water; pure water; or carbonated water, for example. Alternatively, ultrasonic cleaning using such an aqueous solution, pure water, or carbonated water may be performed. Further alternatively, any of these cleaning methods may be combined as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Damage to the oxide semiconductor 230 and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water and second cleaning treatment may use pure water or carbonated water.

In this embodiment, as the cleaning treatment, wet cleaning is performed with use of diluted ammonia water. The cleaning treatment allows removal of impurities that are attached onto the surface of the oxide semiconductor 230 or the like or diffused into the oxide semiconductor 230 or the like. Furthermore, the crystallinity of the oxide semiconductor 230 can be improved.

After the etching or the cleaning, heat treatment is preferably performed. The heat treatment temperature is higher than or equal to 100° C. and lower than or equal to 650° C., preferably higher than or equal to 250° C. and lower than or equal to 600° C., further preferably higher than or equal to 300° C. and lower than or equal to 550° C., still further preferably higher than or equal to 350° C. and lower than or equal to 400° C. Note that the heat treatment is performed in a nitrogen gas atmosphere, an inert gas atmosphere, or an atmosphere containing an oxidizing gas at 10 ppm or more, 1% or more, or 10% or more. The heat treatment is preferably performed in an oxygen-containing atmosphere. For example, it is preferable that the flow rate ratio of a nitrogen gas to an oxygen gas be 4:1 and the heat treatment be performed at a temperature of 350° C. for one hour. Accordingly, oxygen can be supplied to the oxide semiconductor 230 to reduce oxygen vacancies. In addition, the crystallinity of the oxide semiconductor 230 can be improved by the heat treatment. Furthermore, hydrogen remaining in the oxide semiconductor 230 reacts with supplied oxygen, so that the hydrogen can be removed as H₂O (dehydration). This can inhibit recombination of hydrogen remaining in the oxide semiconductor 230 with oxygen vacancies and formation of VoH. Accordingly, a transistor including the oxide semiconductor 230 can have favorable electrical characteristics and high reliability. In addition, variations in electrical characteristics of transistors formed over the same substrate can be reduced. The heat treatment may be performed under reduced pressure. Alternatively, the heat treatment may be performed as follows: heat treatment is performed in an oxygen atmosphere, and then another heat treatment is successively performed in a nitrogen atmosphere without exposure to the air. The heat treatment can also serve as the heat treatment performed after the formation of the oxide semiconductor 30c during the formation of the oxide semiconductor 30. Thus, the crystal region of the oxide semiconductor 230 grows through the heat treatment in some cases.

In the case where heat treatment is performed in a state where the oxide semiconductor 230 is in contact with the conductors 242a and 242b, the sheet resistance is sometimes reduced in each of a region of the oxide semiconductor 230 which overlaps with the conductor 242a and a region of the oxide semiconductor 230 which overlaps with the conductor 242b. In addition, the carrier concentration may be increased. Thus, the resistance of each of the region of the oxide semiconductor 230 which overlaps with the conductor 242a and the region of the oxide semiconductor 230 which overlaps with the conductor 242b can be lowered in a self-aligned manner.

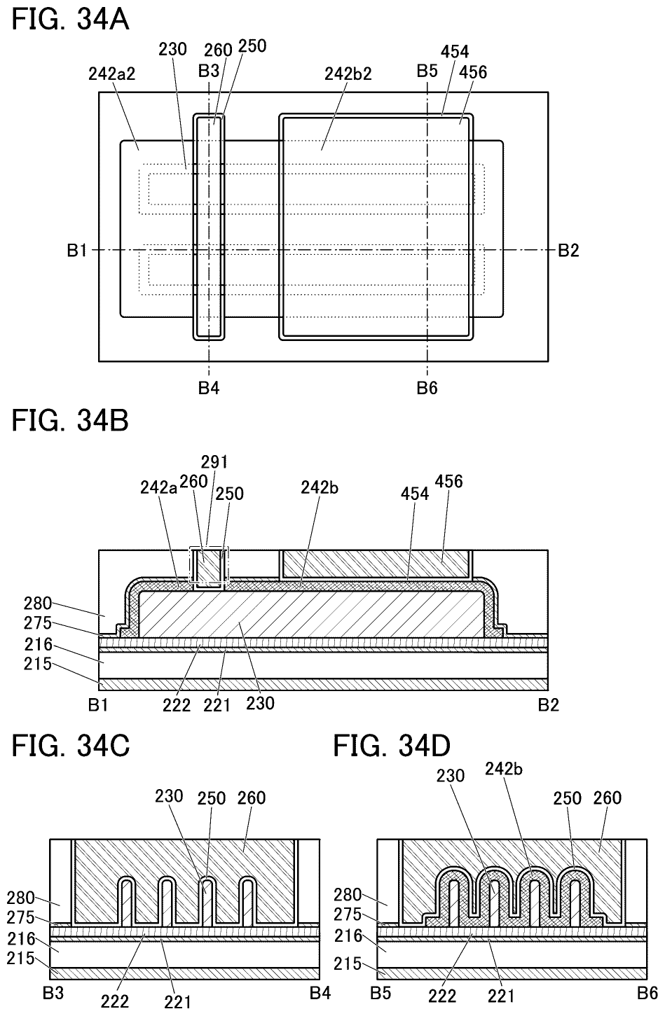

Next, an insulating film 250A (not illustrated) is formed to fill the opening portion 291 formed in the insulators 280 and 275 (see FIGS. 34A to 34D). The insulating film 250A is provided to cover the top surface of the oxide semiconductor 230 which overlaps with the opening portion 291. The insulator 250 and the insulator 454 can be formed by processing the insulating film 250A in a later step. Here, the insulating film 250A is in contact with the insulator 280, the insulator 275, the conductors 242a and 242b, the insulator 222, and the oxide semiconductor 230.

The insulating film 250A can be formed by a sputtering method, a CVD method, an MBE method, a PLD method, or an ALD method. For example, the insulating film 250A is preferably formed by an ALD method. Like the above-described insulator 250, the insulating film 250A is preferably formed to have a small thickness, and an unevenness of the thickness needs to be reduced. In the ALD method, a precursor and a reactant (such as an oxidizer) are alternately introduced to form a film, and the film thickness can be adjusted depending on the number of repetition times of the sequence of the introduction; thus, accurate control of the film thickness is possible. In addition, the insulating film 250A needs to be formed on the bottom surface and the side surface of the opening portion so as to have good coverage. Atomic layers can be deposited one by one on the bottom and side surfaces of the opening portion by the ALD method, whereby the insulating film 250A can be formed in the opening portion with good coverage.

When the insulating film 250A is formed by an ALD method, ozone (O₃), oxygen (O₂), water (H₂O), or the like is used as the oxidizer. When an oxidizer without hydrogen, such as ozone (O₃) or oxygen (O₂), is used, the amount of hydrogen diffusing into the oxide semiconductor 230 can be reduced.

The insulator 250 can have a stacked-layer structure as illustrated in FIGS. 3A and 3B and the like. For example, as illustrated in FIG. 3A, the insulator 250 can have a stacked-layer structure of the insulators 250a to 250d. In that case, an aluminum oxide film can be formed as the insulator 250a by a thermal ALD method, a silicon oxide film can be formed as the insulator 250b by a PEALD method, a hafnium oxide film can be formed as the insulator 250c by a thermal ALD method, and a silicon nitride film can be formed as the insulator 250d by a PEALD method.

Microwave treatment is preferably performed in an oxygen-containing atmosphere after the formation of the insulating film 250A or after the formation of any of the insulators included in the insulating film 250A. Here, the microwave treatment refers to, for example, treatment using an apparatus including a power source for generating high-density plasma using microwaves. In this specification and the like, a microwave refers to an electromagnetic wave having a frequency higher than or equal to 300 MHz and lower than or equal to 300 GHz.

The microwave treatment is preferably performed with a microwave treatment apparatus including a power source for generating high-density plasma using microwaves, for example. Here, the frequency of the microwave treatment apparatus is preferably set higher than or equal to 300 MHz and lower than or equal to 300 GHz, further preferably higher than or equal to 2.4 GHz and lower than or equal to 2.5 GHz, and can be 2.45 GHz, for example. Oxygen radicals at a high density can be generated with high-density plasma. The electric power of the power source that applies microwaves of the microwave treatment apparatus is preferably set higher than or equal to 1000 W and lower than or equal to 10000 W, further preferably higher than or equal to 2000 W and lower than or equal to 5000 W. The microwave treatment apparatus may be provided with a power source that applies RF to the substrate side. Application of RF to the substrate side allows oxygen ions generated by the high-density plasma to be introduced into the oxide semiconductor 230 efficiently.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. The treatment temperature can be set higher than or equal to room temperature (e.g., 25° C.), preferably higher than or equal to 100° C. and lower than or equal to 750° C., further preferably higher than or equal to 200° C. and lower than or equal to 500° C. For example, the microwave treatment is preferably performed at a treatment temperature of approximately 250° C. Alternatively, for example, the microwave treatment is preferably performed at a treatment temperature of approximately 400° C. The oxygen plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide semiconductor 230 can be reduced by thus performing the microwave treatment in an oxygen-containing atmosphere. In addition, preventing introduction of an excess amount of oxygen into the chamber in the microwave treatment can prevent an excessive reduction in the carrier concentration in the oxide semiconductor 230.

The microwave treatment in an oxygen-containing atmosphere converts an oxygen gas into plasma using a high-frequency wave such as microwave or RF and applies the oxygen plasma to a region of the oxide semiconductor 230 that is between the conductor 242a and the conductor 242b. By the effects of plasma, a microwave, and the like, VoH in the region can be divided into oxygen vacancies and hydrogen, and hydrogen can be removed from the region. Here, in the case of the structure illustrated in FIG. 3A and the like, an insulating film (e.g., aluminum oxide) having a function of capturing or fixing hydrogen is preferably used as the insulator 250a. With such a structure, hydrogen generated by the microwave treatment can be captured or fixed in the insulating film 250A. In this manner, the amount of VoH contained in the channel formation region can be reduced. As a result, oxygen vacancies and VoH in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

Oxygen implanted into the channel formation region has a variety of forms such as an oxygen atom, an oxygen molecule, an oxygen ion, and an oxygen radical (also referred to as an O radical, which is an atom, a molecule, or an ion having an unpaired electron). The oxygen implanted into the channel formation region preferably has one or more of the above forms. An oxygen radical is particularly preferable. In addition, the insulator 250 can have a higher film quality, which increases the reliability of the transistor.

Furthermore, the microwave treatment can remove impurities such as carbon in the oxide semiconductor 230. By removing carbon, which is an impurity in the oxide semiconductor 230, the crystallinity of the oxide semiconductor 230 can be increased. Accordingly, the oxide semiconductor 230 can be a CAAC-OS. Particularly in the case where the oxide semiconductor 230 is formed by an ALD method, carbon contained in a precursor is sometimes taken into the oxide semiconductor 230; thus, carbon is preferably removed by the microwave treatment.

Meanwhile, the oxide semiconductor 230 includes a region overlapping with the conductor 242a or 242b. The region can function as a source region or a drain region. Here, the conductors 242a and 242b preferably function as a blocking film preventing the effect of the high-frequency wave such as the microwave or the RF, the oxygen plasma, or the like in the microwave treatment in an oxygen-containing atmosphere. Thus, the conductors 242a and 242b preferably have a function of blocking an electromagnetic wave greater than or equal to 300 MHz and less than or equal to 300 GHz, for example, greater than or equal to 2.4 GHz and less than or equal to 2.5 GHz.

Since the conductors 242a and 242b prevent the effect of the high-frequency wave such as the microwave or the RF, the oxygen plasma, or the like, the effect does not reach the region of the oxide semiconductor 230 which overlaps with the conductor 242a or 242b. Hence, a reduction in VoH and supply of an excess amount of oxygen due to the microwave treatment do not occur in the source and drain regions, preventing a decrease in carrier concentration.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited and the conductivity (the state of the low-resistance regions) before the microwave treatment can be maintained. As a result, a change in the electrical characteristics of the transistor can be inhibited; thus, variation in the electrical characteristics of the transistors in the substrate plane can be inhibited.

The microwave treatment improves the film quality of the insulator 250, thereby inhibiting diffusion of hydrogen, water, impurities, and the like. Accordingly, hydrogen, water, impurities, and the like can be inhibited from diffusing into the oxide semiconductor 230 and the like through the insulator 250 in the following step such as formation of a conductive film to be the conductor 260 or the following treatment such as heat treatment. By thus improving the film quality of the insulator 250, the reliability of the transistor can be improved.

In the case where the insulator 250 has a stacked-layer structure of the insulators 250a to 250d, microwave treatment is preferably performed after the formation of the insulator 250b. Furthermore, microwave treatment may be performed again after the formation of the insulator 250c. As described above, the microwave treatment in an oxygen-containing atmosphere may be performed a plurality of times (at least two or more times). In some cases, the microwave treatment can also serve as the heat treatment performed after the formation of the oxide semiconductor 230. Thus, the crystal region of the oxide semiconductor 230 grows through the microwave treatment in some cases.

After the microwave treatment, heat treatment may be performed with the reduced pressure being maintained. Such treatment enables hydrogen in the insulating film and the oxide semiconductor 230 to be removed efficiently. Alternatively, the step of performing microwave treatment and then performing heat treatment with the reduced pressure being maintained may be repeated a plurality of cycles. The repetition of the heat treatment enables hydrogen in the insulating film and the oxide semiconductor 230 to be removed more efficiently. Note that the heat treatment temperature is preferably higher than or equal to 300° C. and lower than or equal to 500° C. The heat treatment can also serve as the heat treatment performed after the formation of the oxide semiconductor 230. Thus, the crystal region of the oxide semiconductor 230 grows through the heat treatment in some cases.

Next, a conductive film 260A (not illustrated) is formed over the insulating film 250A (see FIGS. 34A to 34D). The conductor 260 and the conductor 456 can be formed by processing the conductive film 260A in a later step.

The conductive film 260A can be formed by a sputtering method, a CVD method, an MBE method, a PLD method, a plating method, or an ALD method, for example. In this embodiment, a stacked film of a titanium nitride film formed by a CVD method and a tungsten film sequentially formed by a CVD method over the titanium nitride film is used as the conductive film 260A. Note that the conductive film 260A may be formed while the substrate is being heated. The substrate heating can also serve as the heat treatment performed after the formation of the oxide semiconductor 230. Thus, the crystal region of the oxide semiconductor 230 grows through the substrate heating in some cases.

Then, the insulating film 250A and the conductive film 260A are polished by CMP treatment until the insulator 280 is exposed. Thus, the insulator 250, the insulator 454, the conductor 260, and the conductor 456 are formed (see FIGS. 34A to 34D).

The insulator 250 is provided in contact with the insulator 280, the insulator 275, the conductor 242a, the conductor 242b, the oxide semiconductor 230, and the insulator 222 in the opening portion 291. The conductor 260 is provided to fill the opening portion 291 with the insulator 250 therebetween. In this manner, the transistor 200 is formed.

The insulator 454 is provided in contact with the insulator 280, the insulator 275, the conductor 242b, and the insulator 222 in the opening portion 292. The conductor 456 is provided to fill the opening portion 292 with the insulator 454 therebetween. In this manner, the capacitor 460 is formed.

Next, the insulator 282 is formed over the insulator 250, the conductor 260, and the insulator 280 (see FIGS. 14A to 15B). The insulator 282 can be formed by a sputtering method, a CVD method, an MBE method, a PLD method, or an ALD method, for example. The insulator 282 is preferably formed by a sputtering method. The insulator 282 may be formed in the following manner: a first layer is formed by an ALD method and a second layer is formed over the first layer by a sputtering method.

Forming the insulator 282 in an oxygen-containing atmosphere by a sputtering method can supply oxygen to the insulator 280 during the formation. Thus, excess oxygen can be contained in the insulator 280. The insulator 282 is preferably formed while the substrate is being heated. By forming the insulator 282 in such a manner, a suitable amount of oxygen can be supplied from the insulator 280 to the oxide semiconductor 230 through the insulator 250. Providing the insulator 250a in the insulator 250 can prevent an excess amount of oxygen from being supplied to the insulator 250, thereby preventing the conductor 242a and the conductor 242b in the vicinity of the insulator 250 from being excessively oxidized.

An aluminum oxide film is formed using an aluminum target in an atmosphere containing an oxygen gas. The amount of oxygen implanted into the insulator 280 can be controlled depending on the amount of a bias power applied to the substrate in a sputtering method. For example, the amount of oxygen implanted into the insulator 280 becomes smaller as the bias power becomes lower, and the amount of oxygen easily becomes saturated even when the insulator 282 has a small thickness. Furthermore, as the bias power becomes higher, the amount of oxygen implanted into the insulator 280 increases. With low RF bias power, the amount of oxygen implanted into the insulator 280 can be reduced. Note that in the case where the substrate bias is applied by an RF power source, the RF frequency is preferably higher than or equal to 10 MHz. The typical frequency is 13.56 MHz. The higher the RF frequency is, the less damage to the substrate can be.

Forming the second layer by a sputtering method over the first layer formed by an ALD method can protect the upper end portion of the insulator 250 and the top surface of the conductor 260 from an impact of ion collision due to formation of the second layer by sputtering.

Heat treatment may be performed before the formation of the insulator 282. The heat treatment may be performed under reduced pressure, and the insulator 282 may be successively formed without exposure to the air. Such treatment can remove moisture and hydrogen adsorbed on the surface of the insulator 280 and can reduce the moisture concentration and the hydrogen concentration in the insulator 280. The heat treatment temperature is preferably higher than or equal to 100° C. and lower than or equal to 400° C. In this embodiment, the heat treatment temperature is 250° C.

Next, the insulator 283 is formed over the insulator 282 (see FIGS. 14A to 15B). The insulator 283 can be formed by a sputtering method, a CVD method, an MBE method, a PLD method, or an ALD method, for example. The insulator 283 is preferably formed by a sputtering method. By using a sputtering method that does not need to use a molecule containing hydrogen as a film formation gas, the hydrogen concentration in the insulator 283 can be reduced. In this embodiment, a silicon nitride film is formed as the insulator 283 by a sputtering method.

Here, it is preferable to form the insulators 282 and 283 successively without exposure to the air. Film formation without exposure to the air can prevent attachment of impurities or moisture from the air onto the insulators 282 and 283, so that an interface between the insulators 282 and 283 and the vicinity thereof can be kept clean.

In this embodiment, a silicon nitride film is formed as the insulator 283, and an aluminum oxide film is formed as the insulator 282. The use of silicon nitride having a function of inhibiting diffusion of hydrogen for the insulator 283 can inhibit diffusion of hydrogen from a layer above the transistor 200. Furthermore, the use of aluminum oxide having a function of capturing or fixing hydrogen for the insulator 282 enables hydrogen contained in the insulator 280 or the like to be captured or fixed by the insulator 282. This can reduce the hydrogen concentration in the oxide semiconductor 230 and in the vicinity thereof.

Next, the insulator 285 is formed over the insulator 283 (see FIGS. 14A to 15B). As the insulator 285, any of the above-described insulators can be used as appropriate. The insulator 285 can be formed using an insulator that can be used as the insulator 280, for example.

Then, an opening reaching the conductor 242a is formed in the insulators 275, 280, 282, 283, and 285 (see FIGS. 14A to 15B). The opening may be formed by a lithography method. In the formation of the opening, an object to be processed is preferably processed by a dry etching method. A dry etching method enables anisotropic etching and thus is suitable for forming an opening with a high aspect ratio. In the case of performing anisotropic etching, reactive ion etching is preferably performed, for example. Note that the above description can be referred to for the conditions and an apparatus for the dry etching method. Although the opening in the top view in FIG. 14A has a quadrangular shape, the shape of the opening is not limited thereto. For example, the opening in the top view may have a circular shape, an almost circular shape such as an elliptical shape, a polygonal shape such as a quadrangular shape, or a polygonal shape such as a quadrangular shape with rounded corners.

Next, heat treatment may be performed after the formation of the opening. The heat treatment temperature is higher than or equal to 100° C. and lower than or equal to 600° C., preferably higher than or equal to 250° C. and lower than or equal to 550° C., further preferably higher than or equal to 350° C. and lower than or equal to 450° C. Note that the heat treatment is preferably performed in a nitrogen gas or inert gas atmosphere. The heat treatment is performed in a state where the conductors 242a and 242b are exposed; thus, the heat treatment is preferably performed in an atmosphere not containing an oxidizing gas or an oxygen gas. For example, heat treatment is preferably performed at 400° C. in a nitrogen gas atmosphere for one hour. The heat treatment may be performed under reduced pressure. By the heat treatment, oxygen contained in the insulator 280 can be supplied to the oxide semiconductor 230 through the insulator 250. Thus, oxygen vacancies in the channel formation region of the oxide semiconductor 230 can be reduced. The heat treatment can also serve as the heat treatment performed after the formation of the oxide semiconductor 230. Thus, the crystal region of the oxide semiconductor 230 grows through the heat treatment in some cases.

Here, the side surface of the insulator 280 is exposed in the opening; thus, oxygen contained in the insulator 280 is diffused outwardly by the heat treatment, so that the amount of oxygen contained in the insulator 280 can be controlled. Meanwhile, since the insulators 282 and 283 each having a barrier property against oxygen are provided over the insulator 280, oxygen is not diffused outwardly from the top surface of the insulator 280. Accordingly, oxygen can be prevented from being excessively diffused from the insulator 280 outwardly and thus, oxygen vacancies can be prevented from being formed in the insulator 280. The oxide semiconductor 230 and the conductors 242a and 242b are covered with the insulator 275. This can prevent direct diffusion of an excess amount of oxygen from the insulator 280 to the oxide semiconductor 230 and the conductors 242a and 242b in the above heat treatment.

In this manner, the amount of oxygen in the insulator 280 can be adjusted more suitably, and a suitable amount of oxygen can be supplied to the oxide semiconductor 230. Accordingly, oxygen vacancies in the oxide semiconductor 230 can be reduced, and an excess amount of oxygen can be prevented from being supplied to the oxide semiconductor 230. Thus, the electrical characteristics and reliability of the transistor 200 can be improved. Furthermore, a step of exposing the side surface of the insulator 280 can also serve as a step of forming an opening to be filled with the conductor 240a; thus, the manufacturing process of the semiconductor device can be simplified.

Next, an insulating film to be the insulator 241a is formed and then subjected to anisotropic etching, so that the insulator 241a is formed in the opening reaching the conductor 242a (see FIGS. 14A to 15B). The insulating film to be the insulator 241a can be formed by a sputtering method, a CVD method, an MBE method, a PLD method, an ALD method, or the like. The insulating film to be the insulator 241a preferably has a function of inhibiting passage of oxygen. For example, a silicon nitride film is preferably formed by a PEALD method. Silicon nitride is preferable because of its high blocking property against hydrogen.

For anisotropic etching of the insulating film to be the insulator 241a, a dry etching method is used, for example. Providing the insulator 241a on the sidewall portion of the opening can inhibit passage of oxygen from the outside and oxidation of the conductor 240a formed in the next step. In addition, diffusion of impurities such as water and hydrogen contained in the insulator 280 or the like into the conductor 240a can be prevented. Note that part of each of the top surfaces of the conductors 242a and 242b may have a depression because of the anisotropic etching.

Next, a conductive film to be the conductor 240a is formed. The conductive film to be the conductor 240a preferably has a stacked-layer structure including a conductor having a function of inhibiting passage of impurities such as water and hydrogen. For example, a stacked-layer structure of tantalum nitride, titanium nitride, or the like and tungsten, molybdenum, copper, or the like can be employed. The conductive film to be the conductor 240a can be formed by a sputtering method, a CVD method, an MBE method, a PLD method, or an ALD method, for example.

Next, the conductive film to be the conductor 240a is partly removed by planarization treatment to expose the top surface of the insulator 285. As a result, the conductive film remains only in the opening, whereby the conductor 240a having a flat top surface can be formed (see FIGS. 14A to 15B). The planarization treatment may remove part of the top surface of the insulator 285. The planarization treatment is preferably performed by a CMP method.

When the conductor 240a is provided in contact with the conductor 242a in this manner, the conductor 240a functioning as one of the source and the drain of the transistor 200 can be electrically connected to a wiring.

Next, the conductor 413 is formed over the conductor 240a.

Through the above steps, the semiconductor device illustrated in FIGS. 14A to 15B can be manufactured.

### Example 2 of Method for Manufacturing Semiconductor Device

An example in which the shapes and manufacturing methods of the insulator 454 and the conductor 456 of the capacitor 460 are different from those in FIGS. 27A to 34D will be described below. Note that the description of the conditions of the same manufacturing steps and the same treatments between steps (such as heat treatment, plasma treatment, and microwave treatment) as those in FIGS. 27A to 34D can be referred to as appropriate.

First, the insulators 215, 216, 221, and 222, the oxide semiconductor 230, and the conductive film 242f are formed in this order by the manufacturing method illustrated in FIGS. 27A to 31D.

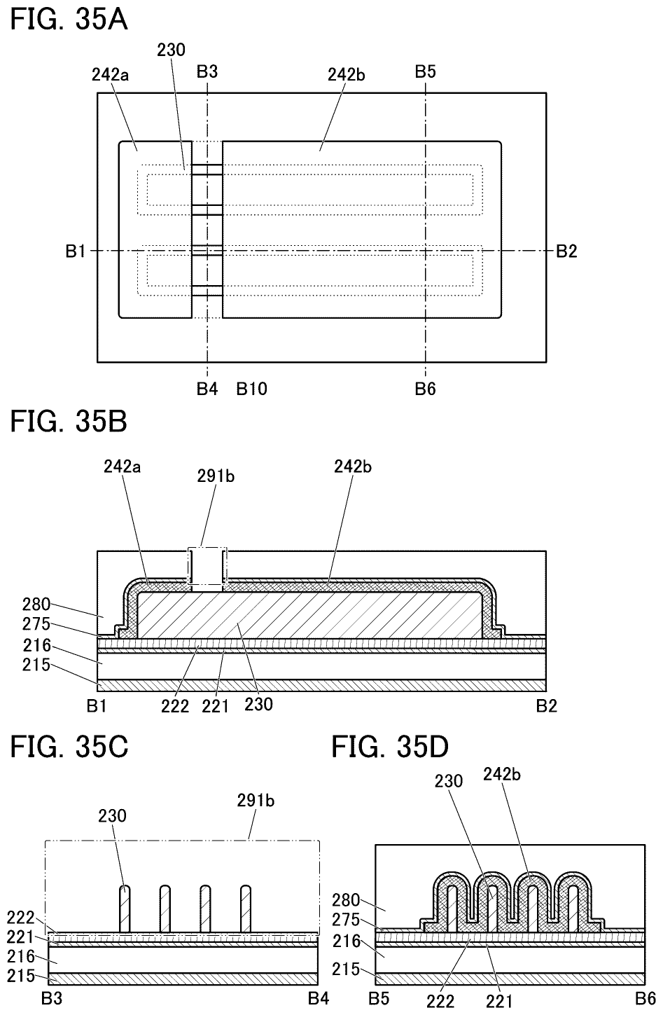

Next, with reference to FIGS. 32A to 32D, the conductive film 242f is partly removed to form a conductor. The insulator 275 is formed to cover the conductor, and the insulator 280 is further formed over the insulator 275. Then, a mask having an opening over a region to be the channel formation region of the transistor 200 is formed by a lithography method. With use of the mask, the insulators 280 and 275 and the conductor are partly removed (see FIGS. 35A to 35D). Thus, an opening portion 291b is provided in the insulators 280 and 275. The conductor is divided into the conductor 242a and the conductor 242b. At this time, no opening portion is provided in a region of the insulators 280 and 275 which overlaps with a region where the capacitor 460 is formed.

FIG. 35A is a plan view. FIG. 35B is a cross-sectional view taken along the dashed-dotted line B1-B2 in FIG. 35A. FIG. 35C is a cross-sectional view taken along the dashed-dotted line B3-B4 in FIG. 35A. FIG. 35D is a cross-sectional view taken along the dashed-dotted line B5-B6 in FIG. 35A. For simplification of the drawing, some components are not illustrated in the plan view of FIG. 35A.

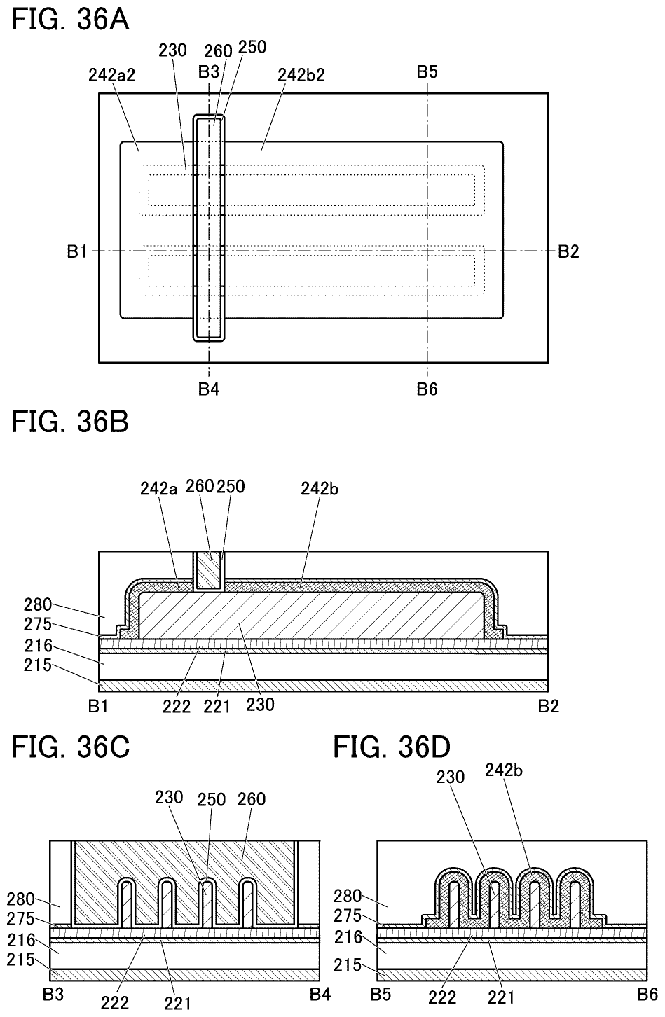

Next, an insulating film to be the insulator 250 and then a conductive film to be the conductor 260 are formed to fill the opening formed in the insulator 280 and the like. After that, the insulating film to be the insulator 250 and the conductive film to be the conductor 260 are polished by CMP treatment until the insulator 280 is exposed. Thus, the insulator 250 and the conductor 260 are formed (see FIGS. 36A to 36D).

FIG. 36A is a plan view. FIG. 36B is a cross-sectional view taken along the dashed-dotted line B1-B2 in FIG. 36A. FIG. 36C is a cross-sectional view taken along the dashed-dotted line B3-B4 in FIG. 36A. FIG. 36D is a cross-sectional view taken along the dashed-dotted line B5-B6 in FIG. 36A. For simplification of the drawing, some components are not illustrated in the plan view of FIG. 36A.

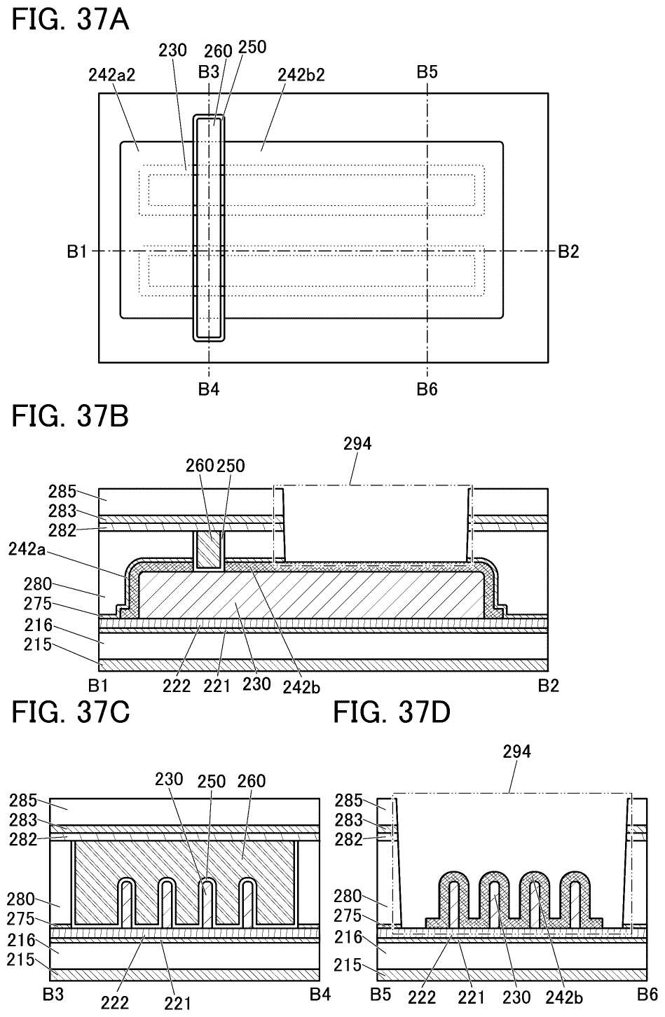

Next, the insulator 282, the insulator 283, and the insulator 285 are formed in this order. Subsequently, an opening reaching the conductor 242b is provided in the insulators 275, 280, 282, 283, and 285 (see FIGS. 37A to 37D). In FIGS. 37A to 37D, an opening portion 294 is provided in a region overlapping with the region where the capacitor 460 is formed.

FIG. 37A is a plan view. FIG. 37B is a cross-sectional view taken along the dashed-dotted line B1-B2 in FIG. 37A. FIG. 37C is a cross-sectional view taken along the dashed-dotted line B3-B4 in FIG. 37A. FIG. 37D is a cross-sectional view taken along the dashed-dotted line B5-B6 in FIG. 37A. For simplification of the drawing, some components are not illustrated in the plan view of FIG. 37A.

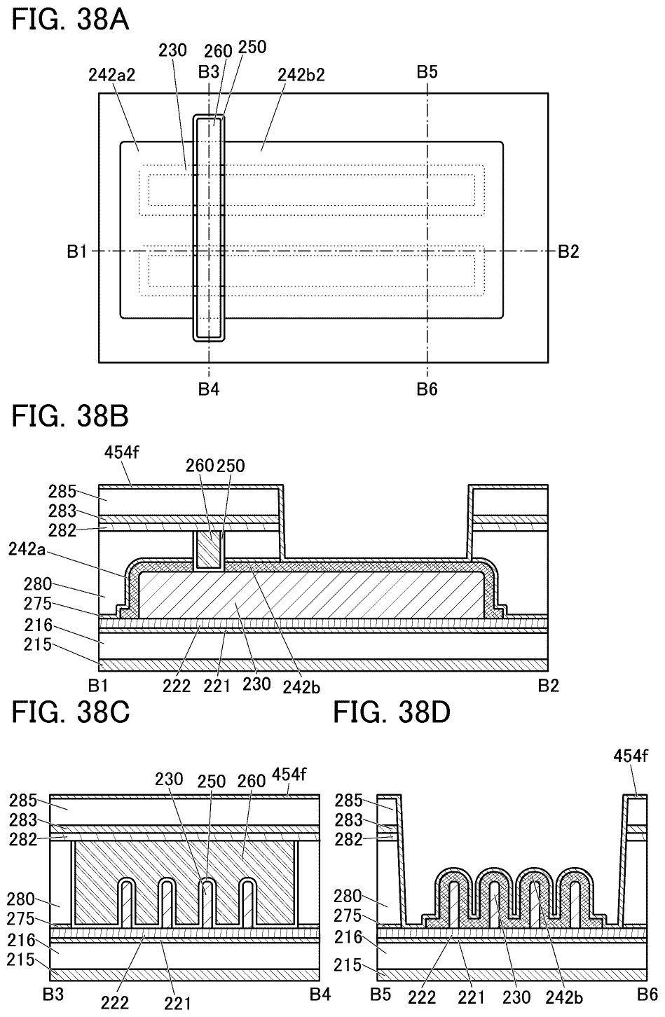

Next, an insulating film 454f is formed (see FIGS. 38A to 38D).

FIG. 38A is a plan view. FIG. 38B is a cross-sectional view taken along the dashed-dotted line B1-B2 in FIG. 38A. FIG. 38C is a cross-sectional view taken along the dashed-dotted line B3-B4 in FIG. 38A. FIG. 38D is a cross-sectional view taken along the dashed-dotted line B5-B6 in FIG. 38A. For simplification of the drawing, some components are not illustrated in the plan view of FIG. 38A.

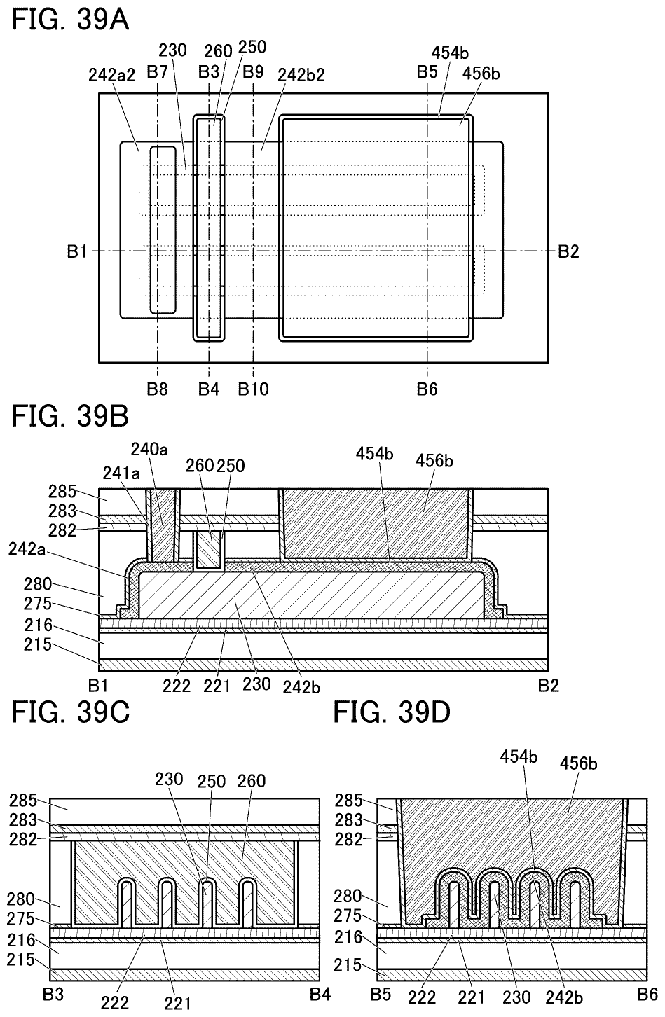

Next, a conductive film to be the conductor 456b is formed, and then the conductive film and the insulating film 454f are partly removed by CMP treatment to expose the top surface of the insulator 285, whereby the conductor 456 and the insulator 454 are formed (see FIGS. 39A to 39D).

Next, an opening reaching the conductor 242a is provided in the insulators 275, 280, 282, 283, and 285. Subsequently, an insulating film to be the insulator 241a is formed and subjected to anisotropic etching, whereby the insulator 241a is formed in the opening reaching the conductor 242a.

Next, a conductive film to be the conductor 240a is formed, and the conductive film to be the conductor 240a is partly removed by CMP treatment to expose the top surface of the insulator 285. As a result, the conductive film remains only in the opening, whereby the conductor 240a having a flat top surface can be formed (see FIGS. 39A to 39D).

At the time of forming the opening portion 294 in FIGS. 37A to 37D, an opening portion may be provided also in the portion where the conductor 240a and the insulator 241a are to be provided. After that, the insulator 241a may be formed by forming the insulating film 454f also in the opening portion and removing part of the insulating film 454f at the bottom portion of the opening portion. In that case, the conductive film to be the conductor 456b may also be provided in the opening portion and subjected to CMP treatment.

Next, the conductor 413 is formed over the conductor 240a.

Through the above steps, the semiconductor device illustrated in FIGS. 16A to 17B can be manufactured.

### Example 3 of Method for Manufacturing Semiconductor Device

A method for manufacturing the semiconductor device illustrated in FIGS. 18A to 19B will be described below. In the semiconductor device illustrated in FIGS. 18A to 19B, the conductors 242a and 242b each have a stacked-layer structure and the stacked conductors have different shapes.

First, the insulators 215, 216, 221, and 222, the oxide semiconductor 230, and the conductive film 242f are formed in this order by the manufacturing method illustrated in FIGS. 27A to 31D. Here, the conductive film 242f has a stacked-layer structure of a conductive film to be the conductors 242a1 and 242b1 and a conductive film to be the conductors 242a2 and 242b2.

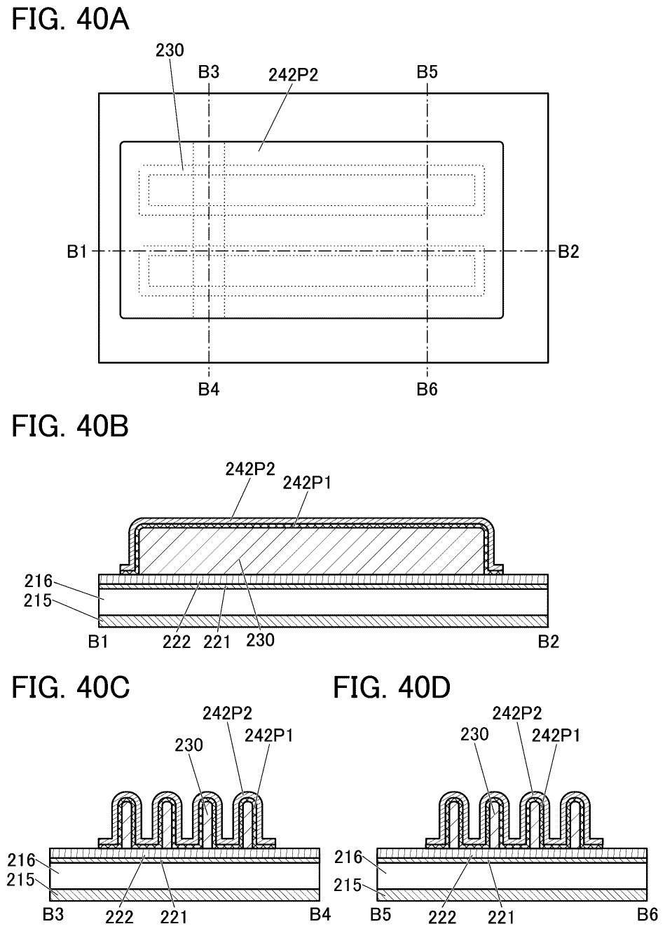

Next, the conductive film to be the conductors 242a2 and 242b2 in the conductive film 242f is partly removed to form a conductor 242P2, and the conductive film to be the conductors 242al and 242b1 in the conductive film 242f is partly removed to form a conductor 242P1 (see FIGS. 40A to 40D).

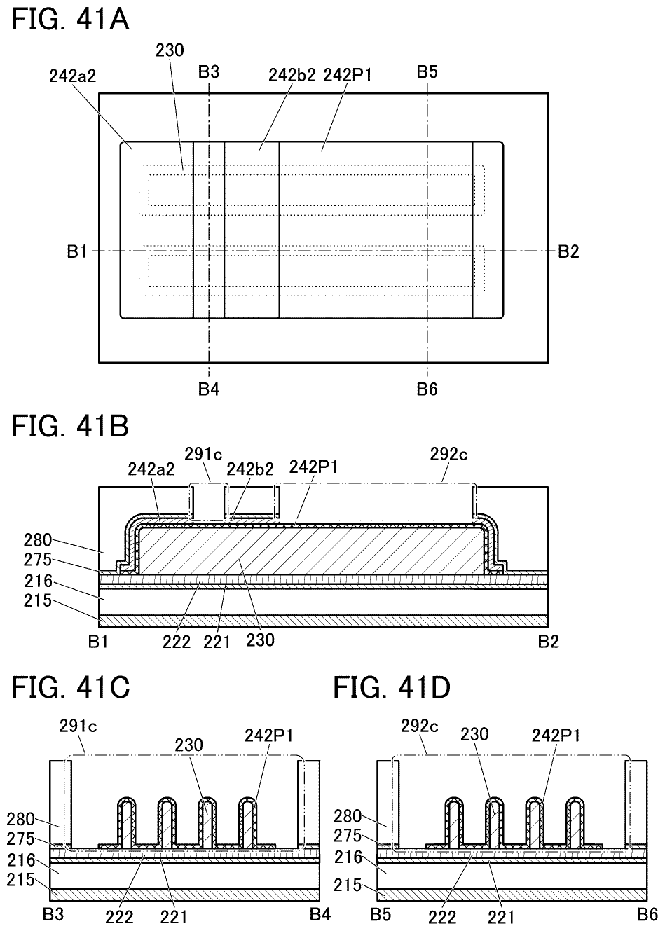

Next, the insulator 275 is formed to cover the conductor 242P2, and the insulator 280 is further formed over the insulator 275 (see FIGS. 41A to 41D).

Next, the conductor 242P2, the insulator 275, and the insulator 280 are processed by a lithography method, whereby openings reaching the conductor 242P1 and the insulator 222 are formed in the insulators 275 and 280 and portions of the conductor 242P2 which overlap with the openings are removed (see FIGS. 41A to 41D). Here, the conductor 242P2 is divided into the conductor 242a2 and the conductor 242b2. In addition, portions of the top surface of the conductor 242P1 which overlap with the openings are exposed.

The openings are formed to overlap with the oxide semiconductor 230 in a region where the transistor 200 is formed and a region where the capacitor 460 is formed. For example, in FIGS. 41B to 41D, an opening portion 291c is formed in the region where the transistor 200 is formed, and an opening portion 292c is formed in the region where the capacitor 460 is formed.

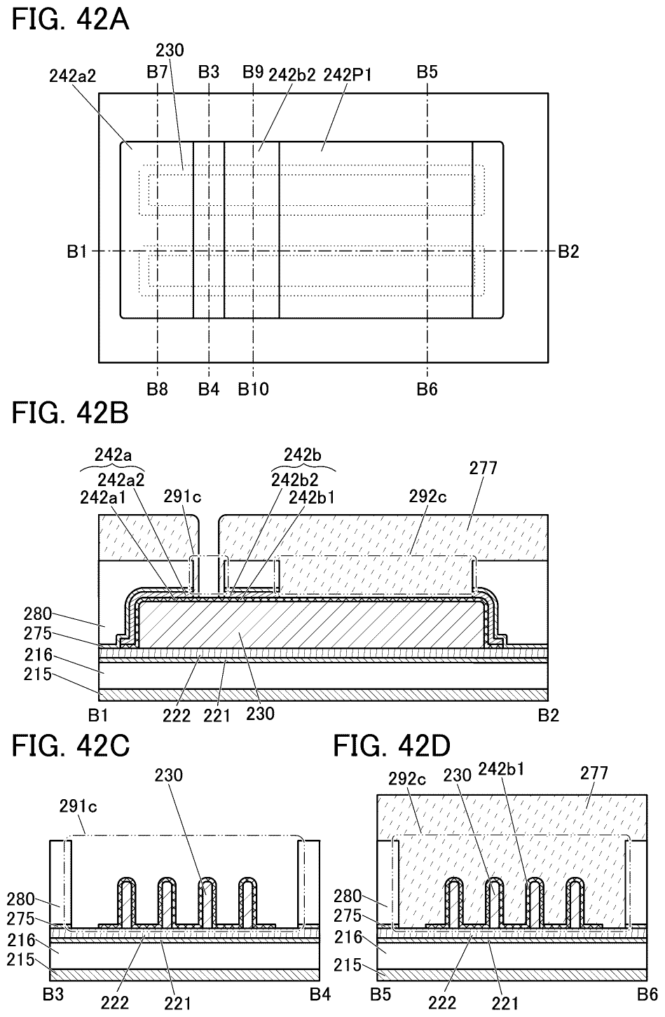

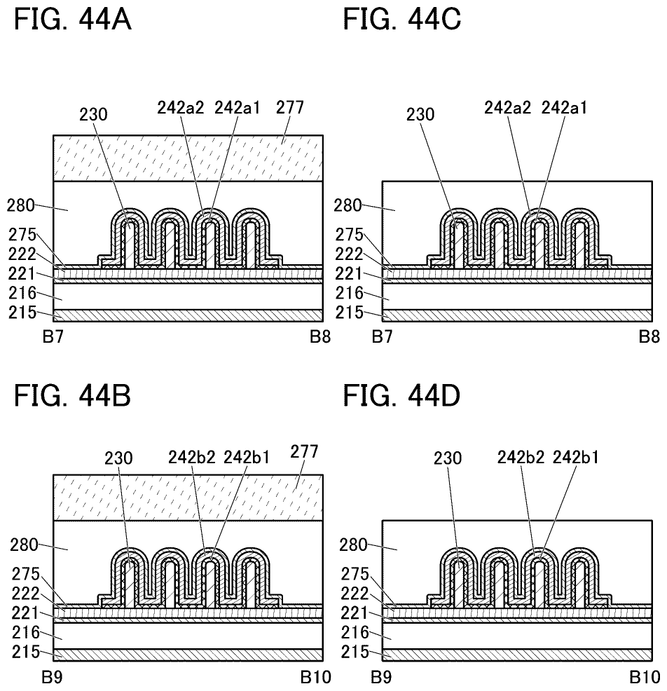

Next, a mask 277 is formed over the insulator 280 and the conductor 242P1 (see FIGS. 42A to 42D, 44A, and 44B).

FIG. 42A is a plan view. FIG. 42B is a cross-sectional view taken along the dashed-dotted line B1-B2 in FIG. 42A. FIG. 42C is a cross-sectional view taken along the dashed-dotted line B3-B4 in FIG. 42A. FIG. 42D is a cross-sectional view taken along the dashed-dotted line B5-B6 in FIG. 42A. FIG. 44A is a cross-sectional view taken along the dashed-dotted line B7-B8 in FIG. 42A. FIG. 44B is a cross-sectional view taken along the dashed-dotted line B9-B10 in FIG. 42A. For simplification of the drawing, some components are not illustrated in the plan view of FIG. 42A.

A resist mask can be used as the mask 277. Alternatively, a stacked-layer structure of an SOC film, an SOG film, and a resist mask may be used.

The mask 277 preferably has an opening in a position overlapping with a region to be the channel formation region of the transistor 200. For example, as illustrated in FIGS. 42B and 42C, an opening portion is provided in a region overlapping with the opening portion 291c, i.e., a region where the conductor 242P2 is removed. As illustrated in FIG. 42B, the opening portion is preferably provided inside the opening portion 291c in the channel length direction.

The mask 277 preferably covers the region to be the capacitor 460. For example, as illustrated in FIGS. 42B and 42D, a region overlapping with the opening portion 292c is preferably covered with the mask 277.

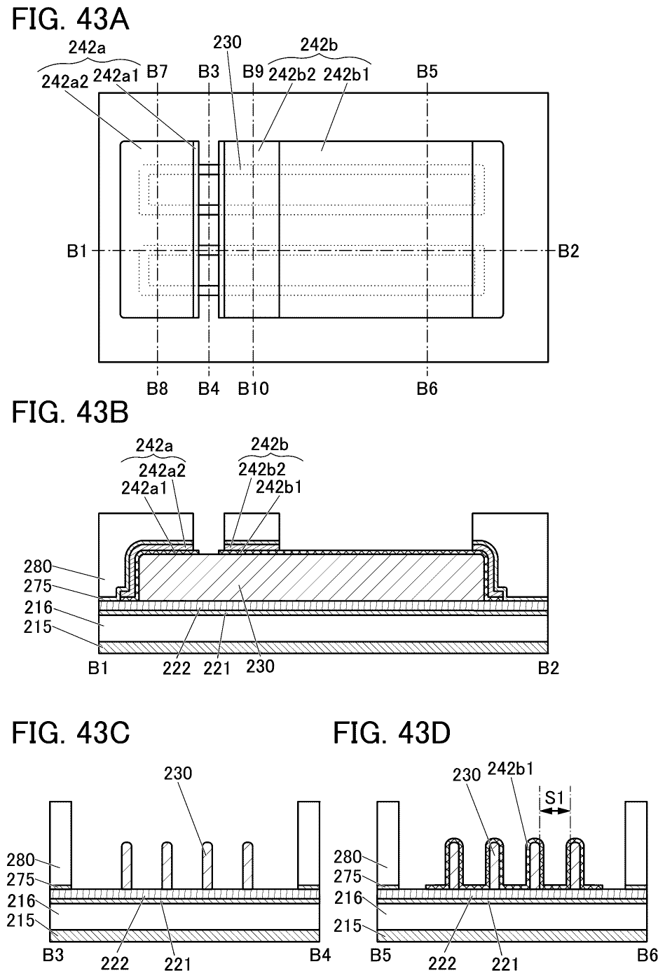

Next, a region of the conductor 242P1 which is covered with neither the mask 277 nor the insulator 280 is removed (see FIGS. 43A to 43D, 44C, and 44D). Here, the conductor 242P1 is divided into the conductor 242al and the conductor 242b1. In a region where the conductor 242P1 is removed, the top surface of the oxide semiconductor 230 that has been covered with the conductor 242P1 is exposed.

Processing using the mask 277 enables the end portions of the conductors 242a1 and 242b1 to extend beyond the end portions of the conductors 242a2 and 242b2 in the region where the transistor 200 is formed.

In addition, the processing using the mask 277 enables the conductor 242b1 to remain over the oxide semiconductor 230 in the region where the capacitor 460 is formed. The remaining conductor 242b1 can be used as the lower electrode of the capacitor 460.

In the method for manufacturing the semiconductor device of one embodiment of the present invention, the mask 277 for processing the conductors to have the extending shape in the transistor 200 can also serve as a mask for leaving the lower electrode of the capacitor 460. Thus, the manufacturing process can be simplified.

In the method for manufacturing the semiconductor device of one embodiment of the present invention, the lower electrode of the capacitor 460 is formed using only the lower layer in the stacked-layer structure of the conductor 242b (the stacked-layer structure of the conductor 242b1 and the conductor 242b2). Thus, the electrode can be thinner than in the case of using the stacked-layer structure of the conductor 242b1 and the conductor 242b2.

FIG. 43D illustrates a space S1 between a plurality of fin-shaped regions of the oxide semiconductor 230 in the B5-B6 direction. Since the lower electrode of the capacitor 460 is thin, the sidewall of the oxide semiconductor 230 can be favorably covered in the space S1 even in the case where the space S1 is narrow.

FIG. 43A is a plan view. FIG. 43B is a cross-sectional view taken along the dashed-dotted line B1-B2 in FIG. 43A. FIG. 43C is a cross-sectional view taken along the dashed-dotted line B3-B4 in FIG. 43A. FIG. 43D is a cross-sectional view taken along the dashed-dotted line B5-B6 in FIG. 43A. FIG. 44C is a cross-sectional view taken along the dashed-dotted line B7-B8 in FIG. 43A. FIG. 44D is a cross-sectional view taken along the dashed-dotted line B9-B10 in FIG. 43A. For simplification of the drawing, some components are not illustrated in the plan view of FIG. 43A.

Next, an insulating film to be the insulators 250 and 454 and then a conductive film to be the conductors 260 and 456 are formed to fill the opening portions formed in the insulator 280 and the like. After that, the insulating film to be the insulators 250 and 454 and the conductive film to be the conductors 260 and 456 are polished by CMP treatment until the insulator 280 is exposed. Thus, the insulators 250 and 454 and the conductors 260 and 456 are formed (see FIGS. 18A to 19B). Note that FIGS. 18A to 19B illustrate an example in which the conductor 260 has a stacked-layer structure of the conductor 260a and the conductor 260b over the conductor 260a.

The insulator 250 is provided in contact with the side surface of the insulator 280, the side surface of the insulator 275, the side surface of the conductor 242a2, and the side surface of the conductor 242b2 in the opening portion 291c. In addition, the insulator 250 is provided in contact with the exposed top surfaces of the conductors 242al and 242b1, the side surfaces of the conductors 242al and 242b1, and the exposed top surface of the oxide semiconductor 230.

The insulator 454 is preferably provided in contact with the side surface of the insulator 280, the side surface of the insulator 275, and the side surface of the conductor 242b2 in the opening portion 292c. In addition, the insulator 454 is preferably provided in contact with the exposed top surface of the conductor 242b1.

Next, with reference to the manufacturing method in FIGS. 14A to 15B, the insulators 282, 283, 285, and 241a and the conductors 240a and 413 are formed, whereby the semiconductor device illustrated in FIGS. 18A to 19B can be manufactured.

This embodiment can be combined with any of the other embodiments as appropriate. In this specification, in the case where a plurality of structure examples are described in one embodiment, the structure examples can be combined as appropriate.

### Embodiment 2

In this embodiment, a semiconductor device 900 of one embodiment of the present invention will be described. The semiconductor device 900 can function as a memory device.

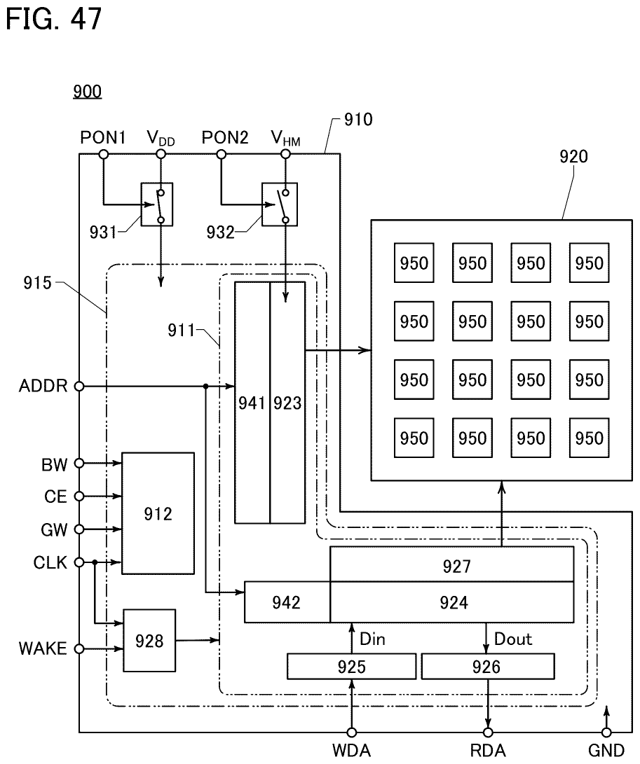

FIG. 47 is a block diagram illustrating a structure example of the semiconductor device 900. The semiconductor device 900 illustrated in FIG. 47 includes a driver circuit 910 and a memory array 920. The memory array 920 includes at least one memory cell 950. FIG. 47 illustrates an example in which the memory array 920 includes a plurality of memory cells 950 arranged in a matrix.

The transistor exemplified in Embodiment 1 can be used for the memory cell 950. With the use of the transistor, the operation speed of the memory device can be increased. This also enables further miniaturization and higher integration of the memory device. In addition, the capacity per area of the memory device can be increased.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, whether to provide or use each circuit, each signal, and each voltage can be selected as appropriate. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signals BW, CE, and GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used to set the word line to the H level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 47 but can be more than one. In that case, a power switch is provided for each power domain.

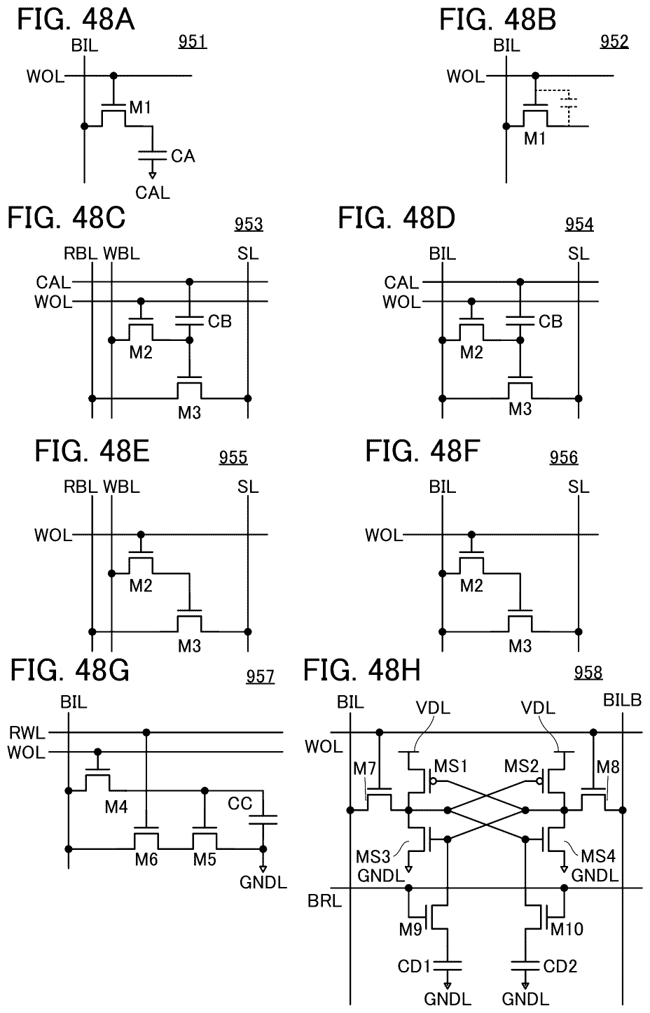

Structure examples of other memory cells each of which can be used as the memory cell 950 are described with reference to FIGS. 48A to 48H.

### [DOSRAM]

FIG. 48A illustrates a circuit structure example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (also referred to as a reference potential in some cases) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 950 is not limited to the memory cell 951, and the circuit structure can be changed. For example, the structure of a memory cell 952 illustrated in FIG. 48B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. Thus, the structure of the memory cell can be greatly simplified.

Note that the transistor M1 is preferably the OS transistor described in Embodiment 1. For example, the transistor 200 and the capacitor 460 illustrated in FIG. 18A or FIG. 18B can be used as the transistor M1 and the capacitor CA in the memory cell 951. As another example, the transistor 200 and the capacitor 460 illustrated in FIG. 19A or FIG. 19B can be used as the transistor M1 and the capacitor CA in the memory cell 951. The use of the OS transistor described in Embodiment 1 enables an increase in the operation speed of the memory device. It also enables a reduction in the area occupied by the memory cell. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 48C illustrates a circuit structure example of a gain memory cell including two transistors and one capacitor. A memory cell 953 includes a transistor M2, a transistor M3, and a capacitor CB. In this specification and the like, a memory device including a gain memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a ground potential) is preferably applied to the wiring CAL.

Data writing is performed by applying a high-level potential to the wiring WOL to turn on the transistor M2, thereby connecting the wiring WBL to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained at the first terminal of the capacitor CB (or the gate of the transistor M3) can be read. That is, data written to the memory cell can be read on the basis of the potential retained at the first terminal of the capacitor CB (or the gate of the transistor M3).

As another example, one wiring BIL may be provided instead of the wiring WBL and the wiring RBL. A circuit structure example of the memory cell is illustrated in FIG. 48D. In a memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 48E is an example in which the capacitor CB and the wiring CAL in the memory cell 953 are omitted. A memory cell 956 illustrated in FIG. 48F is an example in which the capacitor CB and the wiring CAL in the memory cell 954 are omitted. Such structures enable high integration of memory cells.

Note that at least the transistor M2 is preferably the OS transistor described in Embodiment 1. For example, the transistor 200, the transistor 310, and the capacitor 460 illustrated in FIG. 18A or FIG. 18B can be used as the transistor M2, the transistor M3, and the capacitor CB in the memory cell 953 and the memory cell 954. It is particularly preferable that the transistor M2 and the transistor M3 each be the OS transistor described in Embodiment 1. For example, the transistor 200, the transistor 200b, and the capacitor 460 illustrated in FIG. 19A or FIG. 19B can be used as the transistor M2, the transistor M3, and the capacitor CB in the memory cell 953 and the memory cell 954. The use of the OS transistor described in Embodiment 1 enables an increase in the operation speed of the memory device. It also enables a reduction in the area occupied by the memory cell.

Since the OS transistor has a characteristic of an extremely low off-state current, the transistor M2 enables written data to be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of NOSRAMs.

Note that the transistor M3 may be a Si transistor. The Si transistor can have a high field-effect mobility and can be formed as a p-channel transistor, so that circuit design flexibility can be increased.

When the OS transistor is used as the transistor M3, the memory cell can be configured with the transistors having the same conductivity type.

FIG. 48G illustrates an example of a gain memory cell 957 including three transistors and one capacitor. A memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed by applying a high-level potential to the wiring WOL to turn on the transistor M4, thereby connecting the wiring BIL to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that the wiring BIL is connected to the second terminal of the transistor M5. At this time, the potential of the wiring BIL is applied to the second terminal of the transistor M5; the potential of the second terminal of the transistor M5 and the potential of the wiring BIL change depending on the potential retained at the first terminal of the capacitor CC (or the gate of the transistor M5). Here, the potential retained at the first terminal of the capacitor CC (or the gate of the transistor M5) can be read by reading the potential of the wiring BIL. That is, data written to the memory cell can be read on the basis of the potential retained at the first terminal of the capacitor CC (or the gate of the transistor M5).

Note that at least the transistor M4 is preferably the OS transistor described in Embodiment 1. The use of the OS transistor described in Embodiment 1 enables a reduction in the area occupied by the memory cell.

Note that the transistors M5 and M6 may be Si transistors. As described above, a Si transistor may have a higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 48H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 48H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential applied to the wiring BIL (i.e., the signal input to the wiring BIL) is output to the wiring BILB. Since the transistor M9 and the transistor M10 are on, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, the transistors M7 to M10 enable written data to be retained for a long time, and thus the frequency of refresh operation for the memory cell can be decreased. Alternatively, refresh operation for the memory cell can be omitted. The use of the OS transistors described in Embodiment 1 as the transistors M7 to M10 enables an increase in the operation speed of the memory device. It also enables a reduction in the area occupied by the memory cell.

Note that the transistors MS1 to MS4 may be Si transistors.

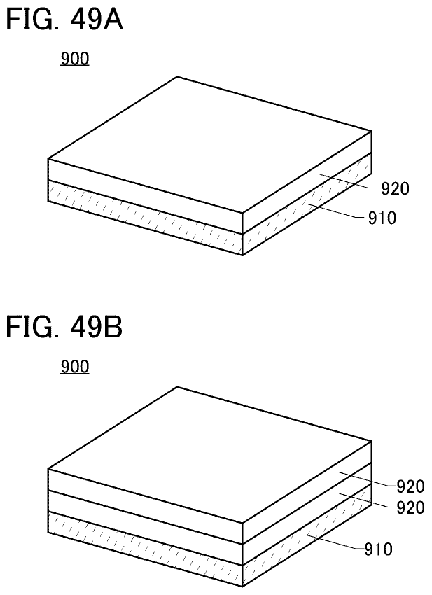

The driver circuit 910 and the memory array 920 included in the semiconductor device 900 may be provided on the same plane. Alternatively, as illustrated in FIG. 49A, the driver circuit 910 and the memory array 920 may be provided to overlap with each other. Overlapping the driver circuit 910 and the memory array 920 can shorten a signal transmission distance. As illustrated in FIG. 49B, a plurality of memory arrays 920 may be stacked over the driver circuit 910.

In the above memory array 920, a plurality of memory arrays 920[1] to 920[m] can be provided in stacked layers. When the memory arrays 920[1] to 920[m] included in the memory array 920 are provided in a direction perpendicular to a surface of the substrate provided with the driver circuit 910, the memory density of the memory cells 951 can be increased. The memory array 920 can be formed by repeating the same manufacturing process in the perpendicular direction. The manufacturing cost of the memory array 920 in the semiconductor device 900 can be reduced.

### Structure Example of Semiconductor Device Including Memory Arrays

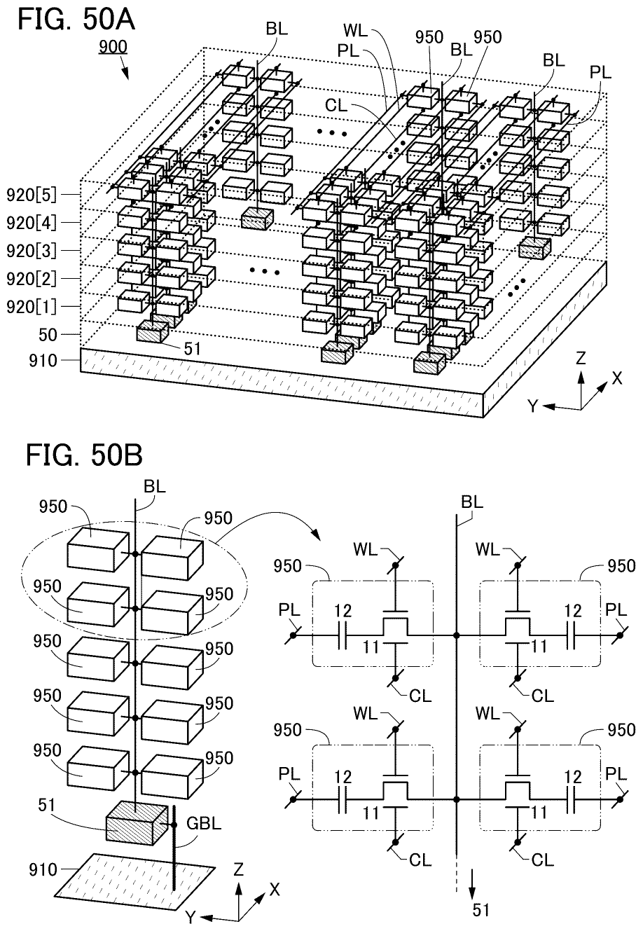

In the semiconductor device 900, a plurality of memory arrays 920 can be provided in stacked layers as described above. For example, in the semiconductor device 900, the plurality of memory arrays 920[1] to 920[m] can be provided in stacked layers as illustrated in FIG. 50A. When the memory arrays 920[1] to 920[m] included in the memory array 920 are provided in a direction perpendicular to a surface of the substrate provided with the driver circuit 910, the memory density of the memory cells 950 can be increased.

A wiring BL functions as a bit line for writing and reading data. A wiring WL functions as a word line for controlling on and off states (conduction and non-conduction states) of an access transistor serving as a switch. A wiring PL has a function of a constant potential line connected to a capacitor. Note that a wiring CL (not illustrated) can be additionally provided as a wiring having a function of supplying a back gate potential to a back gate of an OS transistor serving as the access transistor. The wiring PL may also have a function of supplying the back gate potential.

The memory cell 950 included in each of the memory arrays 920[1] to 920[m] is connected to a functional circuit 51 through the wiring BL. The wiring BL can be provided in the direction perpendicular to the surface of the substrate provided with the driver circuit 910. Since the wiring BL provided to extend from the memory cells 950 included in the memory arrays 920[1] to 920[m] is provided in the direction perpendicular to the surface of the substrate, the length of the wiring between the memory array 920 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 950 is reduced, operation is possible.

The functional circuit 51 has functions of amplifying a data potential retained in the memory cell 950 and outputting the amplified data potential to the sense amplifier 927 included in the driver circuit 910 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 910. Since the wiring BL and the wiring GBL provided to extend from the memory cells 950 included in the memory arrays 920[1] to 920[m] are provided in the direction perpendicular to the surface of the substrate, the length of the wiring between the functional circuit 51 and the sense amplifier 927 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with the semiconductor layer of the transistor included in the memory cell 950. Alternatively, the wiring BL is provided in contact with a region functioning as the source or the drain in the semiconductor layer of the transistor included in the memory cell 950. Alternatively, the wiring BL is provided in contact with a conductor provided in contact with the region functioning as the source or the drain in the semiconductor layer of the transistor included in the memory cell 950. That is, the wiring BL is a wiring for connecting one of the source and the drain of the transistor included in the memory cell 950 in each layer of the memory array 920 to the functional circuit 51 in the perpendicular direction.

The memory array 920 can be provided over the driver circuit 910 to overlap therewith. When the driver circuit 910 and the memory array 920 are provided to overlap with each other, a signal transmission distance between the driver circuit 910 and the memory array 920 can be shortened. Accordingly, resistance and parasitic capacitance between the driver circuit 910 and the memory array 920 are reduced, so that power consumption and signal delays can be reduced. In addition, the semiconductor device 900 can be downsized.

The functional circuit 51 can be provided in any desired position, e.g., over a circuit that is formed using Si transistors in a manner similar to that of the memory arrays 920[1] to 920[m] when the functional circuit 51 is formed with an OS transistor like the transistor included in the memory cell 950 of the DOSRAM, whereby integration can be easily performed. With the structure in which a signal is amplified by the functional circuit 51, a circuit in a subsequent stage, such as the sense amplifier 927, can be downsized, so that the semiconductor device 900 can be downsized.

In the memory array 920 including the memory arrays 920[1] to 920[m](m is an integer greater than or equal to 2) and a functional layer 50, the memory arrays 920 can be provided in stacked layers over the driver circuit 910. Stacking the memory arrays 920 in the plurality of layers can increase the memory density of the memory cells 950. FIG. 50A illustrates a perspective view of the semiconductor device 900 which includes the functional layer 50 and five layers (m=5) of memory arrays 920[1] to 920[5], which overlap with each other, over the driver circuit 910.

In FIG. 50A, the memory array 920 in the first layer is denoted as the memory array 920[1], the memory array 920 in the second layer is denoted as the memory array 920[2], and the memory array 920 in the fifth layer is denoted as the memory array 920[5]. FIG. 50A also illustrates the wiring WL and the wiring PL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 920 are not illustrated.

Each of the plurality of memory cells 950 included in the memory array 920 includes a transistor 11 and a capacitor 12. The transistor 11 and the capacitor 12 can be the transistor 200 and the capacitor 460 described in the above embodiment.

FIG. 50B illustrates an example in which the memory cell 950 employs the structure of the memory cell 951 illustrated in FIG. 48A. Here, the description of the wiring BIL, the wiring WOL, and the wiring CAL in FIG. 48A can be referred to for the wiring WL, the wiring BL, and the wiring PL, respectively. The description of the transistor M1 and the capacitor CA in FIG. 48A can also be referred to for the transistor 11 and the capacitor 12.

FIG. 50B is a schematic view for describing a structure example of the functional circuit 51, which is connected to the wiring BL, and the memory cells 950 included in the memory arrays 920[1] to 920[5], which are connected to the wiring BL, illustrated in FIG. 50A. FIG. 50B also illustrates the wiring GBL provided between the functional circuit 51 and the driver circuit 910. Note that a structure in which a plurality of memory cells (memory cells 950) are connected to one wiring BL is also referred to as “memory string”. In the drawings, the wiring GBL in some cases is represented by a bold line for increasing visibility.

FIG. 50B illustrates an example of a circuit structure of the memory cell 950 connected to the wiring BL. As for the transistor 11, the capacitor 12, and the wirings (e.g., the wiring BL and the wiring WL), for example, a wiring BL[1] and a wiring WL[1] are referred to as the wiring BL and the wiring WL in some cases.

In the memory cell 950, one of the source and the drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring CL.

The wiring PL supplies a constant potential for retaining the potential of the capacitor 12. The wiring CL supplies a constant potential for controlling the threshold voltage of the transistor 11. The wiring PL and the wiring CL may have the same potential. In that case, the number of wirings connected to the memory cell 950 can be reduced by connecting the two wirings.

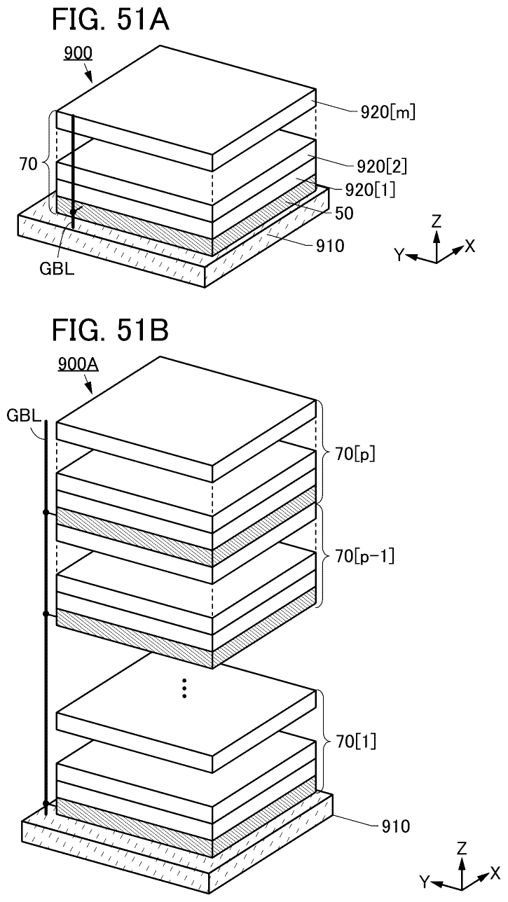

The wiring GBL illustrated in FIG. 50B is provided to connect the driver circuit 910 and the functional layer 50. FIG. 51A illustrates a schematic view of the semiconductor device 900 in which the functional circuit 51 and the memory arrays 920[1] to 920[m] are regarded as a repeating unit 70. Although FIG. 51A illustrates one wiring GBL, the wiring GBL is provided as appropriate depending on the number of functional circuits 51 provided in the functional layer 50.

The wiring GBL is provided in contact with the semiconductor layer of a transistor included in the functional circuit 51. Alternatively, the wiring GBL is provided in contact with a region functioning as the source or the drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL is a wiring for connecting one of the source and the drain of the transistor included in the functional circuit 51 in the functional layer 50 to the driver circuit 910 in the perpendicular direction.

The repeating unit 70 including the functional circuit 51 and the memory arrays 920[1] to 920[m] may have a stacked-layer structure. A semiconductor device 900A of one embodiment of the present invention can include repeating units 70[1] to 70[p](p is an integer greater than or equal to 2) as illustrated in FIG. 51B. The wiring GBL is connected to the functional layers 50 included in the repeating unit 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 910. Since the wiring provided to extend from the memory array 920 and function as a bit line is provided in the direction perpendicular to the surface of the substrate, the length of the wiring between the memory array 920 and the driver circuit 910 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 950 is provided in a layer where the memory array 920 is provided. With this structure, a slight difference in the potential of the wiring BL functioning as a bit line can be amplified at the time of data reading to drive the sense amplifier 927 included in the driver circuit 910. A circuit such as a sense amplifier can be downsized, so that the semiconductor device 900 can be downsized. Moreover, even when the capacitance of the capacitors 12 included in the memory cells 950 is reduced, operation is possible.

Although an example in which the memory cell 950 has a one-transistor and one-capacitor (1T1C) structure like the memory cell 951 illustrated in FIG. 48A or the like is described above, the present invention is not limited to this example. For example, any of the structures illustrated in FIGS. 48B to 48H and the like can be used for the memory cell of the semiconductor device.

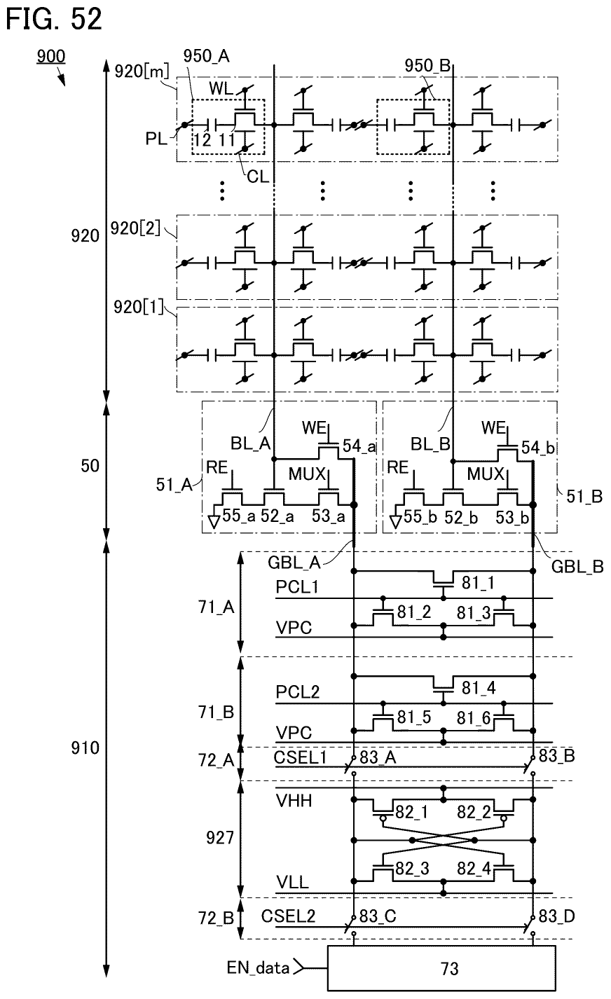

A structure example of the functional circuit 51 and structure examples of the memory array 920 and the sense amplifier 927 included in the driver circuit 910, which are described with reference to FIG. 51A, are described with reference to FIG. 52. FIG. 52 illustrates the driver circuit 910 connected to the wirings GBL (a wiring GBL_A and a wiring GBL_B) connected to the functional circuits 51 (a functional circuit 51_A and a functional circuit 51_B) connected to the memory cells 950 (a memory cell 950_A and a memory cell 950_B) connected to different wirings BL (a wiring BL_A and a wiring BL_B). FIG. 52 also illustrates, as the driver circuit 910, a precharge circuit 71_A, a precharge circuit 71_B, a switch circuit 72_A, a switch circuit 72_B, and a write/read circuit 73 in addition to the sense amplifier 927.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 52 are OS transistors like the transistor 11 included in the memory cell 950. The functional layer 50 including the functional circuits 51 can be provided in stacked layers like the memory arrays 920[1] to 920[m].

The wiring BL_A is connected to a gate of the transistor 52_a, and the wiring BL_B is connected to a gate of the transistor 52_b. One of a source and a drain of each of the transistors 53_a and 54_a is connected to the wiring GBL_A. One of a source and a drain of each of the transistors 53_b and 54_b is connected to the wiring GBL_B. The wirings GBL_A and GBL_B are provided in the perpendicular direction like the wirings BL_A and BL_B and connected to transistors included in the driver circuit 910. As illustrated in FIG. 52, a selection signal MUX, a control signal WE, or a control signal RE is supplied to gates of the transistors 53_a, 53_b, 54_a, 54_b, 55_a, and 55_b.

Transistors 81_1 to 81_6 and 82_1 to 82_4 included in the sense amplifier 927, the precharge circuit 71_A, and the precharge circuit 71_B illustrated in FIG. 52 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 927, or the switch circuit 72_A.

The precharge circuit 71_A includes the n-channel transistors 81_1 to 81_3. The precharge circuit 71_A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 927 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged by selecting the memory cells 950_A and 950_B are changed, and the potentials of the wiring GBL_A and the wiring GBL_B are set to VDD or VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 927 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 927. The on and off states of the switch circuit 72_B are switched under the control of a switching signal CSEL2. The switches 83_C and 83_D are similar to the switches 83_A and 83_B.

As illustrated in FIG. 52, the semiconductor device 900 can have a structure where the memory cell 950, the functional circuit 51, and the sense amplifier 927 are connected to each other through the wiring BL and the wiring GBL provided in the perpendicular direction which is the shortest distance. Even with addition of the functional layer 50 including transistors included in the functional circuit 51, the load of the wiring BL is reduced, whereby the writing time can be shortened and data reading can be facilitated.

As illustrated in FIG. 52, the transistors included in the functional circuits 51_A and 51_B are controlled in accordance with the control signals WE and RE and the selection signal MUX. The transistors can output the potential of the wiring BL through the wiring GBL to the driver circuit 910 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 927 formed using Si transistors.

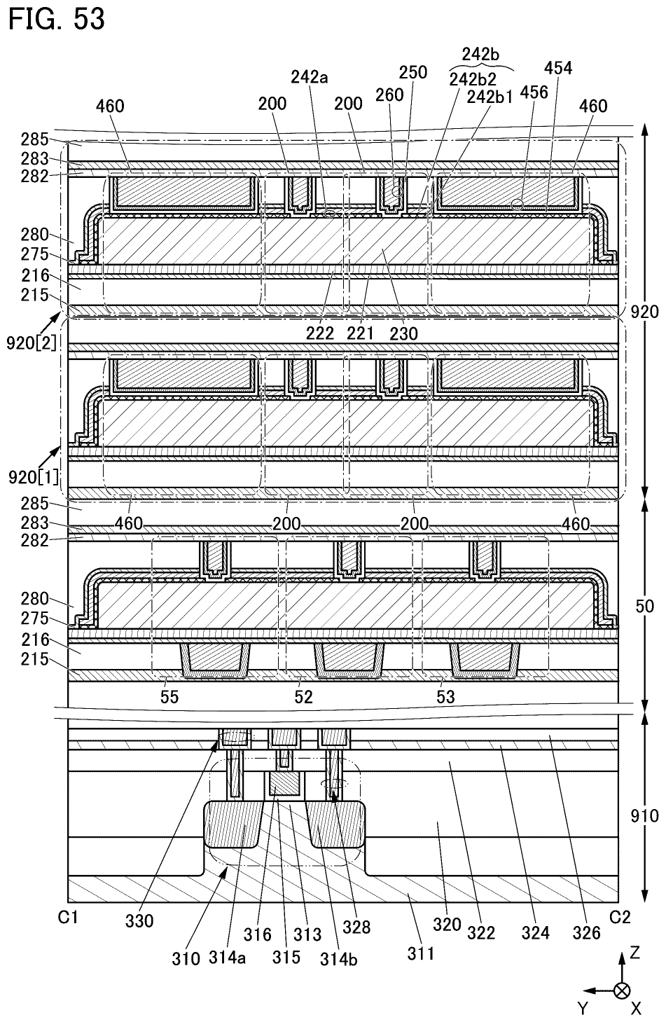

A structure example of the semiconductor device 900 is described with reference to FIG. 53.

The semiconductor device 900 includes the driver circuit 910, which is a layer including a transistor 310 and the like, the functional layer 50, which is a layer including transistors 52, 53, 54, 55, and the like over the driver circuit 910, and the memory arrays 920[1] to 920[m] over the functional layer 50 (FIG. 53 illustrates only the memory arrays 920[1] and 920[2]). Note that the transistor 52 corresponds to the transistors 52_a and 52_b illustrated in FIG. 52, the transistor 53 corresponds to the transistors 53_a and 53_b illustrated in FIG. 52, and the transistor 55 corresponds to the transistors 55_a and 55_b illustrated in FIG. 52. Although not illustrated, the transistor 54 (corresponding to the transistors 54_a and 54_b illustrated in FIG. 52) can be provided in the functional layer 50 where the transistor 52 and the like are provided. The transistor 54 can have a structure similar to that of the transistor 52 or the like.

The transistor 310 included in the driver circuit 910 can be the transistor 310 illustrated in FIGS. 24A and 24B and the like.

An insulator 320, an insulator 322, an insulator 324, and an insulator 326 are sequentially provided in stacked layers over the transistor 310. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a chemical mechanical polishing (CMP) method or the like to have improved planarity.

FIG. 53 also illustrates an example of the transistors 52, 53, and 55 included in the functional layer 50. The transistors 52, 53, and 55 have a structure similar to that of the transistor 200 included in the memory cell 950. The transistors 52, 53, and 55 have their sources and drains connected in series.

In the functional layer 50, the insulators 275, 280, 282, 283, 285, and the like are provided over the transistors 52, 53, and 55. In addition, the memory array 920[1] is provided over the insulator 285. In the memory array 920[1], the insulator 215 is provided over the insulator 285 in the functional layer 50, the insulator 216 is provided over the insulator 215, and the transistor 200 is provided over the insulator 216. The insulators 275, 280, 282, 283, 285, and the like are provided over the transistor 200.

Each of the memory arrays 920[1] to 920[m] includes the plurality of memory cells 950. The conductor 242b of each of the memory cells 950 is connected to the conductor 240 in an upper layer and to the conductor 240 in a lower layer.

As illustrated in FIG. 53, the conductor 242a is shared by the adjacent memory cells 950. The structures of the adjacent memory cells 950 are symmetrical with respect to the conductor 242a. The adjacent memory cells 950 are arranged such that the transistors 200 are adjacent to each other.

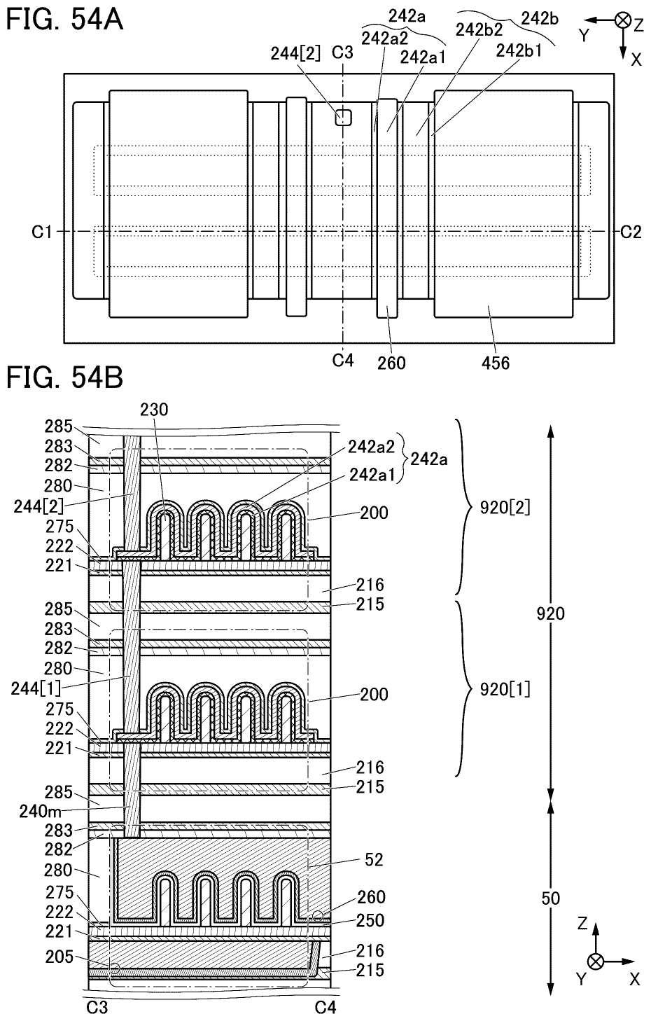

Note that FIG. 54A is a top view of the semiconductor device illustrated in FIG. 53. FIG. 53 is a cross-sectional view taken along the dashed-dotted line C1-C2 in FIG. 54A. FIG. 54B is a cross-sectional view taken along the dashed-dotted line C3-C4 in FIG. 54A. The dashed-dotted line C3-C4 is perpendicular to the dashed-dotted line C1-C2.

The conductor 242a of the memory array 920[1] is connected to the conductor 260 of the transistor 52 included in the functional layer 50 through a conductor 240m. The conductor 240m is provided to fill an opening portion in the insulators 282, 283, and 285 of the functional layer 50 and the insulators 215, 216, 221, and 222 of the memory array 920[1].

The conductor 242a in the lower layer (e.g., the memory array 920[1]) is connected to the conductor 242a in the upper layer (e.g., the memory array 920[2]) through a conductor 244 (e.g., a conductor 244[1] of the memory array 920[1]). The conductor 244 is provided to fill an opening portion in the insulators 275, 280, 282, 283, and 285 and the insulators 215, 216, 221, and 222 of the upper layer. Although the conductor 240m, the conductor 244, or the like is illustrated as one plug in FIG. 54B, the conductor 240m, the conductor 244, or the like may include a plurality of plugs.

Note that the height of the oxide semiconductor 230 is larger than the width thereof in the semiconductor device of one embodiment of the present invention. That is, in a plan view, the area of the oxide semiconductor 230 is small, so that the proportion of the area occupied by the oxide semiconductor 230 can be small. Thus, a plug for connecting the upper and lower layers can be easily placed in a region where the oxide semiconductor 230 is not provided. Thus, the opening portion to be filled with the plug does not need to be formed in the oxide semiconductor 230. Since no opening needs to be formed in the oxide semiconductor 230, the level of difficulty of the manufacturing process can be lowered and the semiconductor device can be easily manufactured even in the case where the etching rate of the oxide semiconductor 230 is low or it is difficult to inhibit the generation of a reaction product due to etching. Accordingly, mass-productivity can be increased.

In the above memory array 920, the plurality of memory arrays 920[1] to 920[m] can be provided in stacked layers. When the memory arrays 920[1] to 920[m] included in the memory array 920 are provided in a direction perpendicular to the surface of the substrate provided with the driver circuit 910, the memory density of the memory cells 950 can be increased. The memory array 920 can be formed by repeating the same manufacturing process in the perpendicular direction. The manufacturing cost of the memory array 920 in the semiconductor device 900 can be reduced.

### Structure Example of Semiconductor Device Including Arithmetic Processing Device

Next, description is made on an example of an arithmetic processing device that can include the semiconductor device, such as the memory device described above.

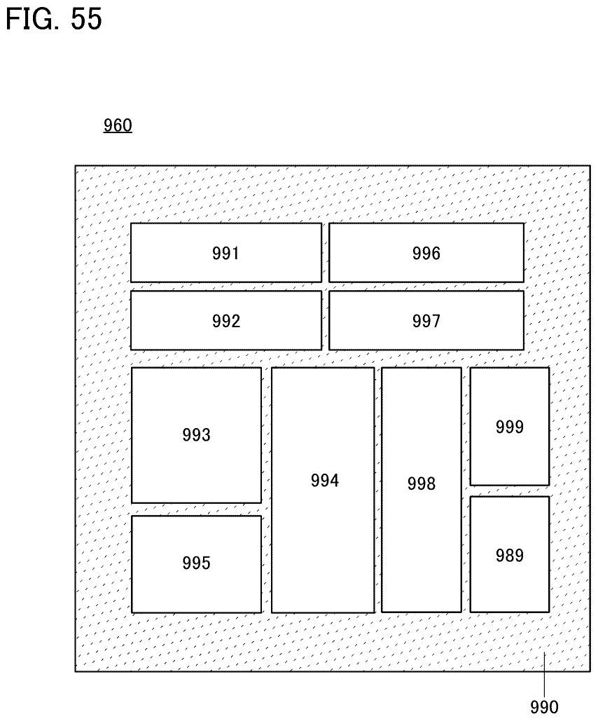

FIG. 55 is a block diagram of an arithmetic device 960. The arithmetic device 960 illustrated in FIG. 55 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 55 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 55 is only an example with a simplified configuration, and the actual arithmetic device 960 has a variety of configurations depending on the application. For example, what is called a multicore configuration is preferably employed in which a plurality of cores each including the arithmetic device 960 in FIG. 55 operate in parallel. A larger number of cores can further enhance the arithmetic performance. The number of cores is preferably larger; for example, the number is preferably 2, further preferably 4, further preferably 8, further preferably 12, further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit or a data bus can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 processes an interrupt request from an external input/output device, a peripheral circuit, or the like after making a determination based on its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 55, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

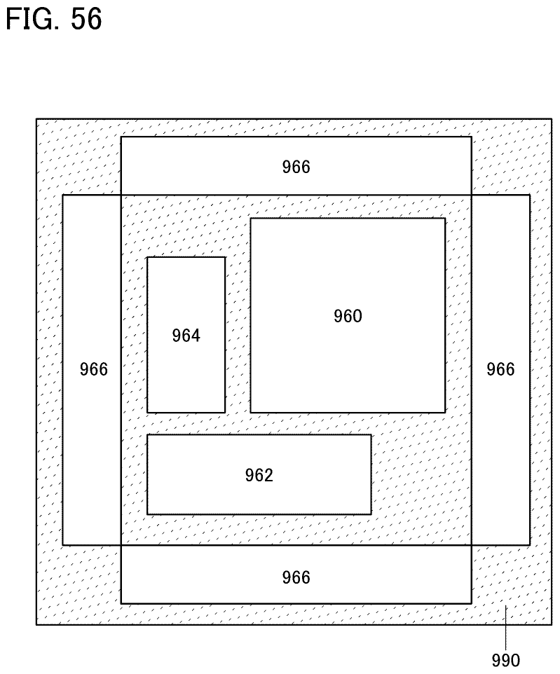

FIG. 56 illustrates an example in which the substrate 990 is provided with not only the arithmetic device 960 but also a memory device 962, an interface circuit 964, an input/output portion 966, and the like.

The memory device 962 can be used as a cache at a lower level than the cache 999 or as a main memory. The memory device 962 is connected to the cache interface 989 in the arithmetic device 960 through the interface circuit 964. The memory device 962 is connected to a main memory provided in another chip through the interface circuit 964 and the input/output portion 966.

The semiconductor device 900 including the memory array 920 can be used for the memory device 962.

The interface circuit 964 is provided with a variety of interface circuits and bus lines. The interface circuit 964 may include a power supply circuit, a clock generation circuit, or the like.

The interface circuit 964 can be provided with an inter-integrated circuit (I2C), a serial peripheral interface (SPI), a general purpose input/output (GPIO), or the like.

The input/output portion 966 includes an input portion to which a signal, a potential, or the like is input from the outside, and an output portion to which a signal is output to the outside. The input/output portion 966 is provided with a plurality of connection terminals, and is connected to a substrate different from the substrate 990 through a connection wiring. Moreover, the input/output portion 966 may be provided with a buffer circuit, a protection circuit, or the like.

The substrate 990 can be connected to another substrate by a method such as wire bonding using a gold or copper wiring, flip-chip bonding using a bump, or direct bonding (hybrid bonding) using a direct bonding technique such as Cu—Cu bonding. Alternatively, as a bonding method without using a substrate, the following method may be used: two or more layers are bonded to each other with an insulating film and then a through electrode is formed, whereby electrodes or the like provided in the layers are connected to each other. A method using direct bonding or a through electrode is particularly preferably used, in which case the pitch width between the connection electrodes can be extremely narrowed and thus a large amount of connection electrodes can be arranged at high density, whereby a larger amount of data can be transmitted between layers.

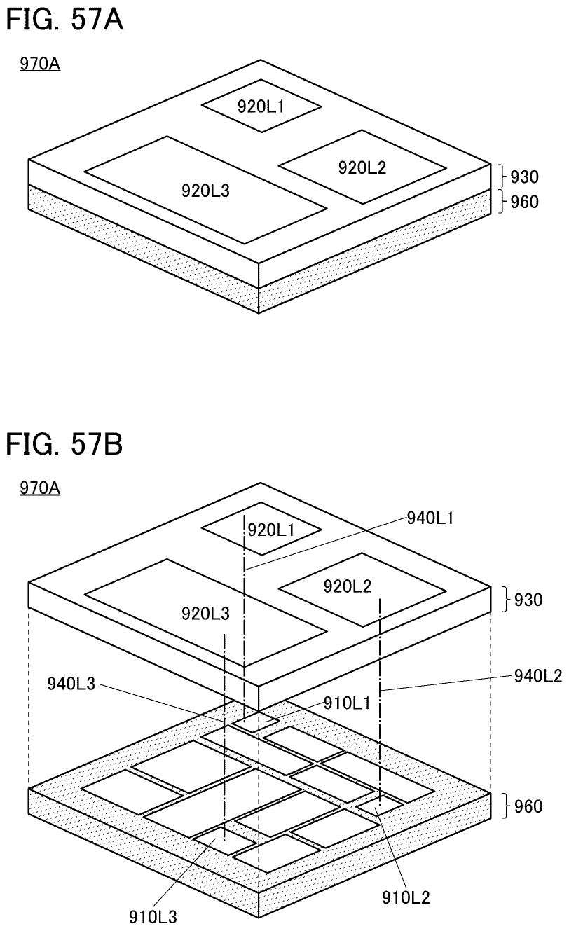

The memory array 920 and the arithmetic device 960 can be provided to overlap with each other. FIGS. 57A and 57B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 57B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 57B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

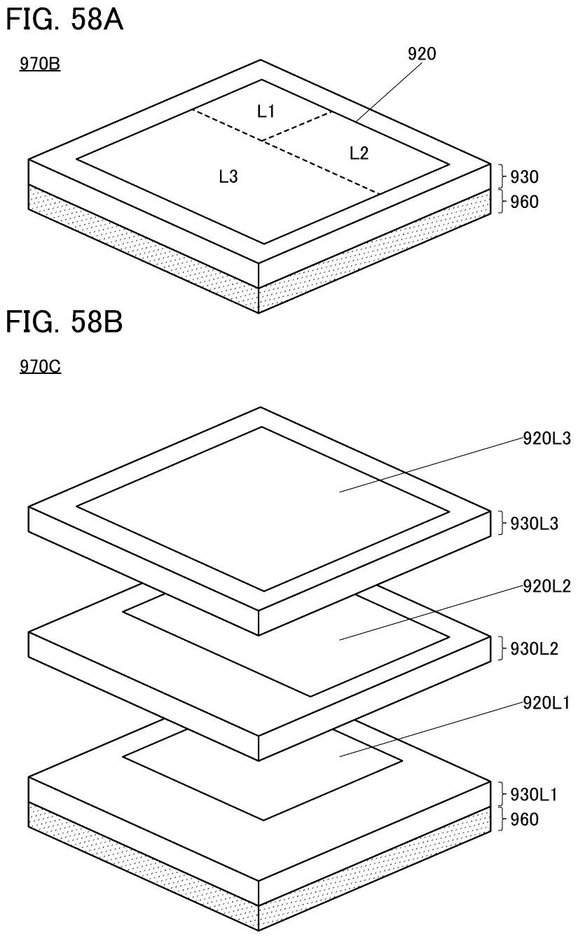

The layer 930 including one memory array 920 may be provided to overlap with the arithmetic device 960. FIG. 58A is a perspective view of a semiconductor device 970B.

In the semiconductor device 970B, one memory array 920 can be divided into a plurality of areas having different functions. FIG. 58A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 58B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 3

In this embodiment, application examples of the memory device of one embodiment of the present invention are described.

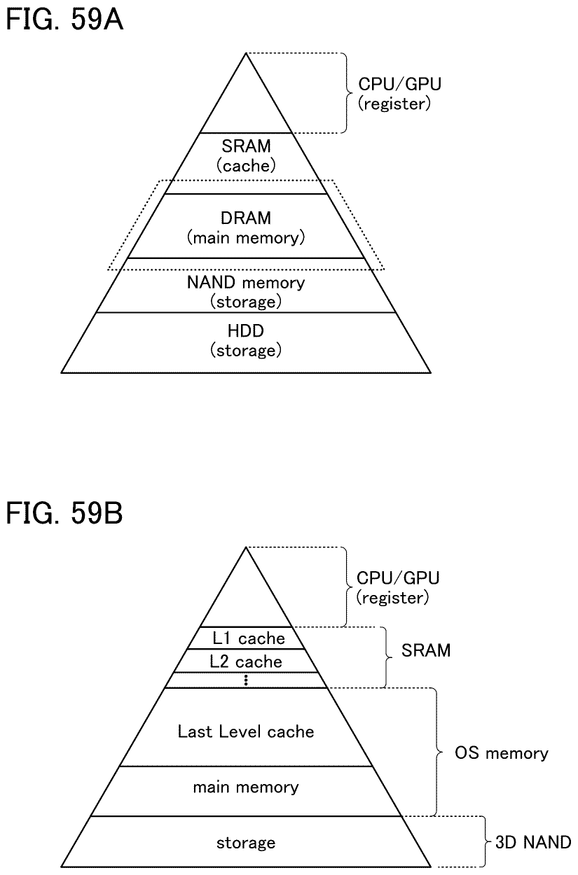

First, a hierarchy of memory devices used for the semiconductor device is described. FIG. 59A illustrates a conventional hierarchy of memory devices.

In FIG. 59A, memory devices closer to a processor (CPU/GPU) are accessed more frequently, and a longer length of the bottom of a region means a higher data capacity. The memory devices closer to the processor require higher operation speeds, and the memory devices farther from the processor require larger memory capacities and higher recording densities. FIG. 59A illustrates an example in which a register is used as a memory included in the processor such as a CPU or a GPU, an SRAM is used as a cache memory, a DRAM is used as a main memory, and a NAND memory and a hard disk drive (HDD) are used as storage.

The memory included in the processor such as a CPU or a GPU is used for temporary storage of arithmetic operation results, for example, and thus is very frequently accessed by an arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage, for example.

The storage has a function of retaining data that needs to be stored for a long time and programs used in the arithmetic processing device, for example. Therefore, the storage needs to have a large memory capacity and a high memory density rather than operating speed. For example, a high-capacity nonvolatile memory device such as an HDD or a NAND memory, e.g., a 3D NAND, can be used.

In one embodiment of the present invention, at least the DRAM used as the main memory among the various memory devices illustrated in FIG. 59A is replaced with a memory device using an oxide semiconductor (an OS memory). Refresh operation is essential particularly for the DRAM among the various memory devices, and the DRAM is a destructive read memory device and thus consumes significantly higher power than other memory devices. Therefore, power consumption can be significantly reduced by not using the DRAM. Note that in FIG. 59A, among the various memory devices, the memory devices to be replaced with an OS memory are in a range surrounded by a dashed line. That is, not only the DRAM used as the main memory but also some SRAMs used as the cache and some NAND memories used as the storage can be replaced with OS memories.

FIG. 59B illustrates an example of the semiconductor device of one embodiment of the present invention. FIG. 59B is a schematic view illustrating the hierarchy of various memory devices used in the semiconductor device.

Caches illustrated in FIG. 59B are a plurality of caches (the L1 and L2 caches) and a last level cache (LLC).

The plurality of caches are provided in the descending order of level, i.e., in the order of the L1 cache and the L2 cache. The higher-level cache is more frequently accessed by the processor, and thus is required to operate at a higher speed. Since the operation speed can also be improved by reducing data capacity, the higher-level cache preferably has a smaller data capacity. The high-level cache is preferably provided physically closer to the processor and connected through a shorter wiring, and thus is preferably provided in the same layer as the processor. The low-level cache and the processor may be provided in different layers.

The lowest-level cache can be referred to as an LLC. The LLC does not require a higher operation speed than a higher-level cache, but desirably has large storage capacity. An OS memory of one embodiment of the present invention to be described later operates at high speed and can retain data for a long time, and thus can be suitably used as the LLC. Note that the OS memory of one embodiment of the present invention can also be used as a final level cache (FLC).

An SRAM can be used as each of the various caches. An OS memory can be suitably used as each of the LLC and the main memory. The memory device can operate at high speed and can retain data for a long time.

The structure exemplified above includes not a DRAM, which has been conventionally used as a main memory or the like, but the OS memory of one embodiment of the present invention. Such a structure can achieve a drastic reduction in power consumption (to one-hundredth or less or one-thousandth or less). Thus, worldwide expansion of information processing devices including a computer, a server, or the like employing such a structure is expected to highly contribute to inhibition of global warming.

Note that this embodiment can be combined with any of the other embodiments in this specification as appropriate.

### Embodiment 4

An electronic device, a large computer, a device for space, and a data center (also referred to as DC) for which the semiconductor device described in the above embodiments can be used are described in this embodiment. An electronic device, a large computer, a device for space, and a data center each employing the semiconductor device of one embodiment of the present invention are effective in improving performance, for example, reducing power consumption.

### [Electronic Device]

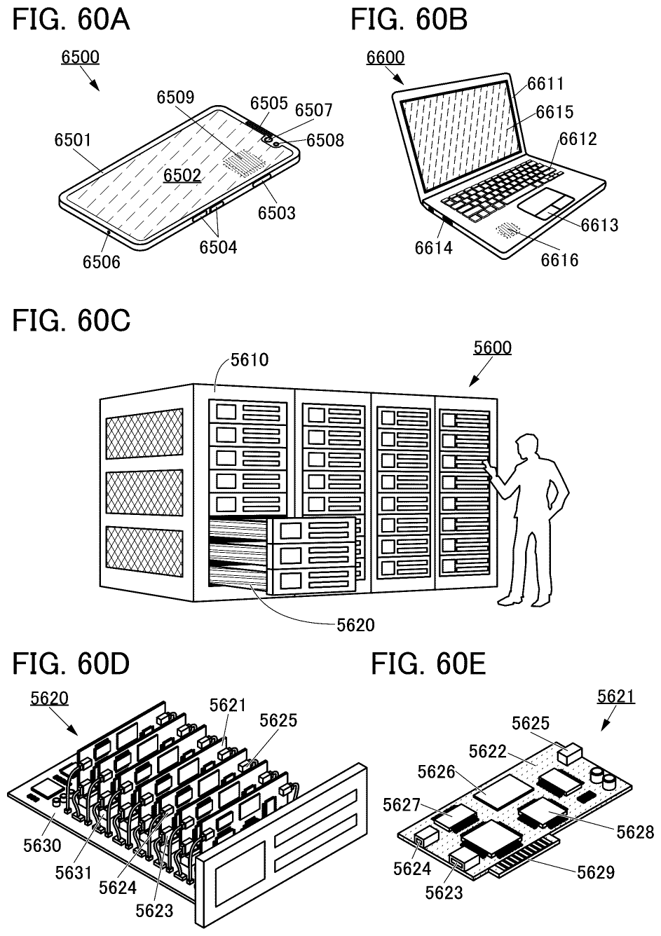

FIG. 60A is a perspective view of an electronic device 6500. The electronic device 6500 in FIG. 60A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 60B is an information terminal that can be used as a laptop personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 60C is a perspective view of a large computer 5600. In the large computer 5600 illustrated in FIG. 60C, a plurality of rack mount computers 5620 are stored in a rack 5610. Note that the large computer 5600 may be referred to as a supercomputer.

The computer 5620 can have a structure in a perspective view illustrated in FIG. 60D, for example. In FIG. 60D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 60E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 60E also illustrates semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used for a device for space, such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

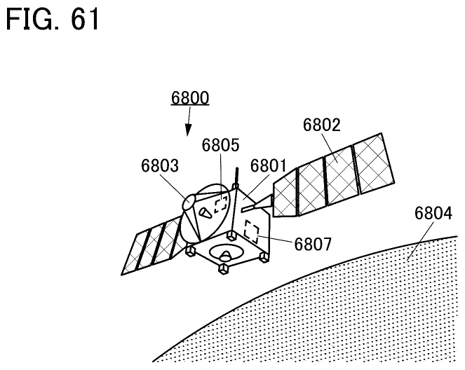

FIG. 61 illustrates an artificial satellite 6800 as an example of a device for space. The artificial satellite 6800 includes a body 6801, a solar panel 6802, an antenna 6803, a secondary battery 6805, and a control device 6807. In FIG. 61, a planet 6804 in outer space is illustrated. Note that outer space refers to, for example, space at an altitude greater than or equal to 100 km, and outer space in this specification may also include thermosphere, mesosphere, and stratosphere.

Although not illustrated in FIG. 61, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to exposure to radiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

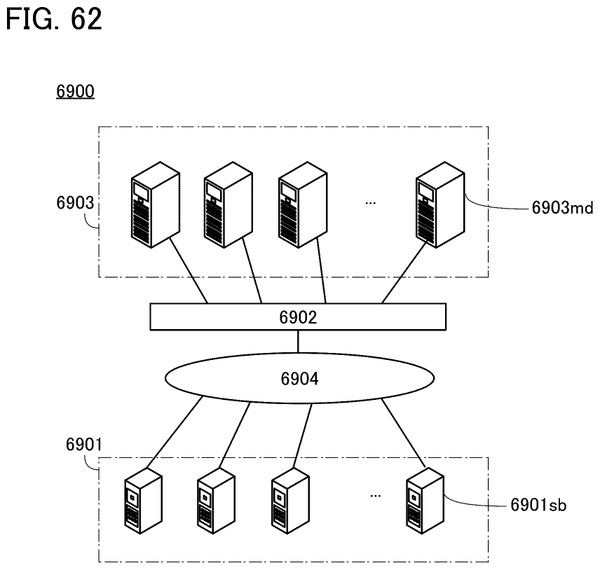

FIG. 62 illustrates a storage system that can be used in a data center. A storage system 6900 illustrated in FIG. 62 includes a plurality of servers 6901sb as a host 6901. The storage system 6900 includes a plurality of memory devices 6903md as a storage 6903. In the illustrated example, the host 6901 and the storage 6903 are connected to each other through a storage area network 6904 and a storage control circuit 6902.

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903. In the storage system, in order to solve the problem of low access speed of the storage 6903, a cache memory is normally provided in the storage to shorten the time needed for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic device, a large computer, a device for space, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

This application is based on Japanese Patent Application Serial No. 2023-167762 filed with Japan Patent Office on Sep. 28, 2023, the entire contents of which are hereby incorporated by reference.

What is claimed is:

1. A method for manufacturing a semiconductor device, comprising the steps of:
forming a second insulator having a columnar shape over a first insulator;
forming a first oxide semiconductor to cover a top surface of the first insulator, a side surface of the second insulator, and a top surface of the second insulator;
forming a second oxide semiconductor by removing a region of the first oxide semiconductor covering the top surface of the second insulator and a region of the first oxide semiconductor covering the top surface of the first insulator by anisotropic etching;
removing the second insulator;
forming a first conductor to cover the second oxide semiconductor and the first insulator;
forming a third insulator over the first conductor;
forming a first opening portion in the third insulator to reach the first conductor;
exposing the second oxide semiconductor and forming a second conductor and a third conductor by forming a second opening portion in the third insulator to reach the first conductor and removing a region of the first conductor overlapping with the second opening portion;
forming a fourth insulator to cover the second oxide semiconductor, the second conductor, the third conductor, and the third insulator;
forming a fourth conductor over the fourth insulator;
forming a fifth conductor in the first opening portion and a sixth conductor in the second opening portion by partly removing the fourth conductor; and
forming a fifth insulator in the first opening portion and a sixth insulator in the second opening portion by partly removing the fourth insulator,
wherein the third conductor is formed to overlap with the first opening portion.

2. The method for manufacturing a semiconductor device according to claim 1, wherein the first opening portion is formed to overlap with the second oxide semiconductor.

3. The method for manufacturing a semiconductor device according to claim 1, wherein the first opening portion and the second opening portion do not overlap with each other.

4. The method for manufacturing a semiconductor device according to claim 1,
wherein the fifth conductor and the sixth conductor are formed by a first treatment for removing a region of the fourth conductor covering a top surface of the third insulator,
wherein the fifth insulator and the sixth insulator are formed by a second treatment for removing a region of the fourth insulator covering the top surface of the third insulator, and
wherein the first treatment and the second treatment are each a planarization treatment.

5. The method for manufacturing a semiconductor device according to claim 4, wherein the planarization treatment is performed by a chemical mechanical polishing method.

6. A method for manufacturing a semiconductor device, comprising the steps of:
forming a second insulator having a columnar shape over a first insulator;
forming a first oxide semiconductor to cover a top surface of the first insulator, a side surface of the second insulator, and a top surface of the second insulator;
forming a second oxide semiconductor by removing a region of the first oxide semiconductor covering the top surface of the second insulator and a region of the first oxide semiconductor covering the top surface of the first insulator by anisotropic etching;
removing the second insulator;
forming a first conductor and a second conductor over the first conductor as a stacked-layer structure to cover the second oxide semiconductor and the first insulator;
forming a third insulator over the second conductor;
forming a first opening portion and a second opening portion in the third insulator to each reach the second conductor;
forming a third conductor and a fourth conductor by removing a region of the second conductor overlapping with the first opening portion and a region of the second conductor overlapping with the second opening portion;
forming a first mask over the third insulator and the first conductor;
exposing the second oxide semiconductor and forming a fifth conductor to overlap with the third conductor and a sixth conductor to overlap with the fourth conductor by partly removing a region of the first conductor overlapping with the second opening portion using the first mask;
forming a fourth insulator to cover the second oxide semiconductor, the fifth conductor, the sixth conductor, and the third insulator;
forming a seventh conductor over the fourth insulator;
forming an eighth conductor in the first opening portion and a ninth conductor in the second opening portion by partly removing the seventh conductor; and
forming a fifth insulator in the first opening portion and a sixth insulator in the second opening portion by partly removing the fourth insulator,
wherein the fifth conductor is formed to overlap with the first opening portion.

7. The method for manufacturing a semiconductor device according to claim 6, wherein the first opening portion is formed to overlap with the second oxide semiconductor.

8. The method for manufacturing a semiconductor device according to claim 6, wherein the first conductor comprises tantalum nitride and the second conductor comprises tungsten.

9. The method for manufacturing a semiconductor device according to claim 6, wherein the first conductor is formed by a sputtering method.

10. The method for manufacturing a semiconductor device according to claim 6, wherein each of the fifth conductor and the sixth conductor comprises a region having an end portion protruding into the second opening portion.

11. The method for manufacturing a semiconductor device according to claim 10,
wherein the end portion of the fifth conductor protruding into the second opening portion extends inward from an end portion of the third conductor, and
wherein the end portion of the sixth conductor protruding into the second opening portion extends inward from an end portion of the fourth conductor.

12. The method for manufacturing a semiconductor device according to claim 1,
wherein the first oxide semiconductor is formed by forming a first semiconductor layer, forming a second semiconductor layer over the first semiconductor layer, and forming a third semiconductor layer over the second semiconductor layer,
wherein the first semiconductor layer and the third semiconductor layer are formed by an ALD method using a precursor comprising indium and an oxidizer, and
wherein the second semiconductor layer is formed by a sputtering method using a sputtering target comprising zinc.

13. The method for manufacturing a semiconductor device according to claim 6,
wherein the first oxide semiconductor is formed by forming a first semiconductor layer, forming a second semiconductor layer over the first semiconductor layer, and forming a third semiconductor layer over the second semiconductor layer,
wherein the first semiconductor layer and the third semiconductor layer are formed by an ALD method using a precursor comprising indium and an oxidizer, and
wherein the second semiconductor layer is formed by a sputtering method using a sputtering target comprising zinc.
